(19) United States
(12) Patent Application Publication
(10) Pub. No.: US 2025/0318220 A1
(43) Pub. Date: Oct. 9, 2025

(54) TRANSISTOR GATE STRUCTURES AND METHODS OF FORMING THE SAME

(71) Applicant: Taiwan Semiconductor Manufacturing Co., Ltd., Hsinchu (TW)

(72) Inventors: Chung-Wei Hsu, Baoshan Township (TW); Kuan-Ting Pan, Taipei City (TW); Lung-Kun Chu, New Taipei City (TW); Kuo-Cheng Chiang, Zhubei City (TW); Chih-Hao Wang, Baoshan Township (TW); Jia-Ni Yu, New Taipei City (TW)

(21) Appl. No.: 19/243,424

(22) Filed: Jun. 19, 2025

Related U.S. Application Data
(62) Division of application No. 18/150,474, filed on Jan. 5, 2023.
(60) Provisional application No. 63/366,076, filed on Jun. 9, 2022.
(60) Provisional application No. 63/405,942, filed on Sep. 13, 2022.

(51) Int. Cl. H10D 62/10; H01L 21/762; H01L 21/768; H10D 30/67; H10D 62/13; H10D 64/01; H10D 84/01; H10D 84/03

(52) U.S. Cl. CPC H10D 62/121; H01L 21/76224; H01L 21/76831; H10D 30/6735; H10D 30/6757; H10D 62/151; H10D 64/017; H10D 84/0167; H10D 84/038

(57) ABSTRACT

In an embodiment, a device includes: an isolation region on a substrate; first nanostructures above the isolation region; second nanostructures above the isolation region; a first gate spacer on the first nanostructures; a second gate spacer on the second nanostructures; a dielectric wall between the first gate spacer and the second gate spacer along a first direction in a top-down view, the dielectric wall disposed between the first nanostructures and the second nanostructures along a second direction in the top-down view, the first direction perpendicular to the second direction; and a gate structure around the first nanostructures and around the second nanostructures, a first portion of the gate structure filling a first area between the dielectric wall and the first nanostructures, a second portion of the gate structure filling a second area between the dielectric wall and the second nanostructures.

### PRIORITY CLAIM AND CROSS-REFERENCE

This application is a divisional of U.S. patent application Ser. No. 18/150,474, filed Jan. 5, 2023, entitled “Transistor Gate Structures and Methods of Forming the Same,” which claims the benefit of U.S. Provisional Application No. 63/405,942, filed on Sep. 13, 2022 and U.S. Provisional Application No. 63/366,076, filed on Jun. 9, 2022, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2-31C are views of intermediate stages in the manufacturing of nanostructure-FETs, in accordance with some embodiments.

FIG. 32 is a top-down view of nanostructure-FETs, in accordance with some embodiments.

FIGS. 33A-52C are views of intermediate stages in the manufacturing of nanostructure-FETs, in accordance with some embodiments.

FIG. 53 is a top-down view of nanostructure-FETs, in accordance with some embodiments.

FIGS. 54A-54C are views of nanostructure-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, dielectric walls are formed between adjacent groups of nanostructures. The dielectric walls provide isolation, so the adjacent groups of nanostructures may be formed closer together. Device density may thus be improved. Additionally, gate structures are formed around the nanostructures and over the dielectric walls. The gate structures are x-shaped, thereby allowing a same gate structure to control the channel regions of adjacent devices. The amount of gate contacts used in a CMOS process may thus be reduced.

Embodiments are described in a particular context, a die including nanostructure field-effect transistor (nanostructure-FETs). Various embodiments may be applied, however, to dies including other types of transistors (e.g., fin field-effect transistors (FinFETs), planar transistors, or the like) in lieu of or in combination with the nanostructure-FETs.

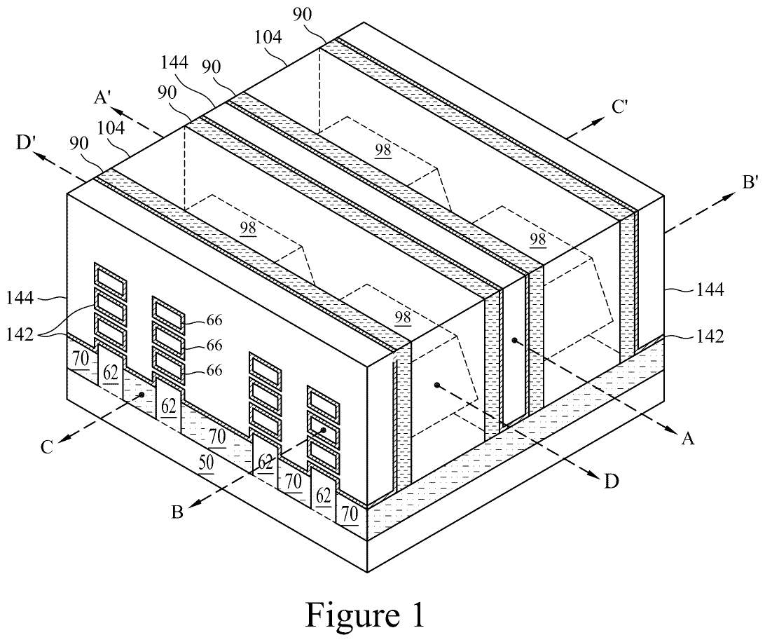

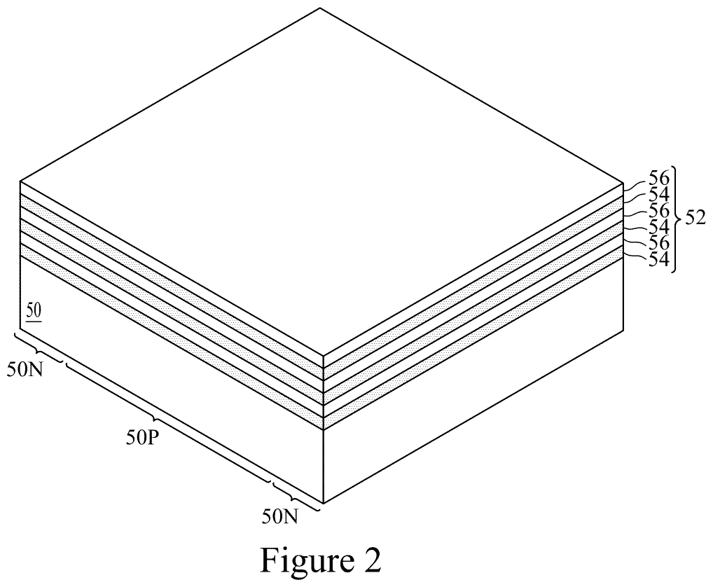

FIG. 1 illustrates an example of nanostructure-FETs (e.g., nanowire FETs, nanosheet FETs, multi bridge channel (MBC) FETs, nanoribbon FETs, gate-all-around (GAA) FETs, or the like), in accordance with some embodiments. FIG. 1 is a three-dimensional view, where some features of the nanostructure-FETs are omitted for illustration clarity.

The nanostructure-FETs include nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may comprise a single material or a plurality of materials. In this context, the fins 62 refer to the portion extending between the neighboring isolation regions 70.

Gate dielectrics 142 are over top surfaces of the fins 62 and along top surfaces, sidewalls, and bottom surfaces of the nanostructures 66. Gate electrodes 144 are over the gate dielectrics 142. Source/drain regions 98 are disposed on the fins 62 on opposing sides of the gate dielectrics 142 and the gate electrodes 144. Source/drain region(s) 98 may refer to a source or a drain, individually or collectively dependent upon the context. An inter-layer dielectric (ILD) 104 is formed over the source/drain regions 98. Contacts (subsequently described) to the source/drain regions 98 will be formed through the ILD 104. The source/drain regions 98 may be shared between various nanostructures 66. For example, adjacent source/drain regions 98 may be electrically connected, such as through coalescing the source/drain regions 98 by epitaxial growth, or through coupling the source/drain regions 98 with a same contact.

FIG. 1 further illustrates reference cross-sections that are used in later figures. Cross-section A-A′ is along a longitudinal axis of a gate electrode 144. Cross-section B-B′ is perpendicular to cross-section A-A′ and is parallel to a longitudinal axis of a fin 62 of the nanostructure-FET and in a direction of, for example, a current flow between the source/drain regions 98 of the nanostructure-FET. Cross-section C-C′ is parallel to cross-section B-B′ and along a longitudinal axis of an isolation region 70 between adjacent fins 62. Cross-section D-D′ is parallel to cross-section A-A′ and extends through source/drain regions 98 of the nanostructure-FETs. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs). For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

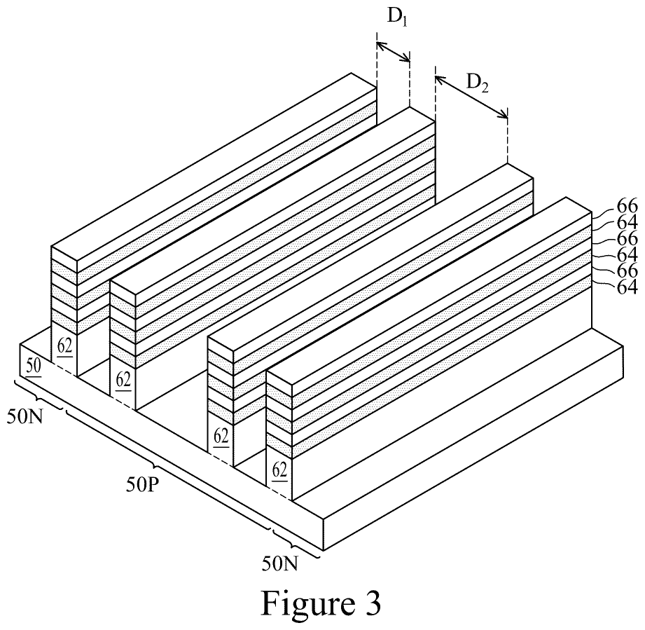

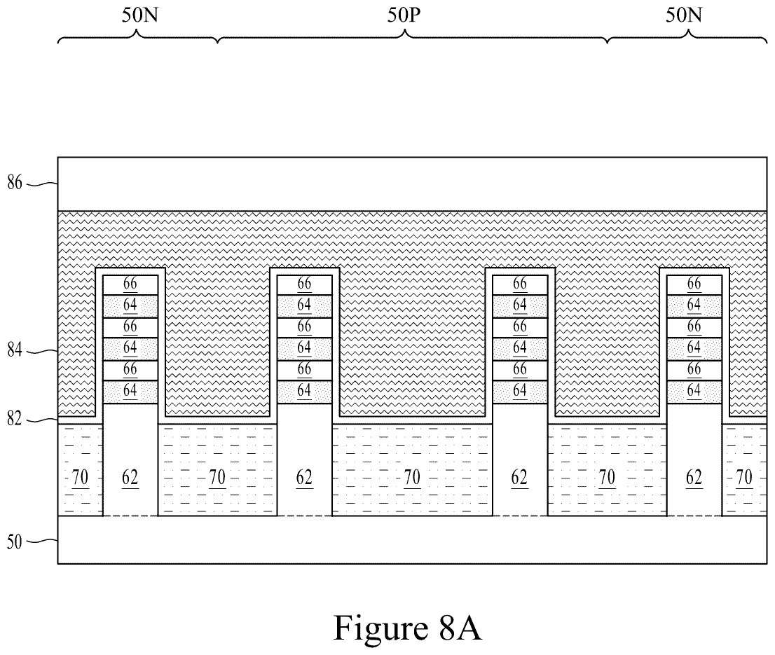

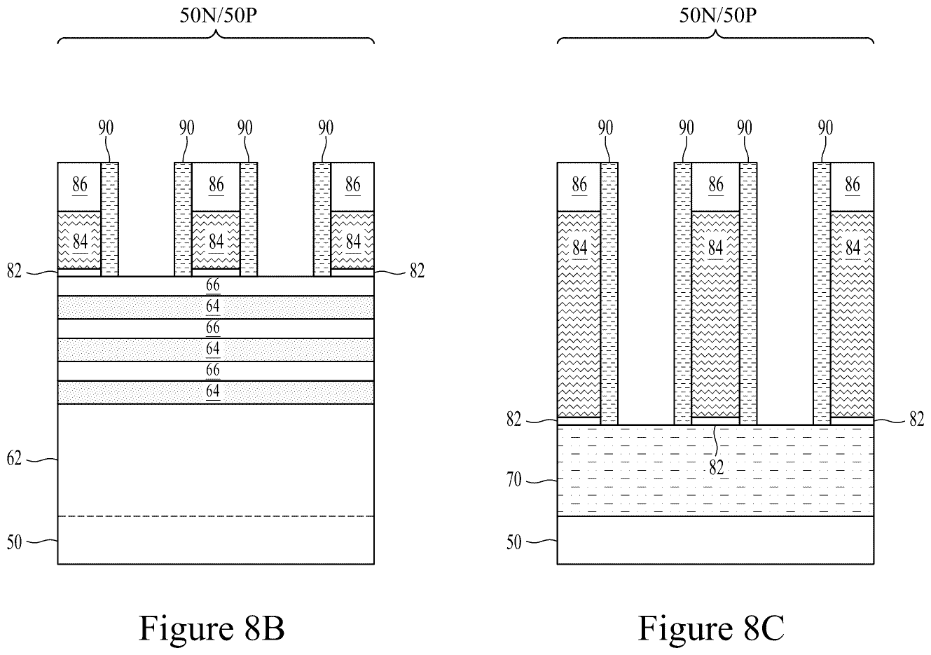

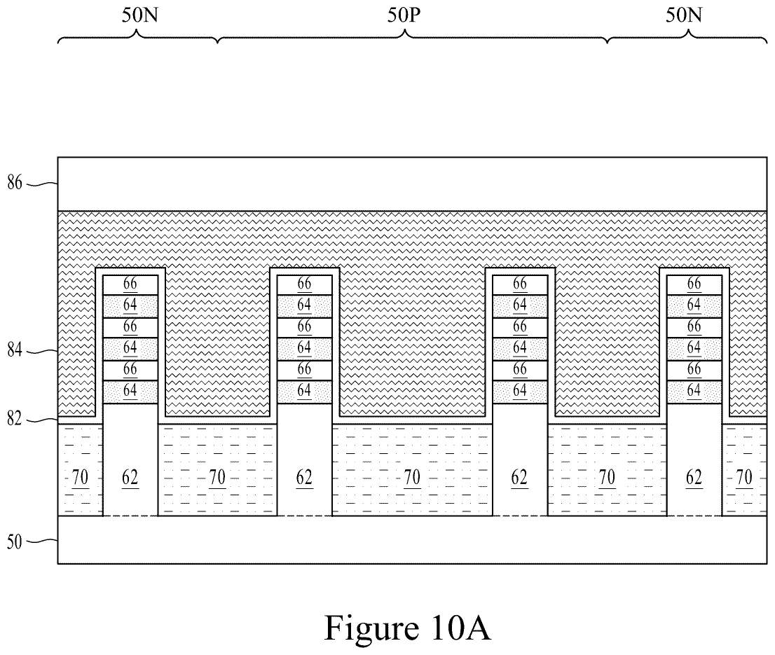

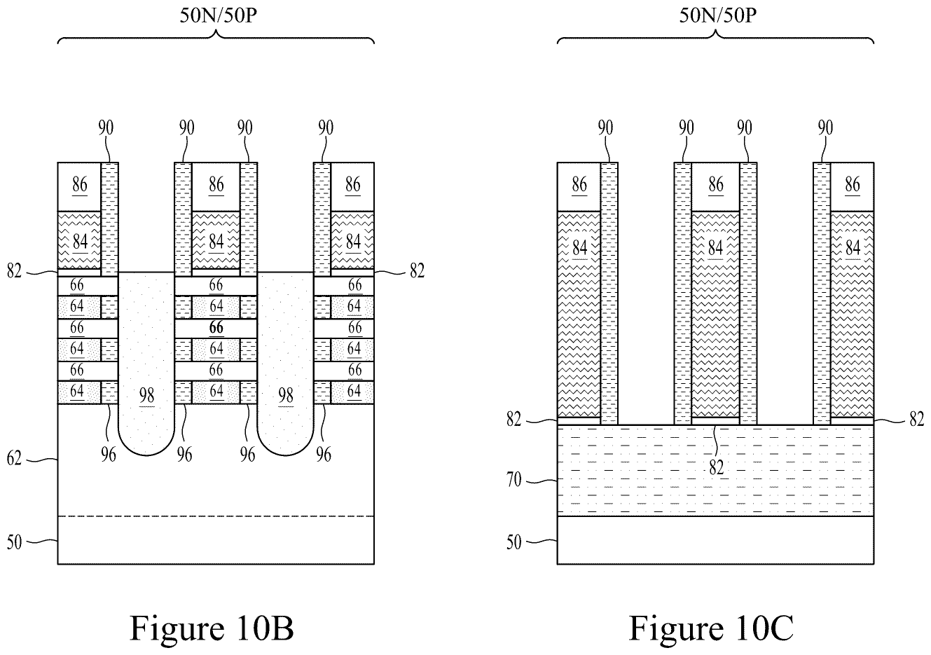

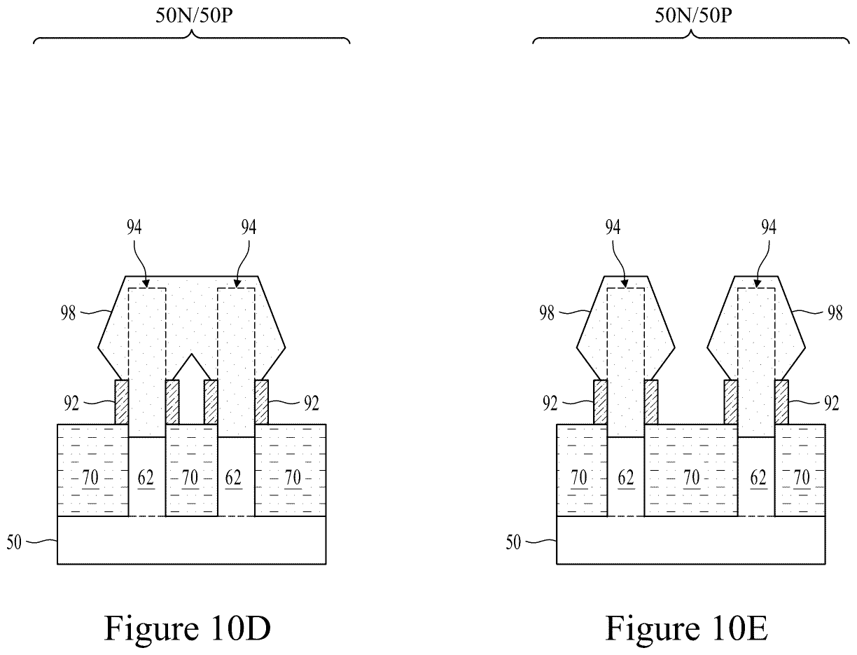

FIGS. 2-31B are views of intermediate stages in the manufacturing of nanostructure-FETs, in accordance with some embodiments. FIGS. 2, 3, 4, 5, 6, and 7 are three-dimensional views showing a similar three-dimensional view as FIG. 1. FIGS. 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, and 31A are cross-sectional views illustrated along a similar cross-section as reference cross-section A-A′ in FIG. 1. FIGS. 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, and 31B are cross-sectional views illustrated along a similar cross-section as reference cross-section B-B′ in FIG. 1. FIGS. 8C, 9C, 10C, 11C, 12C, 13C, 14C, 15C, 16C, 17C, 18C, 19C, 20C, 21C, 22C, 23C, 24C, 25C, 26C, 27C, 28C, 29C, 30C, and 31C are cross-sectional views illustrated along a similar cross-section as reference cross-section C-C′ in FIG. 1. FIGS. 10D and 10E are cross-sectional views illustrated along a similar cross-section as reference cross-section D-D′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has one or more n-type regions 50N and one or more p-type regions 50P. The n-type regions 50N can be for forming n-type devices, such as NMOS transistors, e.g., n-type nanostructure-FETs, and the p-type regions 50P can be for forming p-type devices, such as PMOS transistors, e.g., p-type nanostructure-FETs. As subsequently described in greater detail, an n-type device and a p-type device will be formed close to one another. Forming an n-type device and a p-type device close together increases device density and allows the gate structures for the devices to be physically and electrically coupled to one another, thereby reducing the amount of gate contacts used in a CMOS process. For example, density can be shrunk down to 70% the original density. Channel regions in the n-type regions 50N will be physically separated from channel regions in the p-type regions 50P by dielectric walls to prevent shorting of the channel regions. Although one p-type region 50P and two n-type regions 50N are illustrated, any number of n-type regions 50N and p-type regions 50P may be provided.

The devices in the n-type regions 50N and the p-type regions 50P may be subsequently interconnected by metallization layers in an overlying interconnect structure to form integrated circuits. The integrated circuits may be logic devices, memory devices, or the like. In some embodiments where a CMOS process is utilized, respective ones of the p-type regions 50P are disposed between respective pairs of the n-type regions 50N. Other acceptable integrated circuits may be formed, and the n-type regions 50N and the p-type regions 50P may be provided in any acceptable manner for the integrated circuits.

A multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50.

In the illustrated embodiment, and as subsequently described in greater detail, the first semiconductor layers 54 will be removed and the second semiconductor layers 56 will patterned to form channel regions for the nanostructure-FETs in both the n-type regions 50N and the p-type regions 50P. In such embodiments, the channel regions in both the n-type regions 50N and the p-type regions 50P may have a same material composition (e.g., silicon or another semiconductor material) and be formed simultaneously. The first semiconductor layers 54 are dummy layers that will be removed in subsequent processing to expose the top surfaces and the bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

The multi-layer stack 52 is illustrated as including three of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 (e.g., the second semiconductor layers 56) are formed to be thinner than other layers of the multi-layer stack 52 (e.g., the first semiconductor layers 54). In some embodiments, the second semiconductor layers 56 have a thickness in the range of 2 nm to 6 nm.

In FIG. 3, fins 62 are formed in the substrate 50 and nanostructures 64, 66 are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may further define first nanostructures 64 from the first semiconductor layers 54 and define second nanostructures 66 from the second semiconductor layers 56.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66.

The fins 62 are illustrated as having substantially equal widths in both the n-type regions 50N and the p-type regions 50P. In some embodiments, the widths of the fins 62 in the n-type regions 50N may be greater or less than the width of the fins 62 in the p-type regions 50P. Further, while each of the fins 62 and the nanostructures 64, 66 are illustrated as having a consistent width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in shape. In some embodiments, the nanostructures 66 have a width in the range of 10 nm to 50 nm.

As subsequently described in greater detail, dielectric walls will be formed between the second nanostructures 66 in an n-type region 50N and the second nanostructures 66 in an adjacent p-type region 50P. Each dielectric wall separates a channel region of an n-type device from a channel region of a p-type device to prevent shorting of the channel regions. The second nanostructures 66 in an n-type region 50N may thus be formed close to the second nanostructures 66 in an adjacent p-type region 50P. The distance D₁ between the second nanostructures 66 in an n-type region 50N and an adjacent p-type region 50P may be less than the distance D₂ between the adjacent second nanostructures 66 in a same p-type region 50P or a same n-type region 50N. In some embodiments, the distance D₁ between the second nanostructures 66 in an n-type region 50N and an adjacent p-type region 50P is in the range of 20 nm to 60 nm. In some embodiments, the distance D₂ between the adjacent second nanostructures 66 in a same p-type region 50P or a same n-type region 50N is in the range of 40 nm to 60 nm.

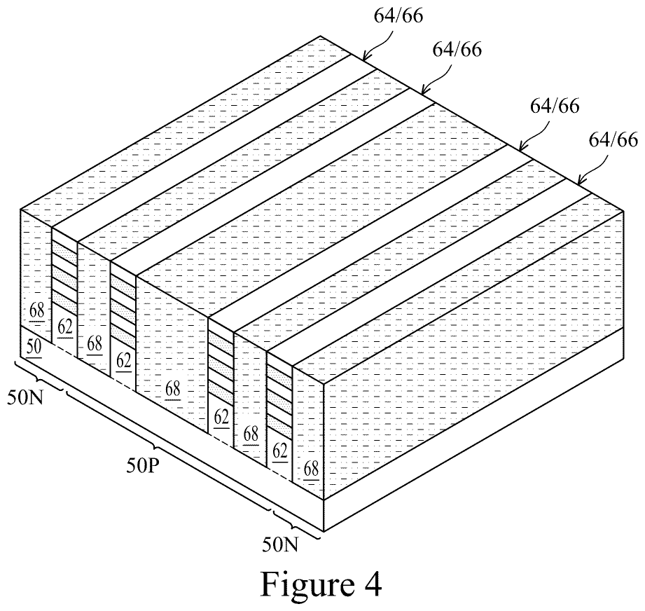

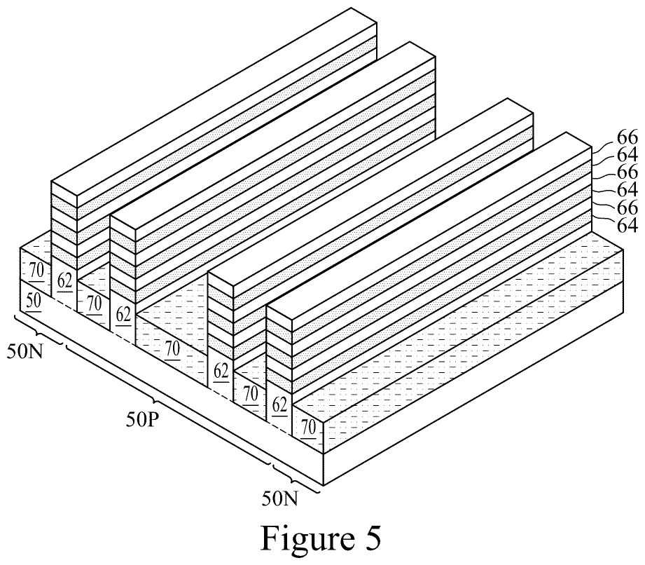

In FIG. 4, an insulation material 68 is deposited over the substrate 50, the fins 62, and nanostructures 64, 66, and between adjacent fins 62 and adjacent nanostructures 64, 66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 is silicon oxide formed by an FCVD process. An annealing process may be performed once the insulation material 68 is formed. In an embodiment, the insulation material 68 is formed such that excess insulation material 68 covers the nanostructures 64, 66. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulation materials may be formed over the liner.

A removal process is then applied to the insulation material 68 to remove excess insulation material 68 over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulation material 68 are level after the planarization process is complete.

In FIG. 5, the insulation material 68 is recessed to form STI regions 70. The STI regions 70 are adjacent the fins 62. The insulation material 68 is recessed such that upper portions of fins 62 and/or the nanostructures 64, 66 protrude from between neighboring STI regions 70. The upper portions of fins 62 and/or the nanostructures 64, 66 are above the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64, 66). For example, an oxide removal using, for example, dilute hydrofluoric (dHF) acid may be used.

The previously described process is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may comprise the previously described alternating semiconductor materials, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the fins 62, the nanostructures 64, 66, and/or the STI regions 70. In embodiments with different well types, different implant steps for the n-type regions 50N and the p-type regions 50P may be achieved using a photoresist or other mask (not separately illustrated). For example, a photoresist may be formed over the fins 62, the nanostructures 64, 66, and the STI regions 70 in the n-type regions 50N and the p-type regions 50P. The photoresist is patterned to expose the p-type regions 50P. The photoresist can be formed by using a spin-on technique and can be patterned using acceptable photolithography techniques. Once the photoresist is patterned, an n-type impurity implant is performed in the p-type regions 50P, and the photoresist may act as a mask to substantially prevent n-type impurities from being implanted into the n-type regions 50N. The n-type impurities may be phosphorus, arsenic, antimony, or the like implanted in the region to a concentration in a range from 10¹³ atoms/cm³ to 10¹⁴ atoms/cm³. After the implant, the photoresist is removed, such as by an acceptable ashing process.

Following or prior to the implanting of the p-type regions 50P, a photoresist or other mask (not separately illustrated) is formed over the fins 62, the nanostructures 64, 66, and the STI regions 70 in the p-type regions 50P and the n-type regions 50N. The photoresist is patterned to expose the n-type regions 50N. The photoresist can be formed by using a spin-on technique and can be patterned using acceptable photolithography techniques. Once the photoresist is patterned, a p-type impurity implant may be performed in the n-type regions 50N, and the photoresist may act as a mask to substantially prevent p-type impurities from being implanted into the p-type regions 50P. The p-type impurities may be boron, boron fluoride, indium, or the like implanted in the region to a concentration in a range from 10¹³ atoms/cm³ to 10¹⁴ atoms/cm³. After the implant, the photoresist may be removed, such as by an acceptable ashing process.

After the implants of the n-type regions 50N and the p-type regions 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

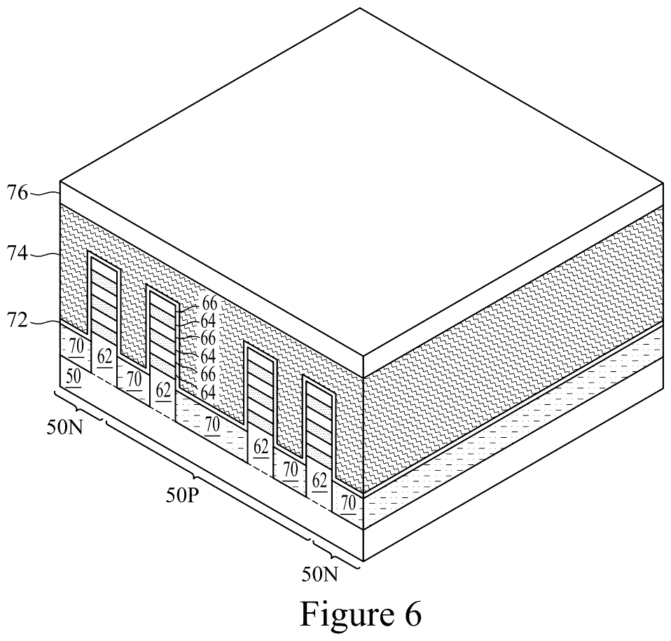

In FIG. 6, a dummy dielectric layer 72 is formed on the fins 62 and/or the nanostructures 64, 66. The dummy dielectric layer 72 may be formed of silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The dummy gate layer 74 may be formed of a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The material of the dummy gate layer 74 may be deposited by CVD, physical vapor deposition (PVD), sputter deposition, or other techniques for depositing the selected material. The dummy gate layer 74 may be made of other materials that have a high etching selectivity from the etching of insulation materials, e.g., the STI regions 70 and/or the dummy dielectric layer 72. The mask layer 76 may be deposited over the dummy gate layer 74. The mask layer 76 may be formed of a dielectric material such as silicon nitride, silicon oxynitride, or the like. In this example, a single dummy gate layer 74 and a single mask layer 76 are formed across the n-type regions 50N and the p-type regions 50P. In the illustrated embodiment, the dummy dielectric layer 72 covers the STI regions 70, such that the dummy dielectric layer 72 extends between the dummy gate layer 74 and the STI regions 70. In another embodiment, the dummy dielectric layer 72 covers only the fins 62 and/or the nanostructures 64, 66.

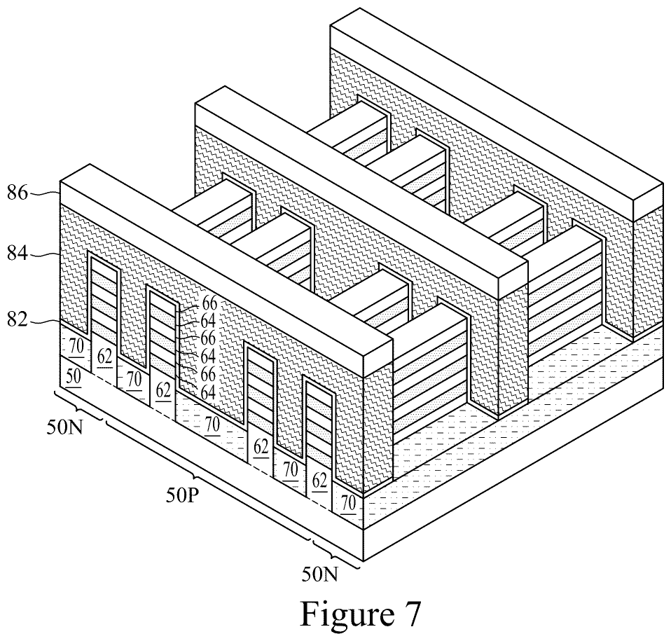

In FIG. 7, the mask layer 76 is patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

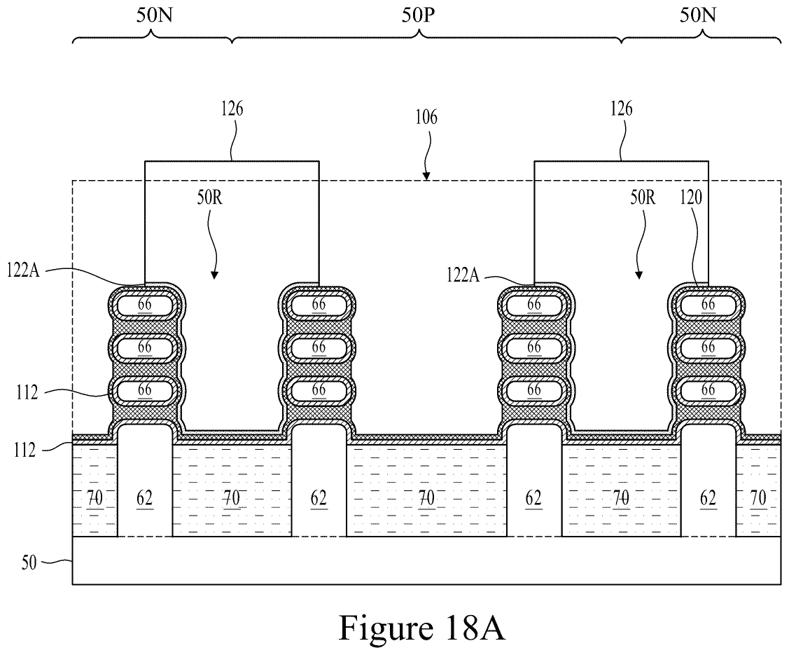

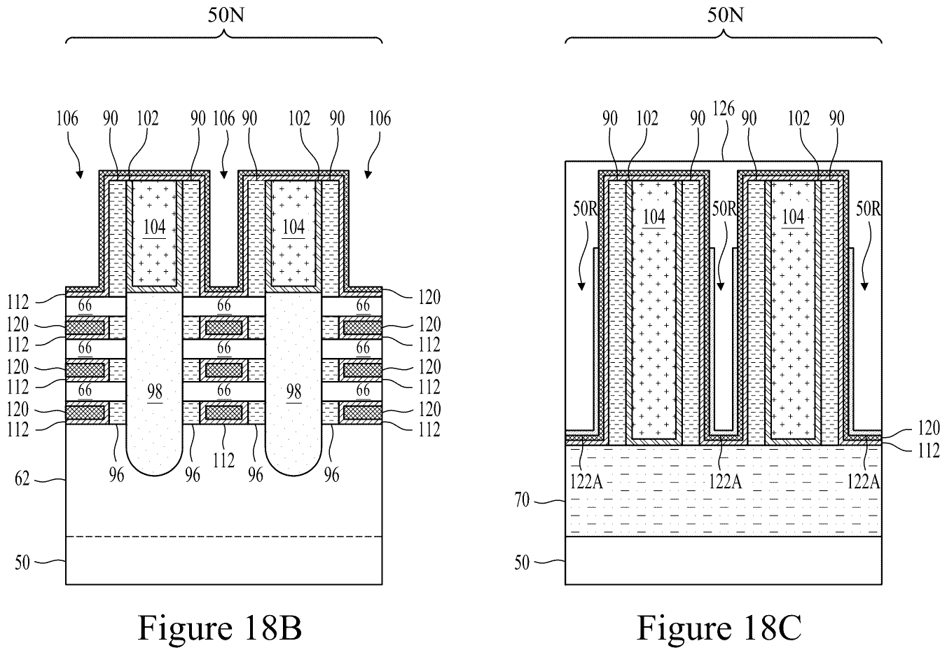

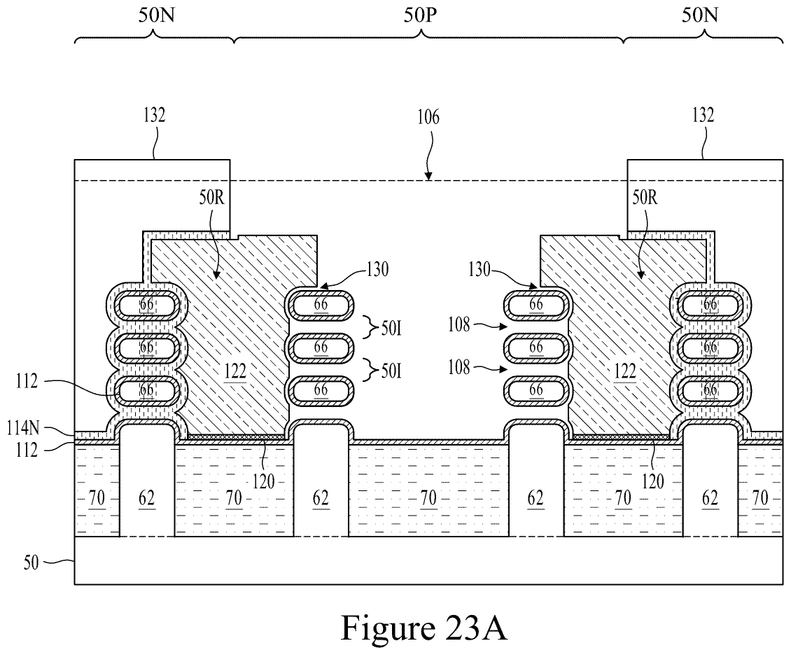

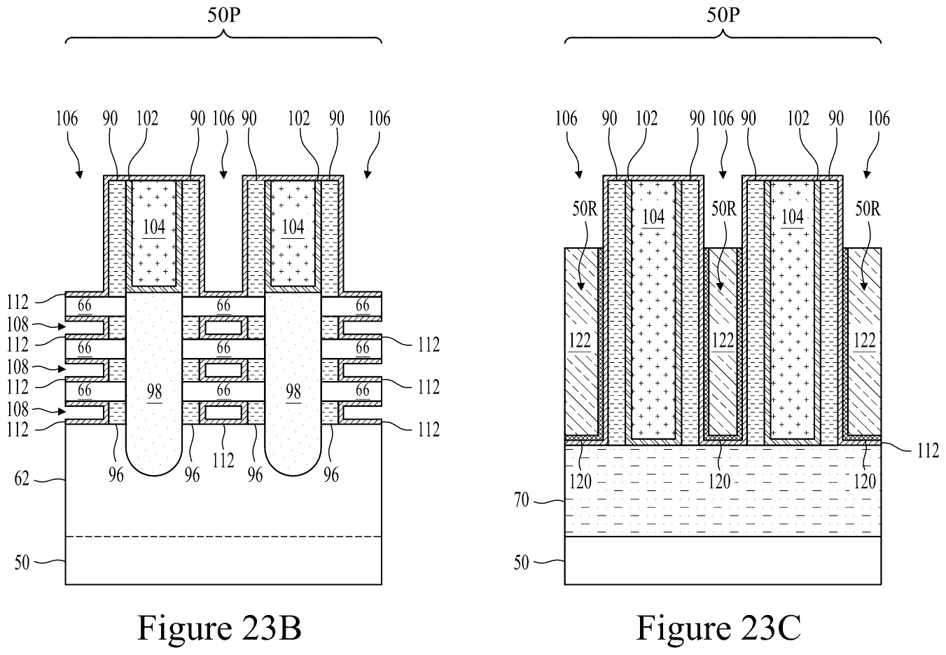

FIGS. 8A-31B illustrate various additional steps in the manufacturing of embodiment devices. FIGS. 8B, 8C, 9B, 9C, 10B, 10C, 11B, 11C, 12B, 12C, 13B, 13C, 14B, 14C, 15B, 15C, 16B, 16C, 17B, 17C, 26B, 26C, 27B, 27C, 28B, 28C, 29B, 29C, 30B, 30C, 31B, and 31C illustrate features in either of the n-type regions 50N and the p-type regions 50P. For example, the structures illustrated may be applicable to both the n-type regions 50N and the p-type regions 50P. Differences (if any) in the structures of the n-type regions 50N and the p-type regions 50P are explained in the description of each figure. FIGS. 18B, 18C, 19B, 19C, 20B, 20C, 21B, 21C, 22B, and 22C illustrate features in the n-type regions 50N. FIGS. 23B, 23C, 24B, 24C, 25B, and 25C illustrate features in the p-type regions 50P.

In FIGS. 8A-8C, gate spacers 90 are formed over the nanostructures 64, 66 and the STI regions 70, on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). As will be subsequently described in greater detail, the dielectric material(s), when etched, may also have portions left on the sidewalls of the fins 62 and/or the nanostructures 64, 66 (thus forming fin spacers 92, see FIGS. 10D and 10E). After etching, the fin spacers 92 and/or the gate spacers 90 can have straight sidewalls (as illustrated) or can have curved sidewalls (not separately illustrated).

Further, implants for lightly doped source/drain (LDD) regions (not separately illustrated) may be performed. In embodiments with different device types, similar to the implants for the previously described wells, a mask, such as a photoresist, may be formed over the n-type regions 50N, while exposing the p-type regions 50P, and appropriate type (e.g., p-type) impurities may be implanted into the fins 62 and the nanostructures 64, 66 exposed in the p-type regions 50P. The mask may then be removed. Subsequently, a mask, such as a photoresist, may be formed over the p-type regions 50P while exposing the n-type regions 50N, and appropriate type impurities (e.g., n-type) may be implanted into the fins 62 and the nanostructures 64, 66 exposed in the n-type regions 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 1015 atoms/cm³ to 1019 atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

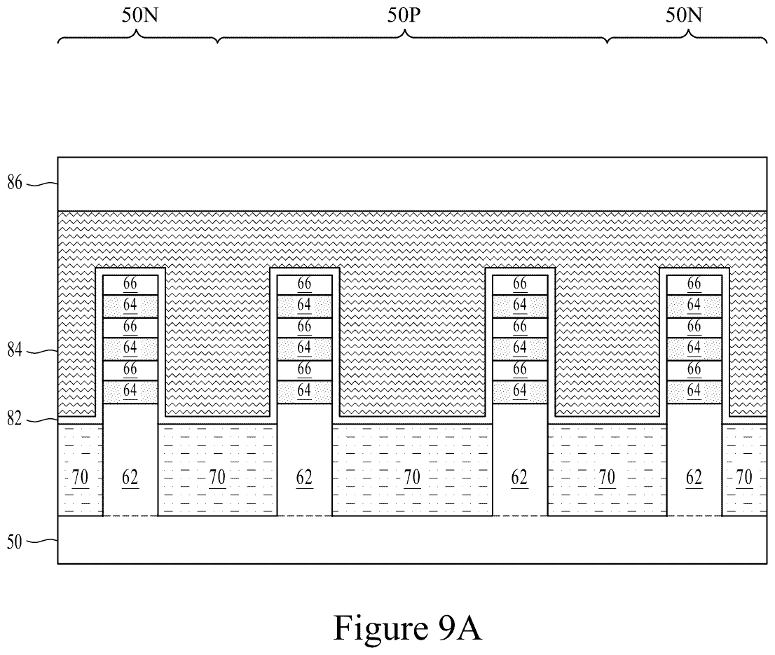

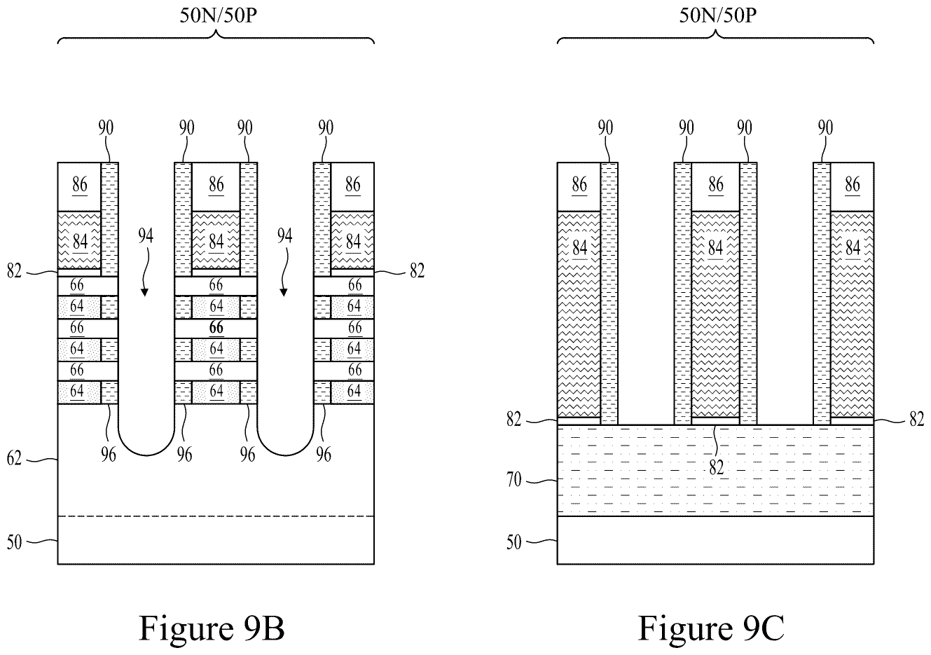

In FIGS. 9A-9C, source/drain recesses 94 are formed in the fins 62, the nanostructures 64, 66, and the substrate 50. Epitaxial source/drain regions will be subsequently formed in the source/drain recesses 94. The source/drain recesses 94 may extend through the nanostructures 64, 66 and into the substrate 50. In some embodiments, the fins 62 may be etched such that bottom surfaces of the source/drain recesses 94 are disposed below the top surfaces of the STI regions 70. The source/drain recesses 94 may be formed by etching the fins 62, the nanostructures 64, 66, and the substrate 50 using anisotropic etching processes, such as RIE, NBE, or the like. The gate spacers 90 and the dummy gates 84 mask portions of the fins 62, the nanostructures 64, 66, and the substrate 50 during the etching processes used to form the source/drain recesses 94. A single etch process or multiple etch processes may be used to etch each layer of the nanostructures 64, 66 and/or the fins 62. Timed etch processes may be used to stop the etching of the source/drain recesses 94 after the source/drain recesses 94 reach a desired depth.

Optionally, inner spacers 96 are formed on the sidewalls of the remaining portions of the first nanostructures 64, e.g., those sidewalls exposed by the source/drain recesses 94. As will be subsequently described in greater detail, source/drain regions will be subsequently formed in the source/drain recesses 94, and the first nanostructures 64 will be subsequently replaced with corresponding gate structures. The inner spacers 96 act as isolation features between the subsequently formed source/drain regions and the subsequently formed gate structures. Further, the inner spacers 96 may be used to prevent damage to the subsequently formed source/drain regions by subsequent etch processes, such as etch processes used to subsequently remove the first nanostructures 64.

As an example to form the inner spacers 96, the source/drain recesses 94 can be laterally expanded. Specifically, portions of the sidewalls of the first nanostructures 64 exposed by the source/drain recesses 94 may be recessed to form sidewall recesses. Although sidewalls of the first nanostructures 64 are illustrated as being straight, the sidewalls may be concave or convex. The sidewalls may be recessed by any acceptable etch process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etch process may be a wet etch using tetramethylammonium hydroxide (TMAH), ammonium hydroxide (NH₄OH), or the like. In another embodiment, the etch process may be a dry etch using a fluorine-based gas such as hydrogen fluoride (HF) gas. In some embodiments, the same etch process may be continually performed to both form the source/drain recesses 94 and recess the sidewalls of the first nanostructures 64. The inner spacers 96 can then be formed by conformally forming an insulating material in the source/drain recesses 94, and subsequently etching the insulating material. The insulating material may be silicon nitride or silicon oxynitride, although any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like.

Although outer sidewalls of inner spacers 96 are illustrated as being flush with sidewalls of the second nanostructures 66, the outer sidewalls of the inner spacers 96 may extend beyond or be recessed from sidewalls of the second nanostructures 66. In other words, the inner spacers 96 may partially fill, completely fill, or overfill the sidewall recesses. Moreover, although the sidewalls of the inner spacers 96 are illustrated as being straight, the sidewalls of the inner spacers 96 may be concave or convex.

In FIGS. 10A-10E, epitaxial source/drain regions 98 are formed in the source/drain recesses 94. In some embodiments, the epitaxial source/drain regions 98 exert stress in the respective channel regions of the second nanostructures 66, thereby improving performance. The epitaxial source/drain regions 98 are formed in the source/drain recesses 94 such that each dummy gate 84 is disposed between respective neighboring pairs of the epitaxial source/drain regions 98. In some embodiments, the gate spacers 90 are used to separate the epitaxial source/drain regions 98 from the dummy gates 84 and the inner spacers 96 are used to separate the epitaxial source/drain regions 98 from the nanostructures 64 by an appropriate lateral distance so that the epitaxial source/drain regions 98 do not short out with subsequently formed gates of the resulting nanostructure-FETs.

The epitaxial source/drain regions 98 in the n-type regions 50N may be formed by masking the p-type regions 50P. Then, the epitaxial source/drain regions 98 are epitaxially grown in the source/drain recesses 94 in the n-type regions 50N. The epitaxial source/drain regions 98 may include any acceptable material appropriate for n-type nanostructure-FETs. For example, if the second nanostructures 66 are formed of silicon, the epitaxial source/drain regions 98 may include materials exerting a tensile strain on the second nanostructures 66, such as silicon, silicon carbide, phosphorous doped silicon carbide, silicon phosphide, or the like. The epitaxial source/drain regions 98 in the n-type regions 50N may be referred to as “n-type source/drain regions.” The epitaxial source/drain regions 98 may have surfaces raised from respective upper surfaces of the nanostructures 64, 66 and may have facets.

The epitaxial source/drain regions 98 in the p-type regions 50P may be formed by masking the n-type regions 50N. Then, the epitaxial source/drain regions 98 are epitaxially grown in the source/drain recesses 94 in the p-type regions 50P. The epitaxial source/drain regions 98 may include any acceptable material appropriate for p-type nanostructure-FETs. For example, if the second nanostructures 66 are formed of silicon, the epitaxial source/drain regions 98 may comprise materials exerting a compressive strain on the first nanostructures 64, such as silicon-germanium, boron doped silicon-germanium, germanium, germanium tin, or the like. The epitaxial source/drain regions 98 in the p-type regions 50P may be referred to as “p-type source/drain regions.” The epitaxial source/drain regions 98 may also have surfaces raised from respective surfaces of the nanostructures 64, 66 and may have facets.

The epitaxial source/drain regions 98, the nanostructures 64, 66, and/or the fins 62 may be implanted with dopants to form source/drain regions, similar to the process previously discussed for forming lightly-doped source/drain regions, followed by an anneal. The source/drain regions may have an impurity concentration of between 1019 atoms/cm³ and 1021 atoms/cm³. The n-type and/or p-type impurities for source/drain regions may be any of the impurities previously discussed. In some embodiments, the epitaxial source/drain regions 98 may be in situ doped during growth.

As a result of the epitaxy processes used to form the epitaxial source/drain regions 98, upper surfaces of the epitaxial source/drain regions 98 have facets which expand laterally outward beyond sidewalls of the nanostructures 64, 66. In some embodiments, these facets cause adjacent epitaxial source/drain regions 98 of a same nanostructure-FET to merge as illustrated by FIG. 10D. In other embodiments, adjacent epitaxial source/drain regions 98 remain separated after the epitaxy process is completed as illustrated by FIG. 10E. In the illustrated embodiments, the fin spacers 92 are formed on a top surface of the STI regions 70, thereby blocking the epitaxial growth. In some other embodiments, the fin spacers 92 may cover portions of the sidewalls of the nanostructures 64, 66 and/or the fins 62, further blocking the epitaxial growth. In another embodiment, the spacer etch used to form the gate spacers 90 is adjusted to not form the fin spacers 92, so as to allow the epitaxial source/drain regions 98 to extend to the surface of the STI region 70.

The epitaxial source/drain regions 98 may comprise one or more semiconductor material layers. For example, the epitaxial source/drain regions 98 may comprise a liner layer, a main layer, and a finishing layer (or more generally, a first semiconductor material layer, a second semiconductor material layer, and a third semiconductor material layer). Any number of semiconductor material layers may be used for the epitaxial source/drain regions 98. Each of the liner layer, the main layer, and the finishing layer may be formed of different semiconductor materials and may be doped to different dopant concentrations. In some embodiments, the liner layer may have a dopant concentration less than the main layer and greater than the finishing layer. In embodiments in which the epitaxial source/drain regions 98 comprise three semiconductor material layers, the liner layer may be deposited, the main layer may be deposited over the liner layer, and the finishing layer may be deposited over the main layer. In embodiments in which the epitaxial source/drain regions 98 include three semiconductor material layers, the liner layers may be grown in the source/drain recesses 94, the main layers may be grown on the liner layers, and the finishing layers may be grown on the main layers

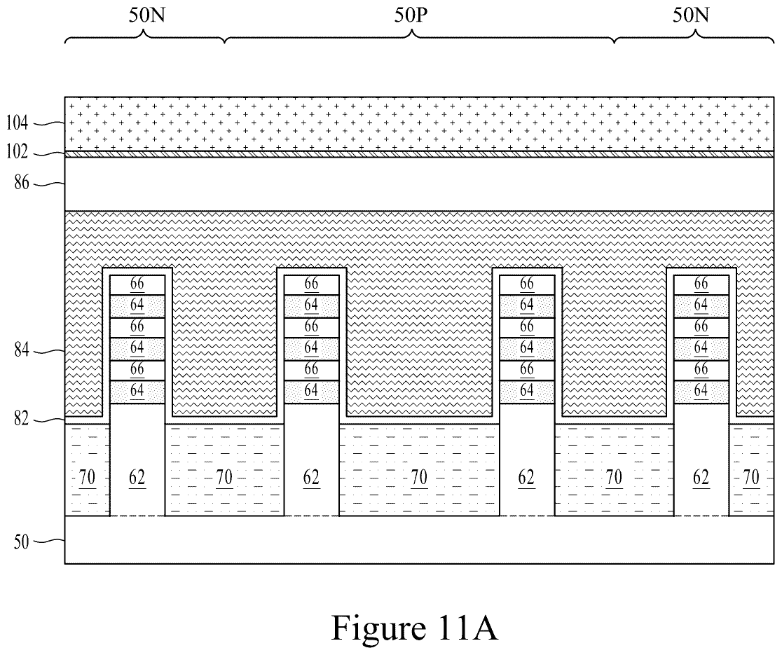

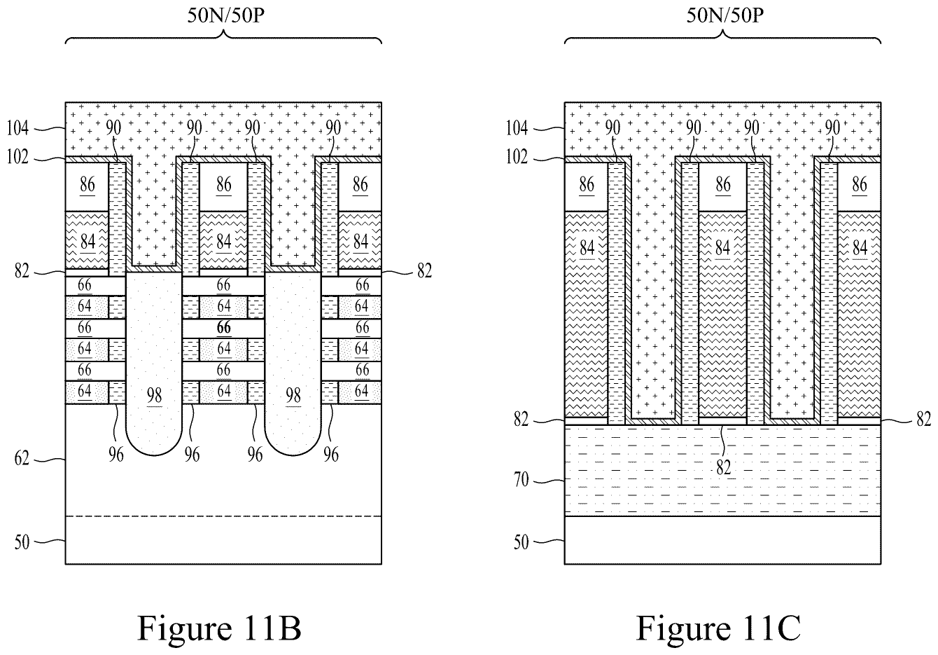

In FIGS. 11A-11C, a first ILD 104 is deposited over the epitaxial source/drain regions 98, the gate spacers 90, and the masks 86 (if present) or the dummy gates 84. The first ILD 104 may be formed of a dielectric material, which may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 102 is formed between the first ILD 104 and the epitaxial source/drain regions 98, the gate spacers 90, and the masks 86 (if present) or the dummy gates 84. The CESL 102 may be formed of a dielectric material having a high etching selectivity from the etching of the first ILD 104, such as, silicon nitride, silicon oxide, silicon oxynitride, or the like, which may be formed by any suitable deposition process, such as CVD, ALD, or the like.

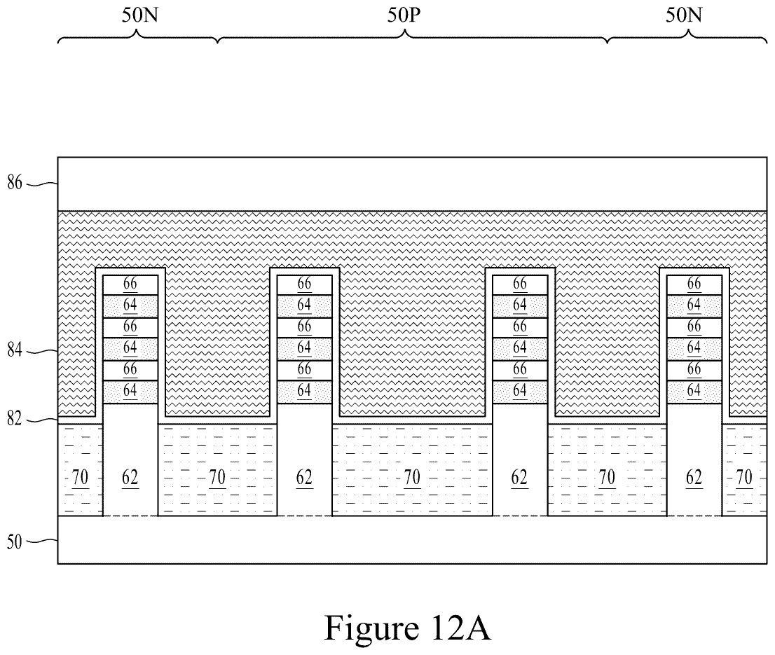

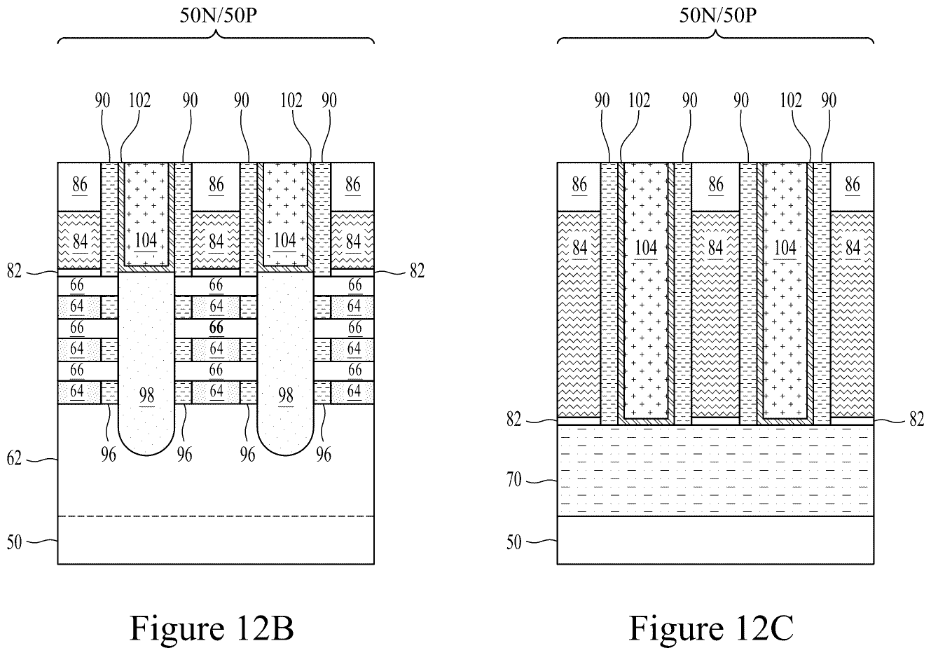

In FIGS. 12A-12C, a removal process is performed to level the top surfaces of the first ILD 104 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the first ILD 104, the gate spacers 90, and the masks 86 (if present) or the dummy gates 84 are substantially coplanar (within process variations). Accordingly, the top surfaces of the masks 86 (if present) or the dummy gates 84 are exposed through the first ILD 104.

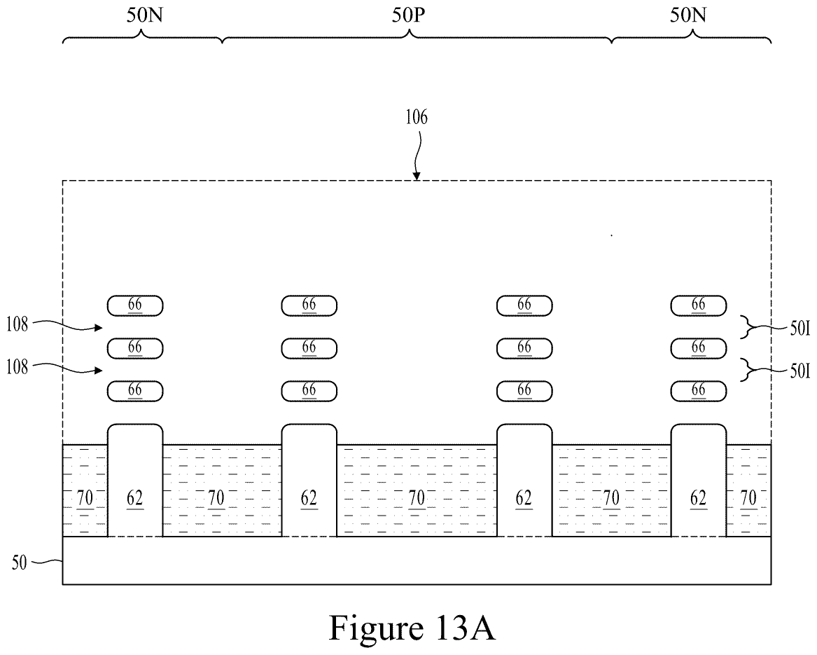

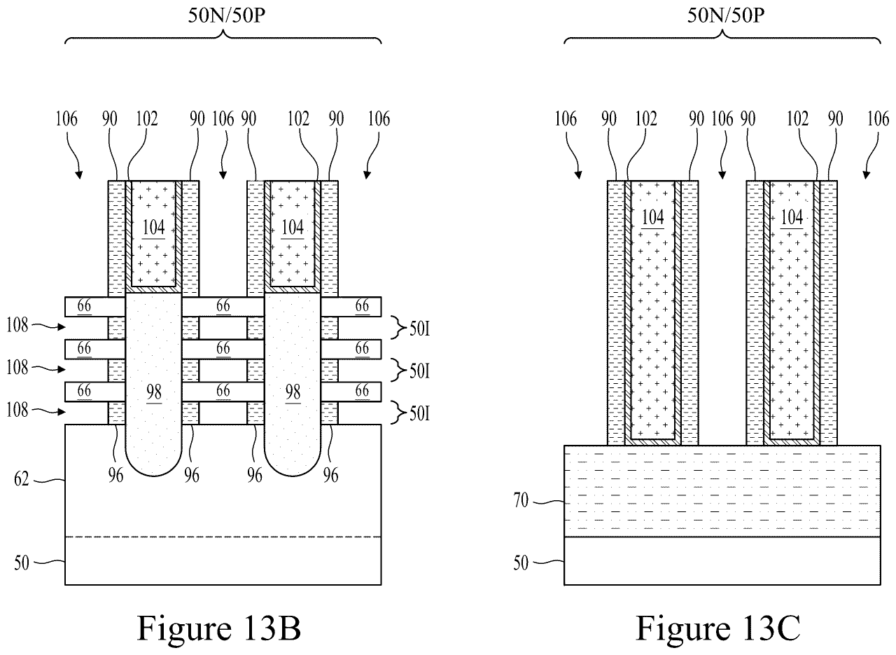

In FIGS. 13A-13C, the masks 86 (if present) and the dummy gates 84 are removed in one or more etching steps, so that recesses 106 are formed. Portions of the dummy dielectrics 82 in the recesses 106 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 104 and the gate spacers 90. Each recesses 106 exposes and/or overlies portions of nanostructures 64, 66, which act as the channel regions in subsequently completed nanostructure-FETs. Portions of the nanostructures 64, 66 which act as the channel regions are disposed between neighboring pairs of the epitaxial source/drain regions 98. During the removal, the dummy dielectrics 82 may be used as etch stop layers when the dummy gates 84 are etched. The dummy dielectrics 82 may then be removed after the removal of the dummy gates 84.

The remaining portions of the first nanostructures 64 are then removed to form openings 108 in regions 50I between the second nanostructures 66. The remaining portions of the first nanostructures 64 can be removed by any acceptable etch process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second nanostructures 66 and expand the openings 108. The exposed portions of the second nanostructures 66 may be rounded after the trim and/or removal processes. The recesses 106 and the openings 108 are between the gate spacers 90.

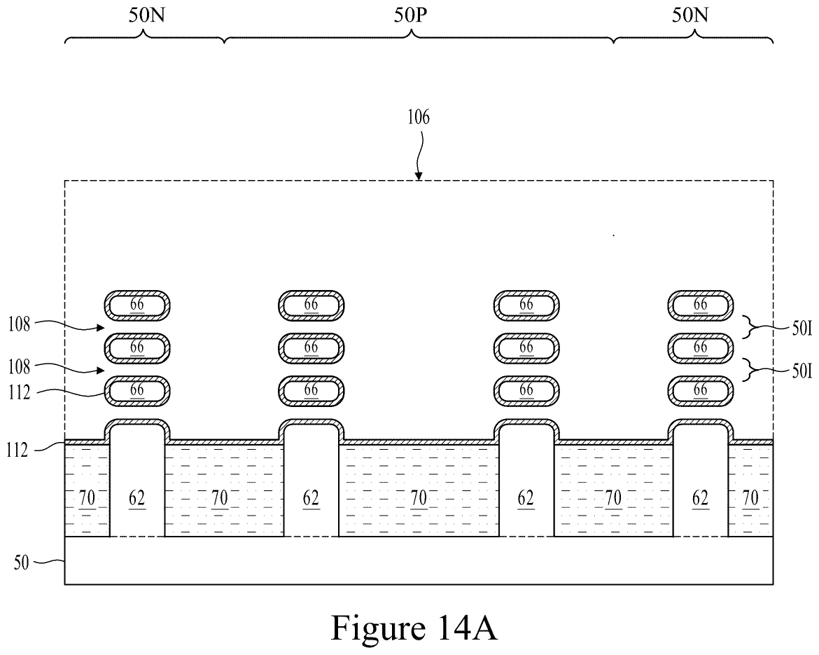

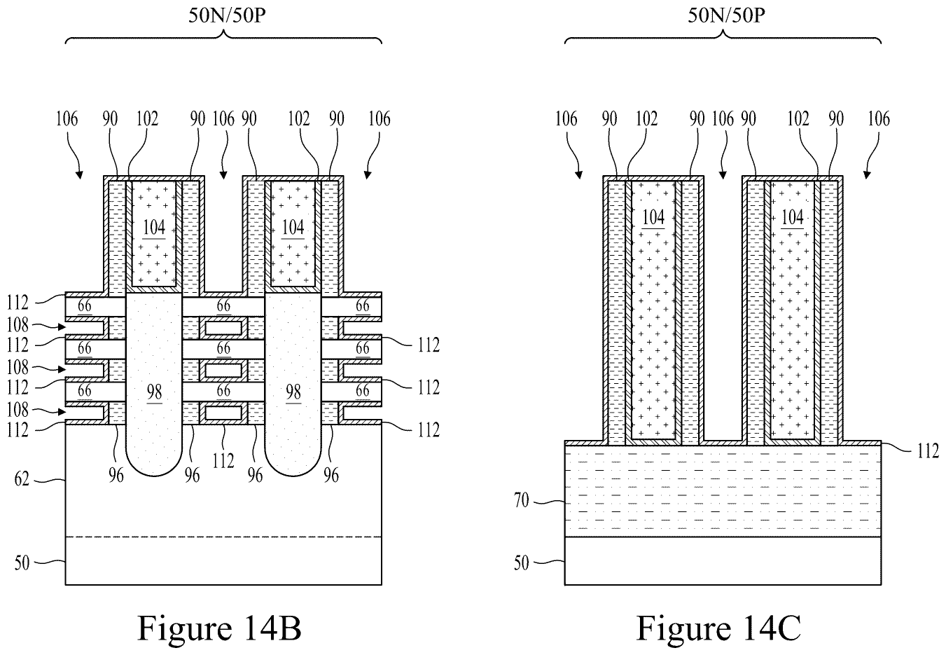

FIGS. 14A-27C illustrate a process in which a gate dielectric layer 112 and a gate electrode layer 114 for replacement gates are formed in the recesses 106 and the openings 108. Specifically, a gate structure is formed in the recesses 106, and that gate structure extends across at least one n-type region 50N and an adjacent p-type region 50P. The gate structure may be formed around the second nanostructures 66 in the adjacent regions 50N, 50P, such that the gate structure is coupled to the channel regions of the devices in the adjacent regions 50N, 50P. Such coupling may be advantageous in some CMOS processes. For example, when the nanostructure-FETs are used to form inverters, gates, memories, and the like, using a single gate structure to control multiple channel regions may allow for a reduction in the quantity of gate contacts.

In FIGS. 14A-14C, a gate dielectric layer 112 is conformally formed on the channel regions of the second nanostructures 66, such that it conformally lines the recesses 106 and the openings 108. Specifically, the gate dielectric layer 112 is formed on the top surfaces of the fins 62; on the top surfaces, the sidewalls, and the bottom surfaces of the second nanostructures 66; and on the sidewalls of the gate spacers 90. The gate dielectric layer 112 wraps around all (e.g., four) sides of the second nanostructures 66. The gate dielectric layer 112 may also be formed on the top surfaces of the first ILD 104 and the gate spacers 90, and may be formed on the sidewalls of the fins 62 (e.g., in embodiments where the top surfaces of the STI regions 70 are below the top surfaces of the fins 62). The gate dielectric layer 112 may include an oxide such as silicon oxide or a metal oxide, a silicate such as a metal silicate, combinations thereof, multi-layers thereof, or the like. The gate dielectric layer 112 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 112 may include molecular-beam deposition (MBD), ALD, PECVD, and the like. Although a single-layered gate dielectric layer 112 is illustrated, the gate dielectric layer 112 may include multiple layers, such as an interfacial layer and an overlying high-k dielectric layer. The interfacial layer may be formed of silicon oxide and the high-k dielectric layer may be formed of hafnium oxide. The gate dielectric layer 112 may include any acceptable number of layers.

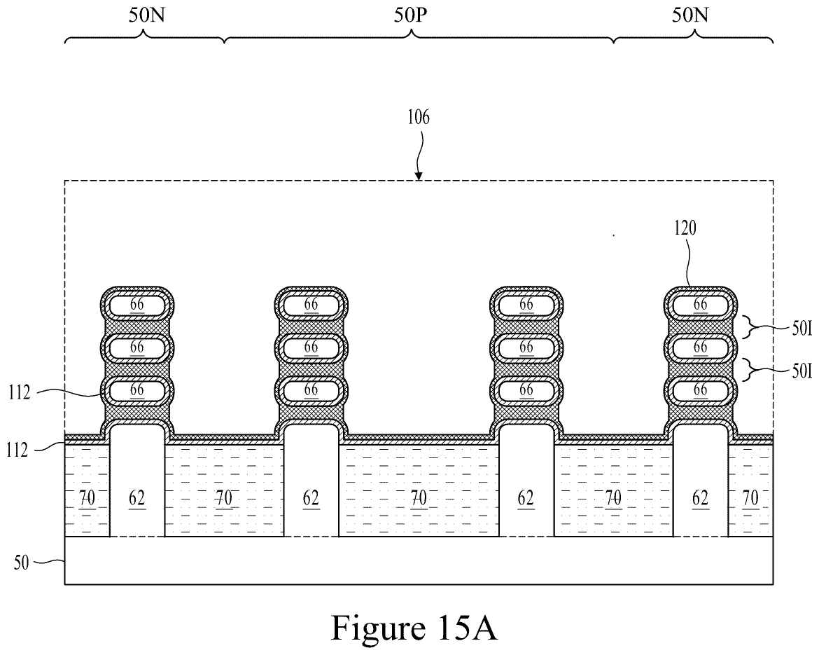

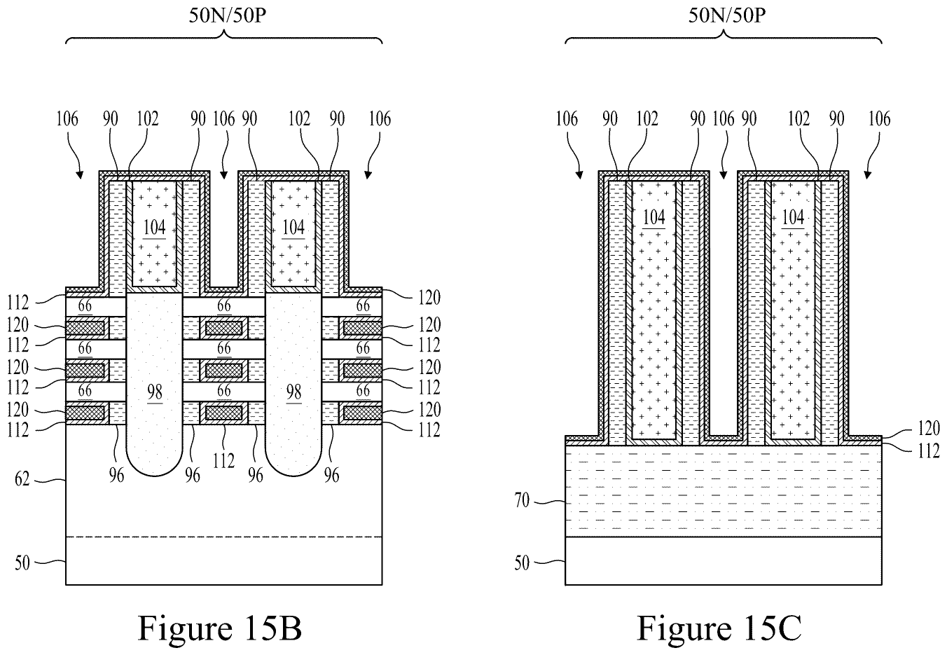

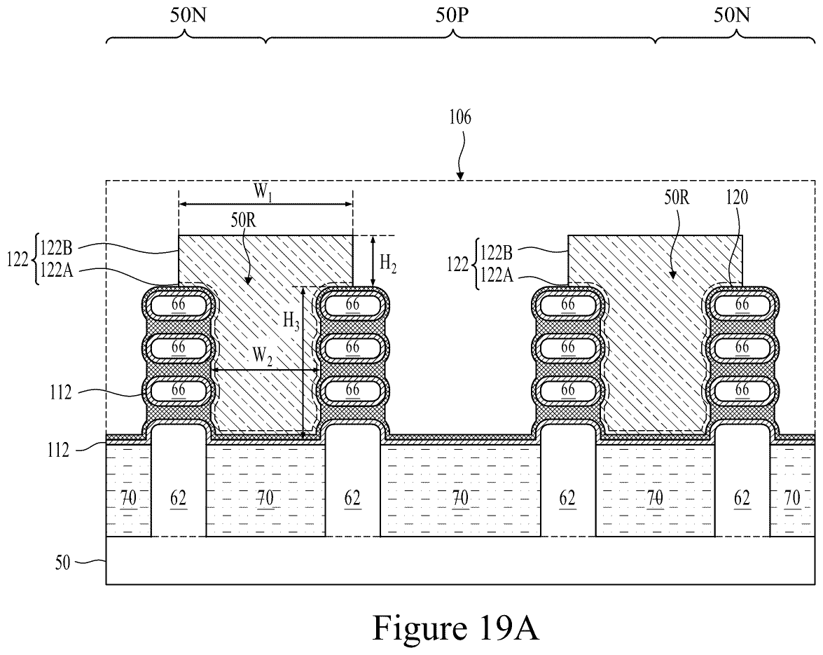

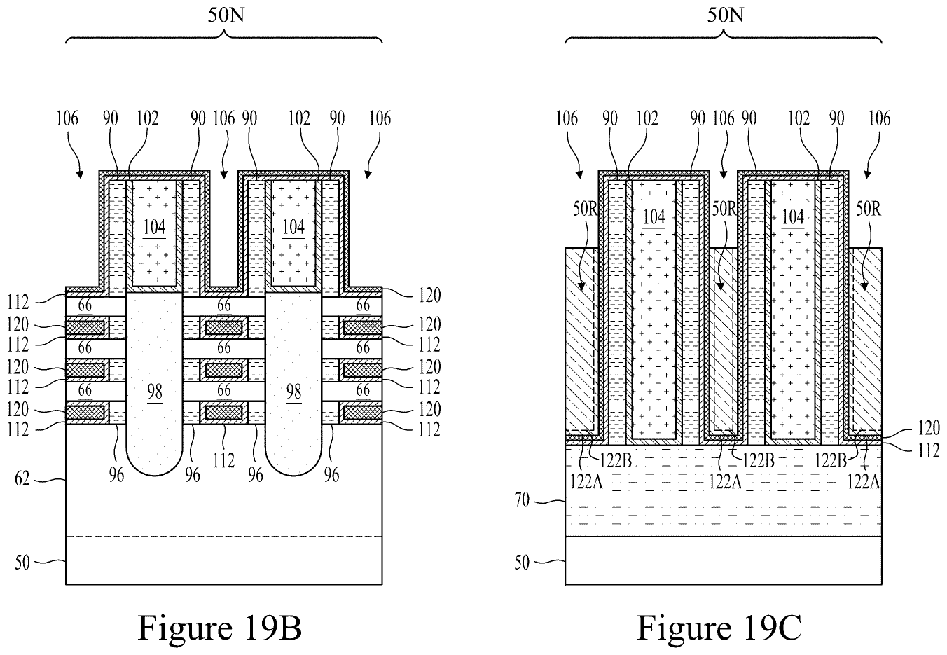

FIGS. 15A-19C illustrate a process in which dielectric walls 122 (see FIG. 19A-19C) are formed between the second nanostructures 66 in the n-type regions 50N and the second nanostructures 66 in the adjacent p-type regions 50P. Specifically, each dielectric wall 122 is formed in a recess 106 at the boundary of a pair of adjacent regions 50N, 50P. In some embodiments, the dielectric wall 122 is within 50 nm of the boundary of the adjacent regions 50N, 50P. The height of the dielectric walls 122 will be less than the height of the recesses 106, such that the subsequently formed gate electrodes in the recesses 106 extend over the dielectric walls 122.

In FIGS. 15A-15C, a liner layer 120 is conformally formed on the gate dielectric layer 112, such that it conformally lines the recesses 106 and the openings 108. The liner layer 120 is formed of a dielectric material that can be selectively etched in a subsequent removal process. Acceptable dielectric materials may include aluminum oxide, aluminum nitride, silicon oxide, silicon nitride, silicon carbonitride, silicon oxycarbonitride, or the like, which may be formed by a deposition process such as chemical vapor deposition (CVD), atomic layer deposition (ALD), or the like. The liner layer 120 is deposited until it is thick enough to fill the remaining portions of the regions 50I between the second nanostructures 66. Specifically, respective portions of the gate dielectric layer 112 wrap around respective second nanostructures 66, and respective portions of the liner layer 120 wrap around the respective portions of the gate dielectric layer 112, thereby completely filling areas between the respective second nanostructures 66. In some embodiments, the liner layer 120 has a thickness in the range of 1 nm to 6 nm.

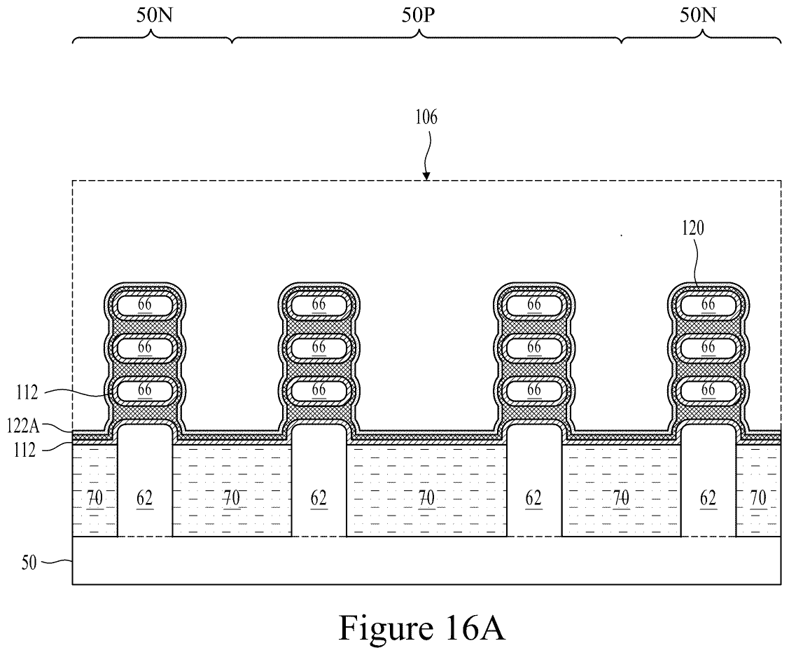

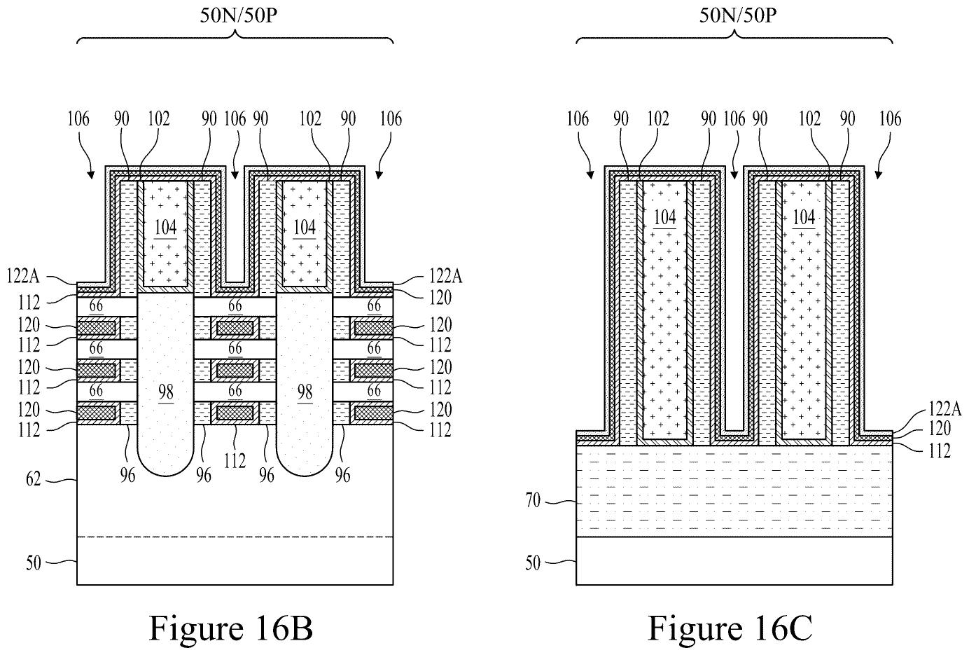

In FIGS. 16A-16C, a liner layer 122A for the dielectric walls is conformally formed on the liner layer 120, such that it conformally lines the recesses 106. The liner layer 122A is formed of a dielectric material having a high etching selectivity from the etching of the liner layer 120. Acceptable dielectric materials may include oxides such as silicon oxide or aluminum oxide, nitrides such as silicon nitride or aluminum nitride, or the like, which may be formed by a deposition process such as chemical vapor deposition (CVD), atomic layer deposition (ALD), or the like. As will be subsequently described in greater detail, a fill layer for a dielectric wall will be selectively deposited on the liner layer 122A in the recesses 106, and the liner layer 122A will act as a seed layer for the selective deposition of the liner layer. The liner layer 122A is thin, and is deposited to a lesser thickness than the subsequently formed filler layer. In some embodiments, the liner layer 122A has a thickness in the range of 1 nm to 5 nm.

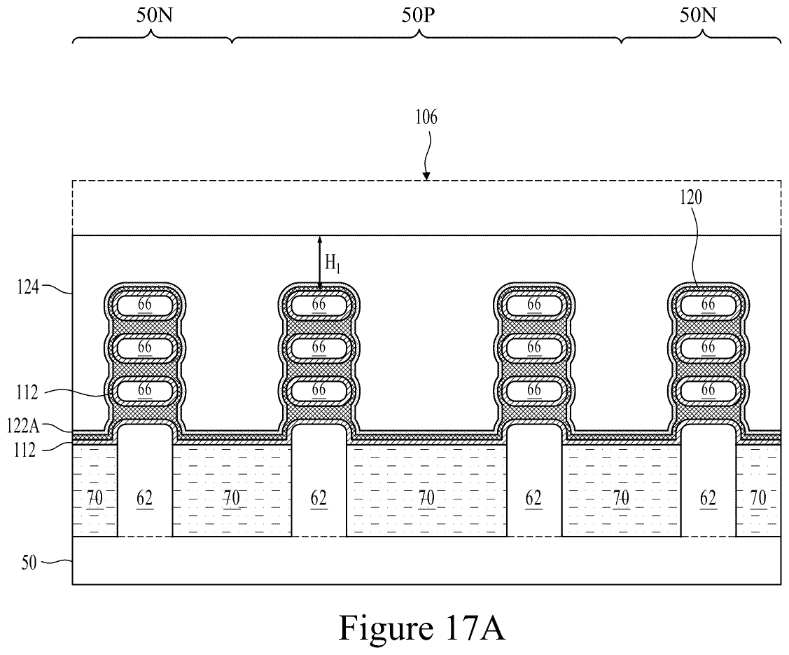

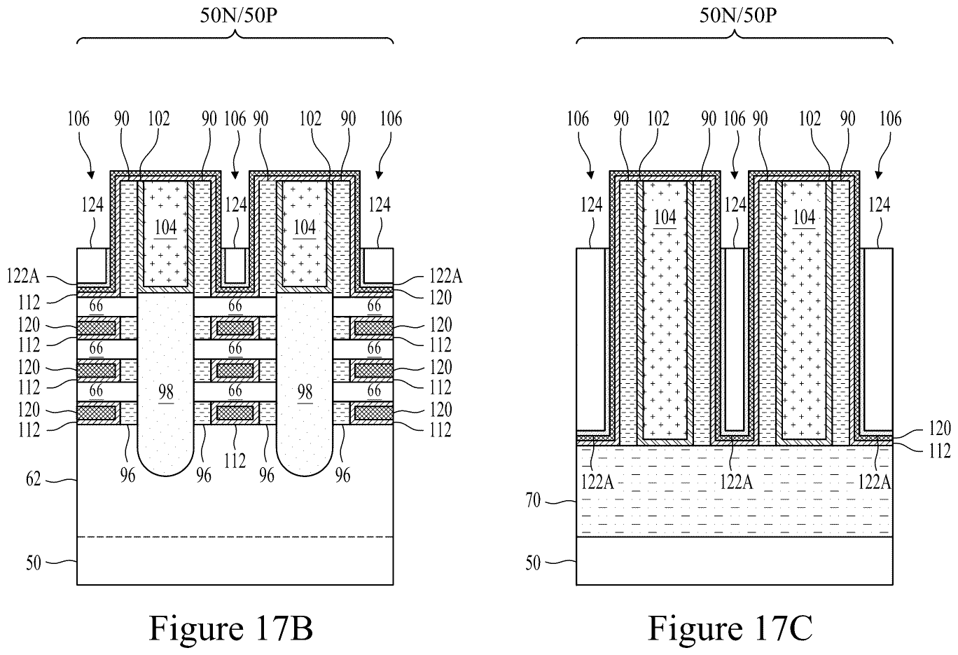

In FIGS. 17A-17C, the liner layer 122A is pulled back to remove the portions of the liner layer 122A outside of the recesses 106 and to reduce the height of the liner layer 122A in the recesses 106. The liner layer 122A may be pulled back with any acceptable etch process that is selective to the liner layer 122A (e.g., selectively etches the material of the liner layer 122A at a faster rate than the materials of the liner layer 120 and the gate dielectric layer 112). The etch process may be isotropic. A mask 124, such as a photoresist, may be formed in the recesses 106 and used as an etching mask when etching the liner layer 122A. The photoresist can be formed by using a spin-on technique and can be patterned using acceptable photolithography techniques. The height of the mask 124 is less than the depth of the recesses 106. The height of the mask 124 in the recesses 106 determines the height of the liner layer 122A remaining in the recesses 106. After the etching, the mask 124 may be removed, such as by an acceptable ashing process when the mask 124 is a photoresist. As previously noted, a fill layer for a dielectric wall will be selectively deposited on the liner layer 122A. The height of the liner layer 122A remaining in the recesses 106 thus determines the height of the dielectric walls. The height H1 of the liner layer 122A is large enough that the liner layer 122A extends above the top surfaces of the second nanostructures 66. In some embodiments, the liner layer 122A extends a height H1 in the range of 5 nm to 20 nm above the top surfaces of the second nanostructures 66.

In FIGS. 18A-18C, the liner layer 122A is patterned to remove portions of the liner layer 122A in undesired locations. The liner layer 122A may be patterned with any acceptable etch process that is selective to the liner layer 122A (e.g., selectively etches the material of the liner layer 122A at a faster rate than the materials of the liner layer 120 and the gate dielectric layer 112). The etch process may be isotropic. A mask 126, such as a photoresist, may be formed in the recesses 106 and used as an etching mask when etching the liner layer 122A. The photoresist can be formed by using a spin-on technique and can be patterned using acceptable photolithography techniques. After the etching, the mask 126 may be removed, such as by an acceptable ashing process when the mask 126 is a photoresist. In some embodiments, the ashing process is performed by annealing the mask 126 at a temperature in the range of 150° C. to 180° C. in an environment containing nitrogen, hydrogen, or oxygen gas. As subsequently described in greater detail, dielectric walls will extend above a portion of the second nanostructures 66 in an n-type region 50N, above a portion of the second nanostructures 66 in an adjacent p-type region 50P, and in regions 50R between the second nanostructures 66 in those adjacent regions 50N, 50P. The liner layer 122A is patterned so that it remains in those regions where the dielectric walls are desired. As such, each portion of the liner layer 122A overlaps a portion of the second nanostructures 66 in an n-type region 50N, overlaps a portion of the second nanostructures 66 in a p-type region 50P, and is in a region 50R between the second nanostructures 66 in that n-type region 50N and the second nanostructures 66 in that p-type region 50P.

In FIGS. 19A-19C, fill layers 122B for the dielectric walls are selectively deposited on the remaining portions of the liner layer 122A. The fill layers 122B may be formed of the same dielectric material as the liner layer 122A (e.g., an oxide, a nitride, or the like). The fill layers 122B are formed by a selective deposition process, such as a selective chemical vapor deposition (CVD) that forms a desired dielectric material at nucleation sites of the liner layer 122A. The fill layers 122B are selectively deposited on the liner layer 122A until they merge in the regions 50R between the second nanostructures 66 in adjacent regions 50N, 50P. After the fill layers 122B are deposited, an etch-back may be performed to remove any dielectric material that was deposited in undesired locations (e.g., not on the liner layer 122A). The etch-back may include any acceptable etch process that is selective to the fill layers 122B (e.g., selectively etches the material of the fill layers 122B at a faster rate than the materials of the liner layer 120 and the gate dielectric layer 112).

Each fill layer 122B and an underlying remaining portion of the liner layer 122A forms a dielectric wall 122. In the cross-section of FIG. 19A, the dielectric walls 122 have lower portions in the regions 50R between the second nanostructures 66 in adjacent regions 50N, 50P. The dielectric walls 122 have upper portions above the second nanostructures 66. The upper portions of the dielectric walls 122 overlap the second nanostructures 66 and are shelter features that will protect the second nanostructures 66 during a subsequent gate cut process. The width of the upper portions of the dielectric walls 122 is greater than the width of the lower portions of the dielectric walls 122. In some embodiments, the upper portions of the dielectric walls 122 have a width W1 in the range of 30 nm to 110 nm and have a height H2 in the range of 5 nm to 20 nm. In some embodiments, the lower portions of the dielectric walls 122 have a width W2 in the range of 15 nm to 50 nm and have a height Hg in the range of 30 nm to 70 nm.

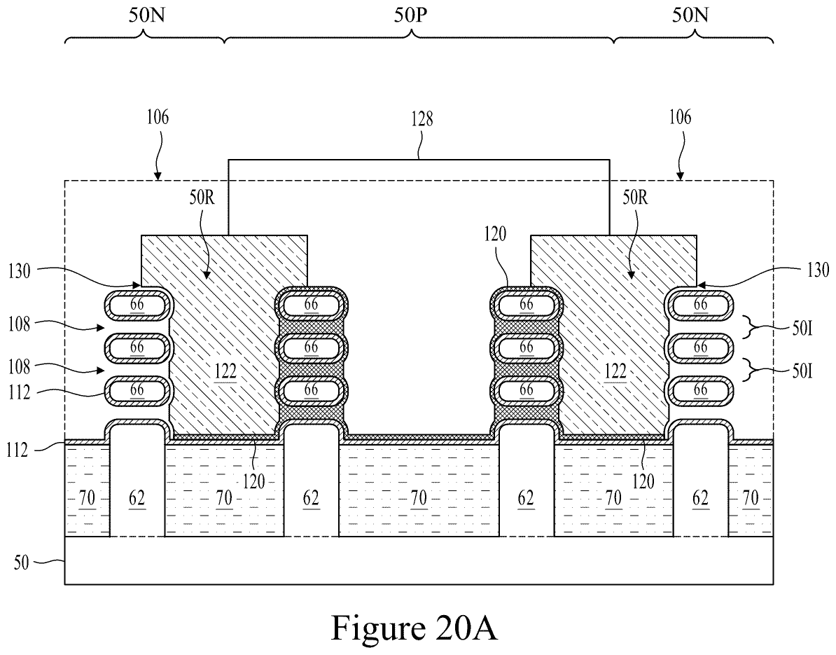

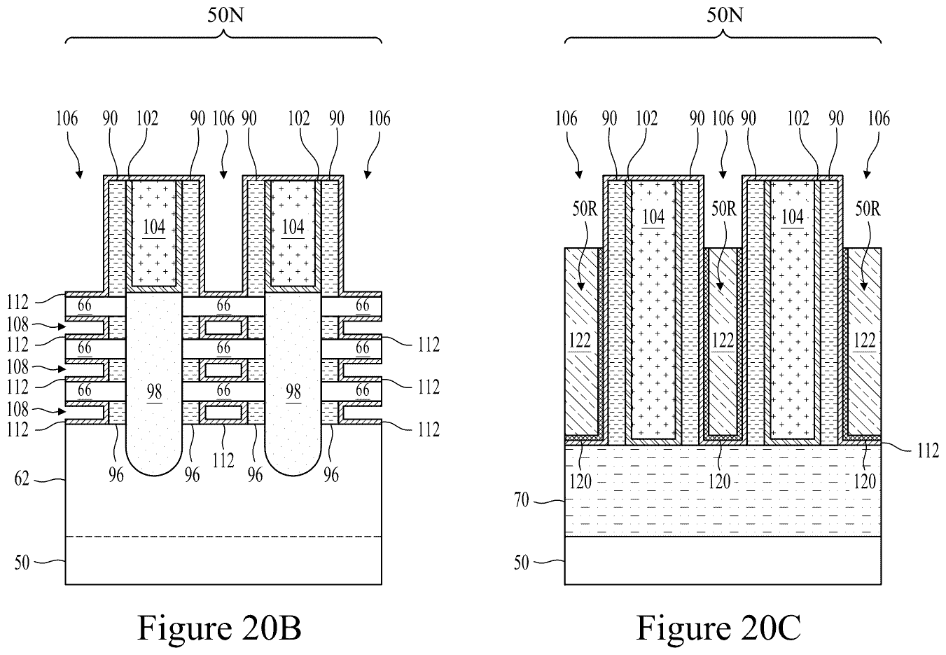

In FIGS. 20A-20C, the liner layer 120 is patterned to remove portions of the liner layer 120 in the n-type regions 50N. Specifically, the portions of the liner layer 120 uncovered by the dielectric walls 122 in the n-type regions 50N are removed. Removing the portions of the liner layer 120 in the n-type regions 50N re-forms the openings 108 between the second nanostructures 66 in the n-type regions 50N. Additionally, removing the portions of the liner layer 120 in the n-type regions 50N forms openings 130 between the dielectric walls 122 and the portions of the gate dielectric layer 112 in the n-type regions 50N. The portions of the liner layer 120 in the p-type regions 50P are not removed at this step. The liner layer 120 may be patterned with any acceptable etch process that is selective to the liner layer 120 (e.g., selectively etches the material of the liner layer 120 at a faster rate than the materials of the dielectric walls 122 and the gate dielectric layer 112). The etch process may be isotropic. For example, when the liner layer 120 is formed of aluminum oxide, the etch process may be a wet etch using ammonium hydroxide (NH₄OH), dilute hydrofluoric (dHF) acid, or the like. A mask 128, such as a photoresist, may be formed in the p-type regions 50P and used as an etching mask when etching the liner layer 120. The photoresist can be formed by using a spin-on technique and can be patterned using acceptable photolithography techniques.

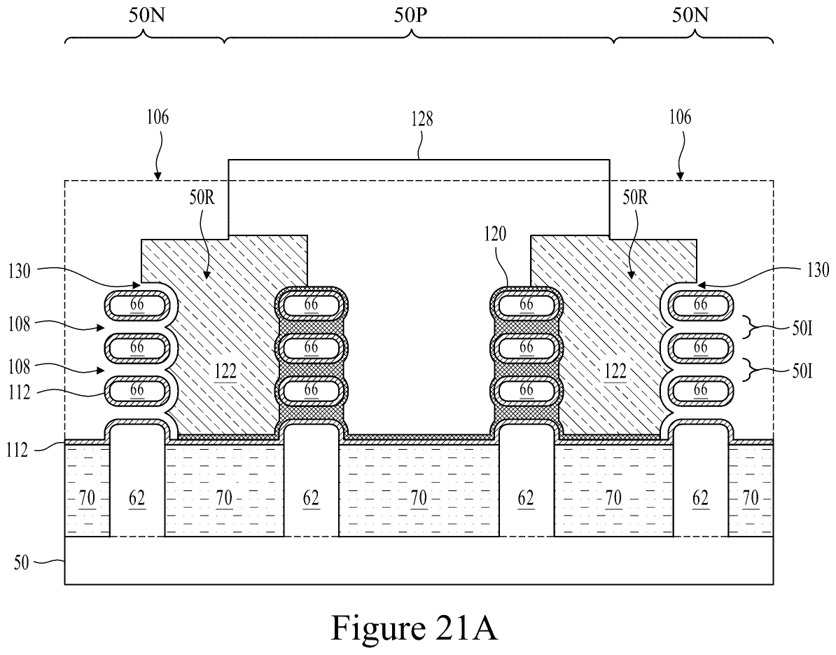

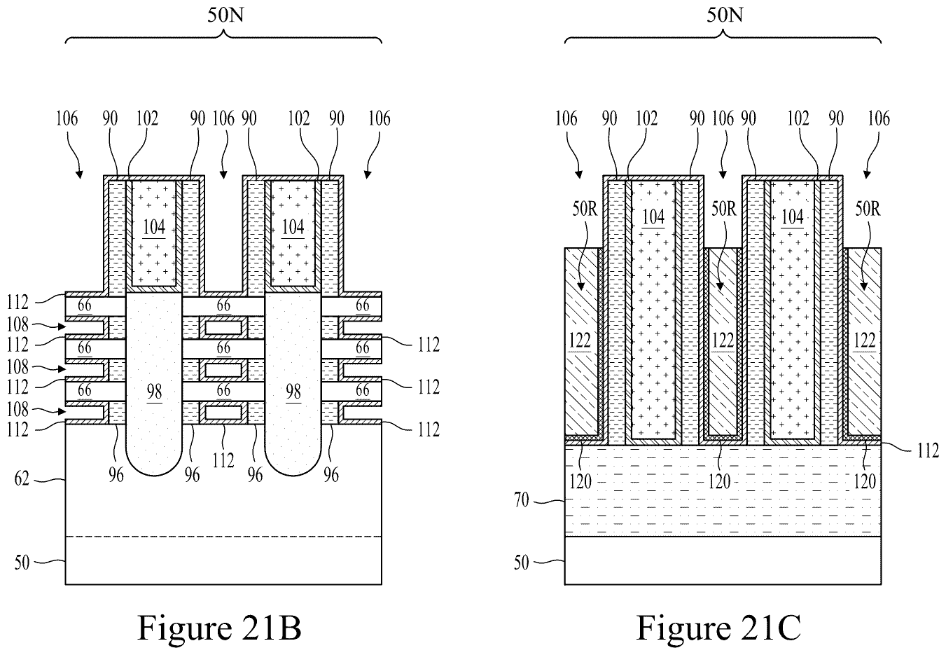

In FIGS. 21A-21C, the dielectric walls 122 are optionally trimmed to expand the openings 130 in the n-type regions 50N. The dielectric walls 122 may be trimmed with any acceptable etch process that is selective to the dielectric walls 122 (e.g., selectively etches the material of the dielectric walls 122 at a faster rate than the materials of the gate dielectric layer 112). After trimming the width of the openings 130 may be less than the width of the openings 108. The liner layer 120 may (or may not) also be trimmed by the etch used to trim the dielectric walls 122. The mask 128 used to pattern the liner layer 120 may also be used as an etching mask when trimming the dielectric walls 122 and the liner layer 120 (when applicable). After the trimming of the dielectric walls 122 and/or the patterning of the liner layer 120, the mask 128 may be removed, such as by an acceptable ashing process when the mask 128 is a photoresist.

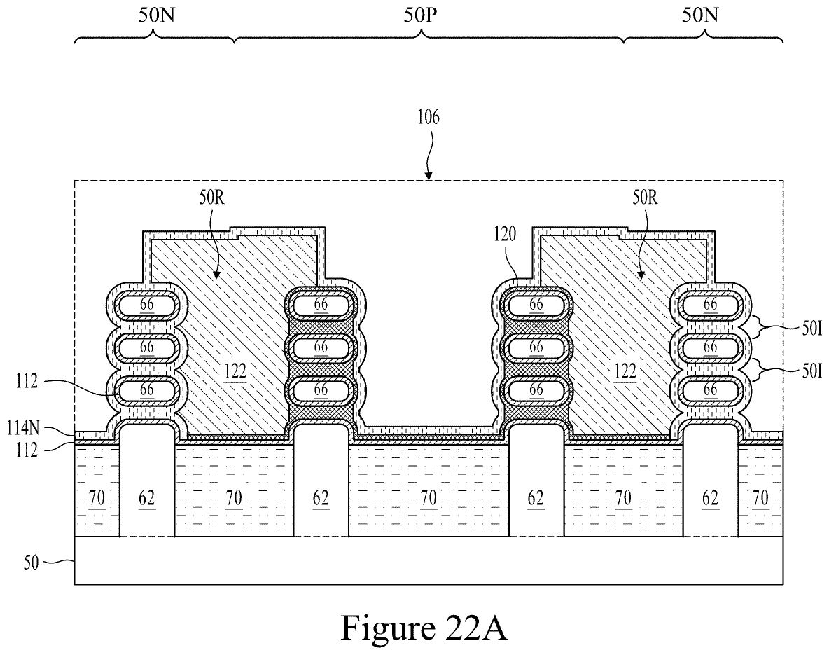

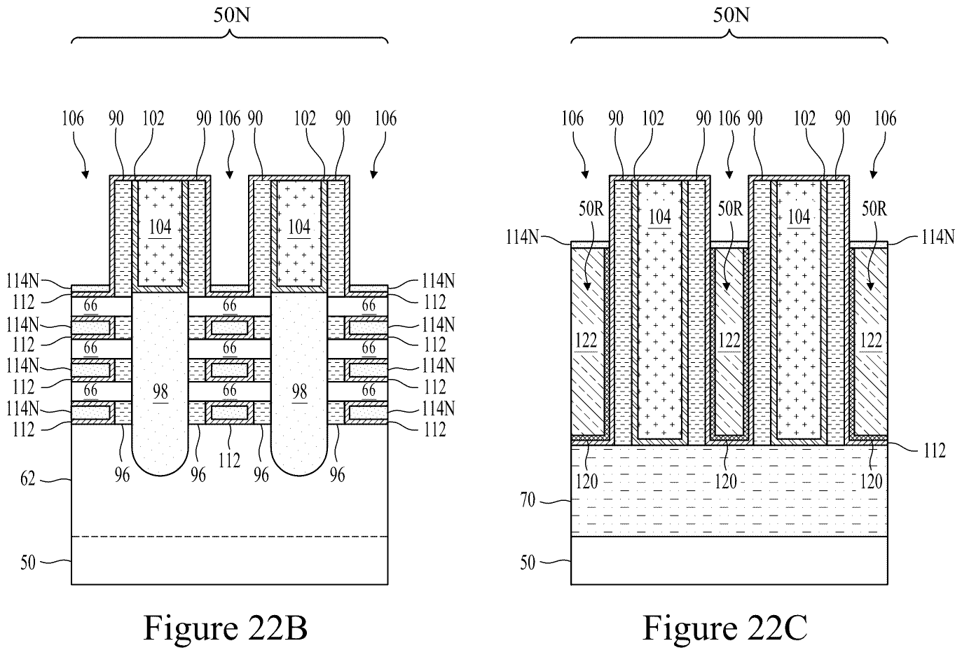

In FIGS. 22A-22C, an n-type work function tuning layer 114N is conformally formed on the gate dielectric layer 112, such that it conformally lines the recesses 106, the openings 108, and the openings 130 in the n-type regions 50N. The n-type work function tuning layer 114N is formed of an n-type work function material (NWFM) that is acceptable to tune a work function of a nanostructure-FET to a desired amount given the application of the device to be formed, and may be formed by any acceptable deposition process. In some embodiments, the n-type work function tuning layer 114N is formed of titanium aluminum, titanium aluminum carbide, tantalum aluminum, tantalum carbide, combinations thereof, or the like, which may be formed by a deposition process such as ALD, CVD, PVD, or the like. In some embodiments, the n-type work function tuning layer 114N has a thickness in the range of 15 Å to 50 Å.

The n-type work function tuning layer 114N may be formed by a conformal deposition process such that it is deposited on the dielectric walls 122, the liner layer 120, the gate dielectric layer 112, and the gate spacers 90. Because the liner layer 120 was removed from the n-type regions 50N but not the p-type regions 50P, the n-type work function tuning layer 114N is formed around the second nanostructures 66 in the n-type regions 50N but not the p-type regions 50P.

The n-type work function tuning layer 114N fills the remaining portions of the regions 50I between the second nanostructures 66 in the n-type regions 50N. Specifically, the n-type work function tuning layer 114N is deposited on the gate dielectric layers 112 in the n-type regions 50N until it is thick enough to merge and seam together in the openings 108 and the openings 130. Interfaces (not separately illustrated) may be formed by the contacting of adjacent portions of the n-type work function tuning layer 114N (e.g., those portions around the second nanostructures 66 in the n-type regions 50N). The openings 108 and the openings 130 in the n-type regions 50N are thus completely filled by respective portions of the gate dielectric layer 112 and the n-type work function tuning layer 114N. Specifically, respective portions of the gate dielectric layer 112 wrap around respective second nanostructures 66 in the n-type regions 50N and respective portions of the n-type work function tuning layer 114N wrap around the respective portions of the gate dielectric layer 112, thereby completely filling areas between the respective second nanostructures 66.

In FIGS. 23A-23C, the n-type work function tuning layer 114N is patterned to remove portions of the n-type work function tuning layer 114N in the p-type regions 50P. The n-type work function tuning layer 114N may be patterned with any acceptable etch process that is selective to the n-type work function tuning layer 114N (e.g., selectively etches the material of the n-type work function tuning layer 114N at a faster rate than the materials of the dielectric walls 122 and the gate dielectric layer 112). The etch process may be isotropic. A mask 132, such as a photoresist, may be formed in the p-type regions 50P and used as an etching mask when etching the n-type work function tuning layer 114N. The photoresist can be formed by using a spin-on technique and can be patterned using acceptable photolithography techniques.

The liner layer 120 is then patterned to remove portions of the liner layer 120 in the p-type regions 50P. Removing the portions of the liner layer 120 in the p-type regions 50P re-forms the openings 108 between the second nanostructures 66 in the p-type regions 50P. Additionally, removing the portions of the liner layer 120 in the p-type regions 50P forms openings 130 between the dielectric walls 122 and the portions of the gate dielectric layer 112 in the p-type regions 50P. The liner layer 120 may be patterned with any acceptable etch process that is selective to the liner layer 120 (e.g., selectively etches the material of the liner layer 120 at a faster rate than the materials of the dielectric walls 122 and the gate dielectric layer 112). The etch process may be isotropic. For example, when the liner layer 120 is formed of aluminum oxide, the etch process may be a wet etch using ammonium hydroxide (NH₄OH), dilute hydrofluoric (dHF) acid, or the like. The mask 132 used to pattern the n-type work function tuning layer 114N may also be used as an etching mask when patterning the liner layer 120. The remaining portions of the liner layer 120 are between the dielectric walls 122 and the STI regions 70.

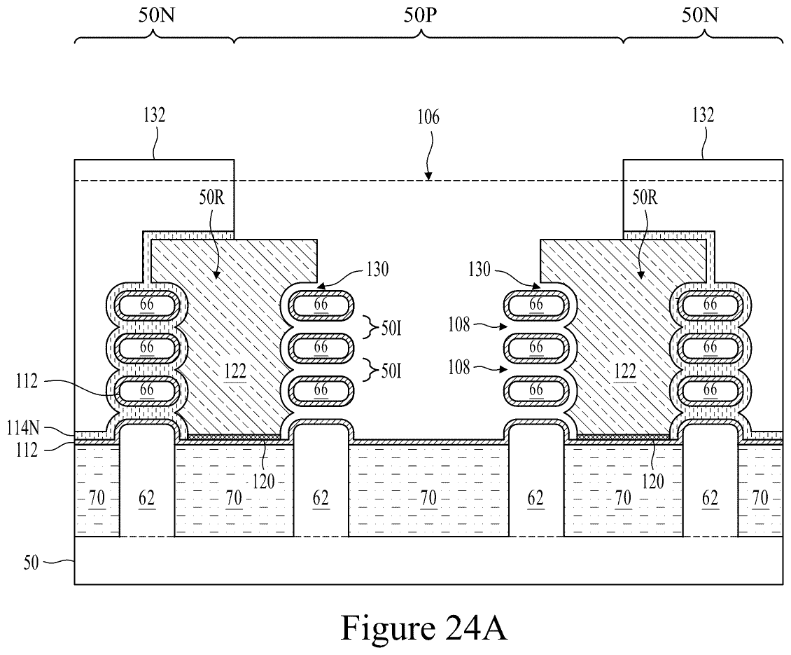

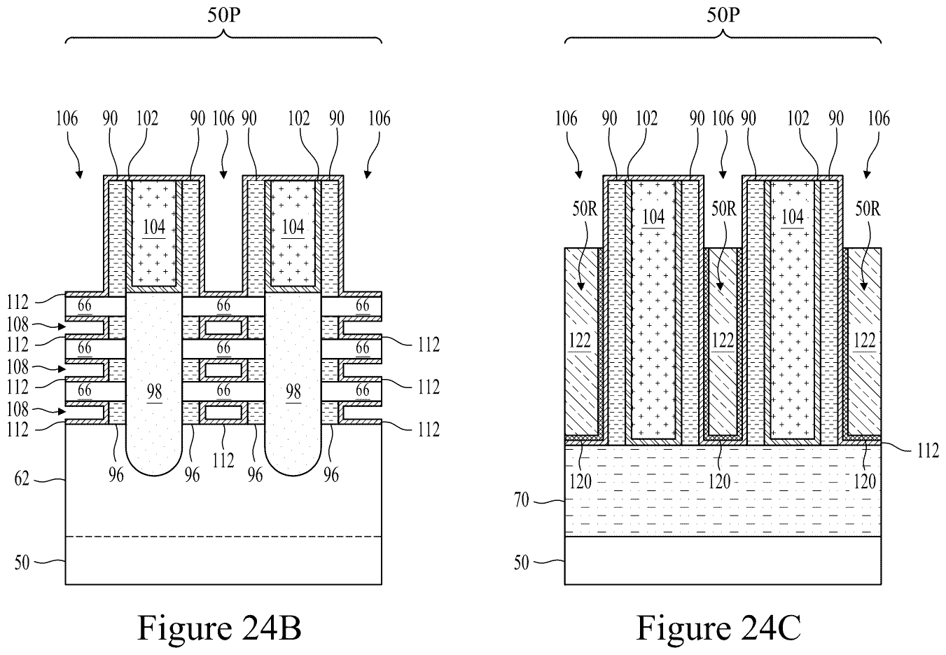

In FIGS. 24A-24C, the dielectric walls 122 are optionally trimmed to expand the openings 130 in the p-type regions 50P. The dielectric walls 122 may be trimmed with any acceptable etch process that is selective to the dielectric walls 122 (e.g., selectively etches the material of the dielectric walls 122 at a faster rate than the materials of the gate dielectric layer 112). After trimming the width of the openings 130 may be less than the width of the openings 108. The liner layer 120 may (or may not) also be trimmed by the etch used to trim the dielectric walls 122. The mask 132 used to pattern the liner layer 120 may also be used as an etching mask when trimming the dielectric walls 122. After the patterning of the liner layer 120, the removal of the n-type work function tuning layer 114N and/or the trimming of the dielectric walls 122, the mask 132 may be removed, such as by an acceptable ashing process when the mask 132 is a photoresist.

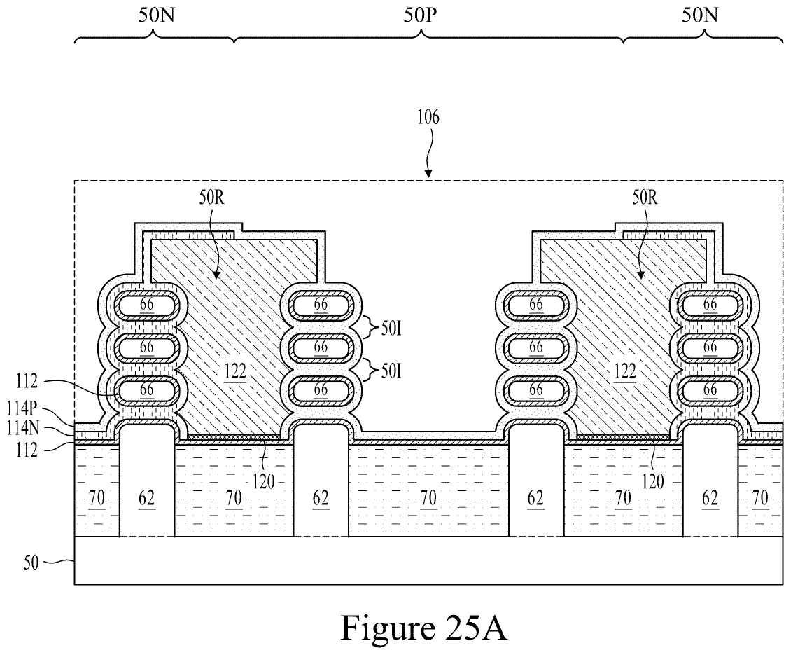

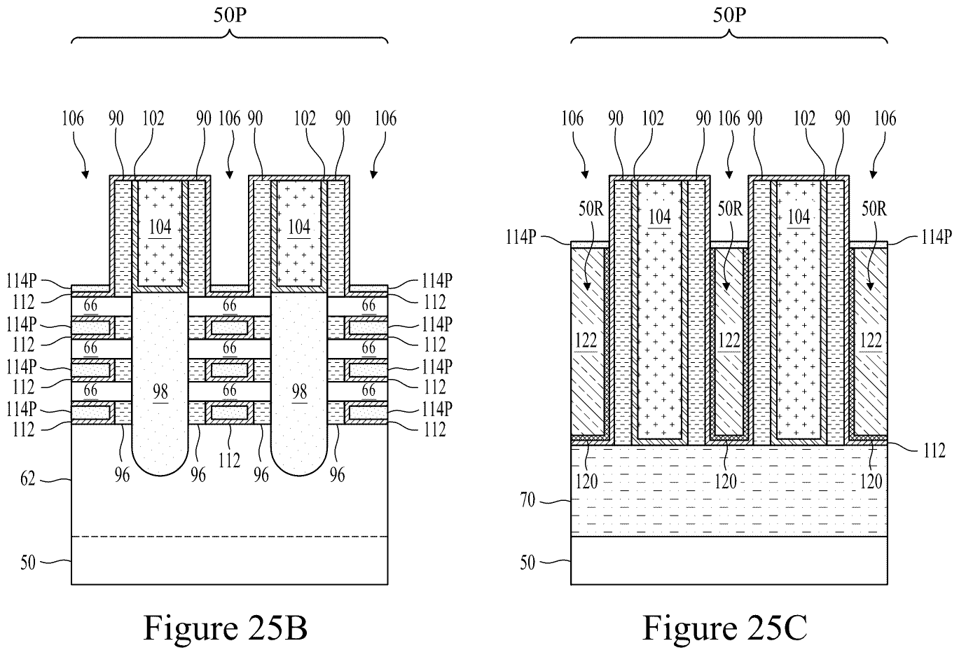

In FIGS. 25A-25C, a p-type work function tuning layer 114P is conformally formed on the gate dielectric layer 112, such that it conformally lines the recesses 106, the openings 108, and the openings 130 in the p-type regions 50P. The p-type work function tuning layer 114P formed of a p-type work function material (PWFM) that is acceptable to tune a work function of a nanostructure-FET to a desired amount given the application of the device to be formed, and may be formed by any acceptable deposition process. In some embodiments, the p-type work function tuning layer 114P is formed of titanium nitride, tantalum nitride, combinations thereof, or the like, which may be formed by a deposition process such as PVD, ALD, CVD, or the like. In some embodiments, the p-type work function tuning layer 114P has a thickness in the range of 15 Å to 50 Å.

The p-type work function tuning layer 114P may be formed by a conformal deposition process such that it is deposited on the dielectric walls 122, the liner layer 120, the n-type work function tuning layer 114N, the gate dielectric layer 112, and the gate spacers 90. Because the liner layer 120 was removed from the p-type regions 50P, the p-type work function tuning layer 114P is formed around the second nanostructures 66 in the p-type regions 50P.

The p-type work function tuning layer 114P fills the remaining portions of the regions 50I between the second nanostructures 66 in the p-type regions 50P. Specifically, the p-type work function tuning layer 114P is deposited on the gate dielectric layers 112 in the p-type regions 50P until it is thick enough to merge and seam together in the openings 108 and the openings 130. Interfaces (not separately illustrated) may be formed by the contacting of adjacent portions of the p-type work function tuning layer 114P (e.g., those portions around the second nanostructures 66 in the p-type regions 50P). The openings 108 and the openings 130 in the p-type regions 50P are thus completely filled by respective portions of the gate dielectric layer 112 and the p-type work function tuning layer 114P. Specifically, respective portions of the gate dielectric layer 112 wrap around respective second nanostructures 66 in the p-type regions 50P and respective portions of the p-type work function tuning layer 114P wrap around the respective portions of the gate dielectric layer 112, thereby completely filling areas between the respective second nanostructures 66.

In the illustrated embodiment, the p-type work function tuning layer 114P is formed in both the p-type regions 50P and the n-type regions 50N, and the n-type work function tuning layer 114N is formed in the n-type regions 50N but not the p-type regions 50P. The resulting gate structures in each region thus include different materials and a different number of layers. The gate structures in the n-type regions 50N may include more work function tuning layers than the gate structures in the p-type regions 50P. Other structures of work function tuning layer may be utilized in the different regions. For example, the p-type work function tuning layer 114P may also be patterned to remove portions of the p-type work function tuning layer 114P in the n-type regions 50N, thereby exposing the n-type work function tuning layer 114N.

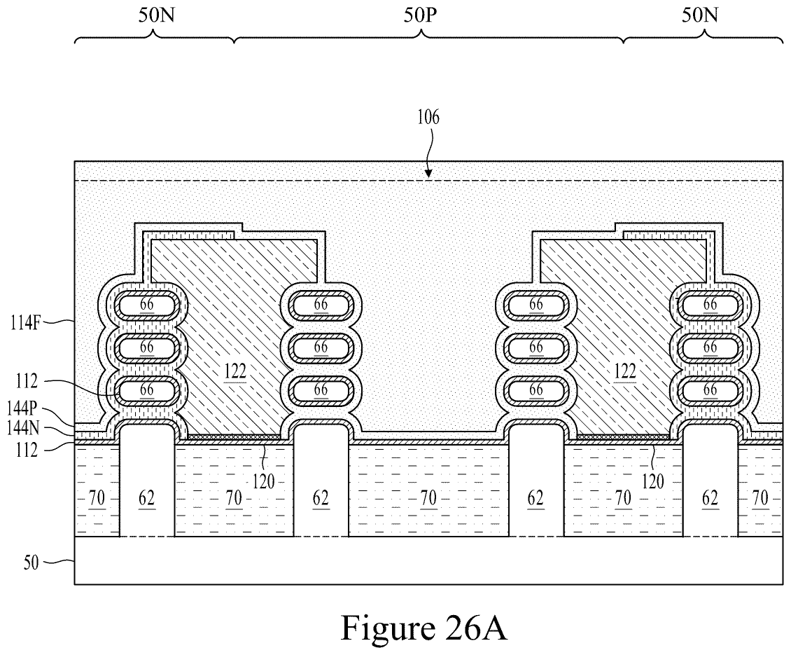

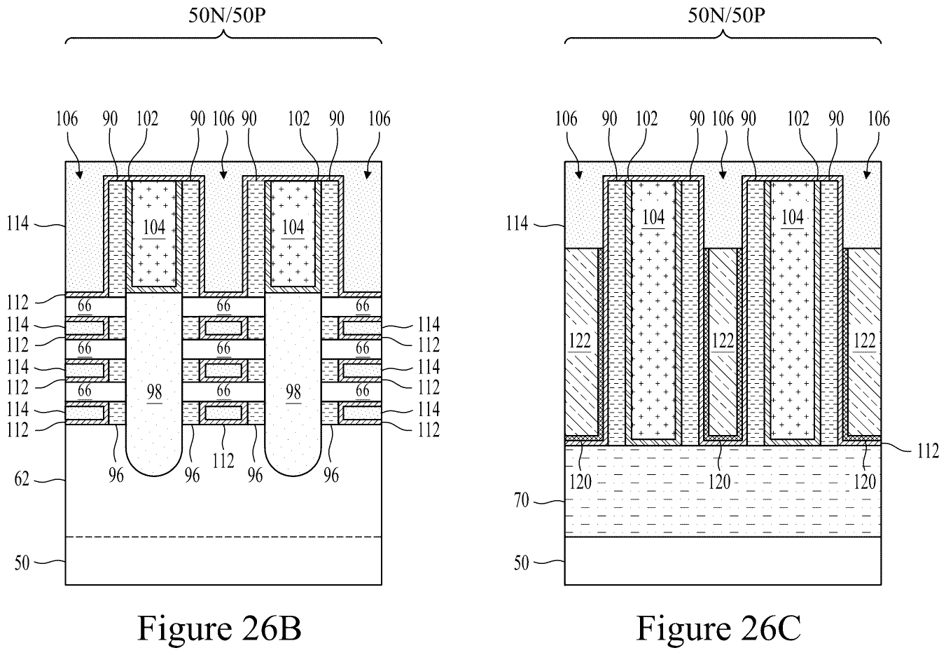

In FIGS. 26A-26C, the remaining portions of the gate electrode layer are formed in the recesses 106 in the p-type regions 50P and the n-type regions 50N. In the illustrated embodiment, a fill layer 114F (not shown in FIGS. 26B-26C, but see FIG. 26A) is deposited on the p-type work function tuning layer 114P and the n-type work function tuning layer 114N (when exposed). The fill layer 114F may be formed of a conductive material such as cobalt, ruthenium, aluminum, tungsten, combinations thereof, or the like, which may be formed by a deposition process such as CVD, ALD, PECVD, PVD, or the like. The fill layer 114F fills the remaining portions of the recesses 106 in the p-type regions 50P and the n-type regions 50N. Although not separately illustrated, it should be appreciated that other layers, such as glue layer, barrier layers, and the like may be formed beneath the fill layer 114F.

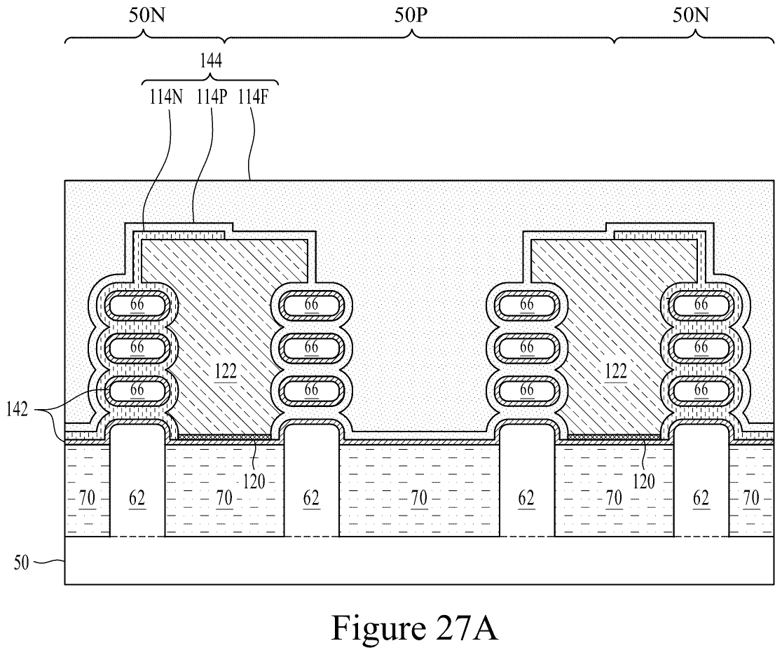

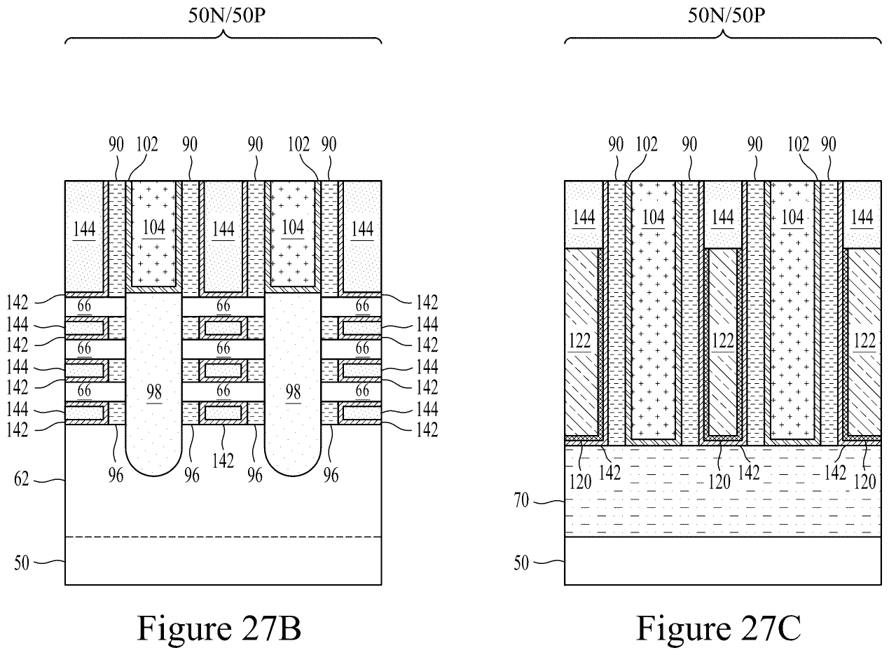

In FIGS. 27A-27C, a removal process is performed to remove the excess portions of the gate dielectric layer 112 and the gate electrode layer 114, which excess portions are over the top surfaces of the first ILD 104 and the gate spacers 90, thereby forming gate dielectrics 142 and gate electrodes 144. In some embodiments, a planarization process such as a chemical mechanical polish (CMP), an etch-back process, combinations thereof, or the like may be utilized. The gate dielectric layer 112, when planarized, has portions left in the recesses 106 and the openings 108 (thus forming the gate dielectrics 142). The gate electrode layer 114, when planarized, has portions left in the recesses 106, the openings 108, and the openings 130 (thus forming the gate electrodes 144). The top surfaces of the gate spacers 90; the CESL 102; the first ILD 104; the gate dielectrics 142; and the gate electrodes 144 (e.g., the n-type work function tuning layers 114N, the p-type work function tuning layers 114P, and the fill layers 114F; not shown in FIGS. 27B-27C, but see FIG. 27A) are substantially coplanar (within process variations). The gate dielectrics 142 and the gate electrodes 144 form replacement gates of the resulting nanostructure-FETs. Each respective pair of a gate dielectric 142 and a gate electrode 144 may be collectively referred to as a “gate structure.” The gate structures each extend along top surfaces, sidewalls, and bottom surfaces of a channel region of the second nanostructures 66. As demonstrated by FIG. 27A, the gate electrodes 144 are x-shaped gate electrodes, extending along top surfaces and sidewalls of the dielectric walls 122. The dielectric wall 122 is disposed on the gate dielectrics 142. The gate electrodes 144 are formed x-shaped in a self-aligned manner, as a result of the previously described process, thereby obviating one or more trim step(s).

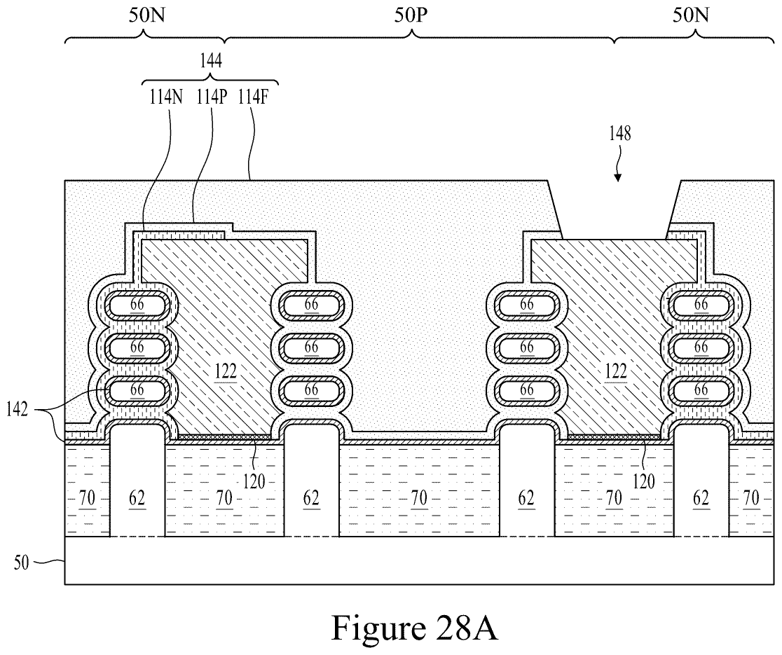

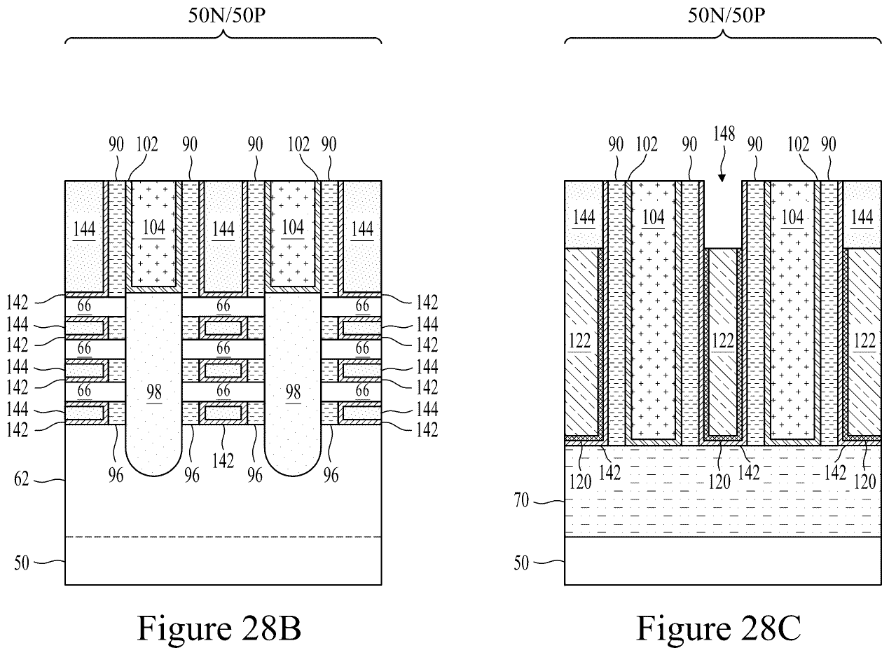

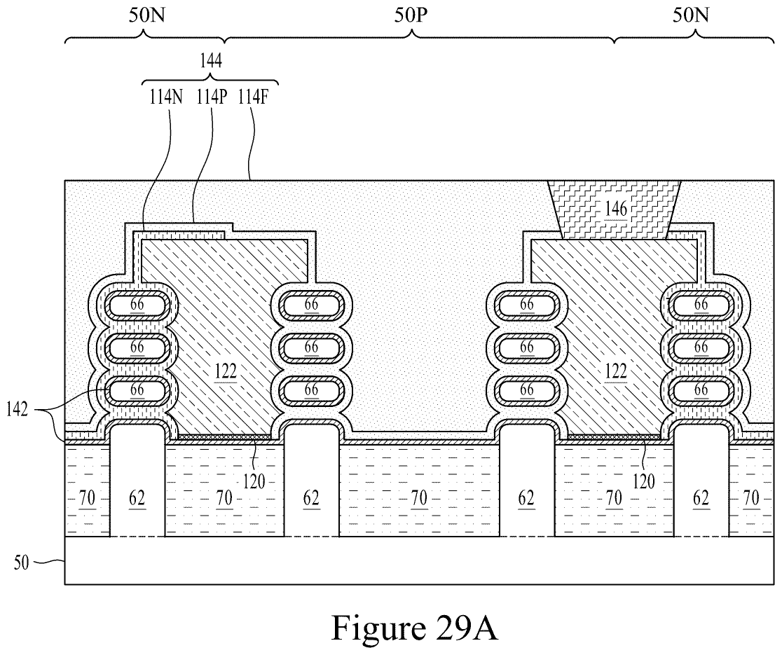

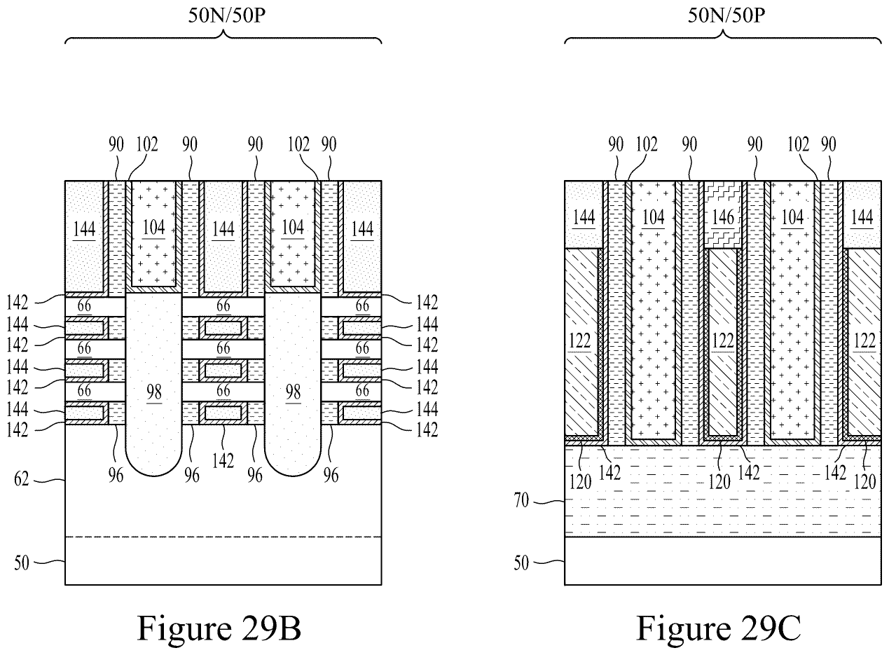

FIGS. 28A-29C illustrate a process in which an isolation region 146 (see FIG. 29A-29C) is formed to divide (or “cut”) a gate electrode 144 into multiple gate electrode segments. The isolation region 146 may be formed between the second nanostructures 66 in an n-type region 50N and the second nanostructures 66 in an adjacent p-type region 50P. Specifically, the isolation region 146 is formed at the boundary of a pair of adjacent regions 50N, 50P, on a dielectric wall 122.

In FIGS. 28A-28C, an opening 148 for an isolation region is patterned in a desired gate electrode 144. Any acceptable etching process, such as a dry etch, a wet etch, the like, or a combination thereof, may be performed to pattern the opening 148. The etching may be anisotropic. The opening 148 exposes a top surface of a dielectric wall 122 instead of an STI region 70. As previously noted, the width of the upper portions of the dielectric walls 122 is greater than the width of the lower portions of the dielectric walls 122. More specifically, the upper portions of the dielectric walls 122 overlap the second nanostructures 66 to protect the second nanostructures 66 during the etching of the opening 148. Forming the dielectric walls 122 thus increases the processing window for cutting a gate electrode 144. The upper portion of a dielectric walls 122 is wider than the overlying isolation region 146.

In FIGS. 29A-29C, an isolation region 146 is formed in the opening 148. The isolation region 146 may be formed of a dielectric material, such as silicon nitride, silicon oxide, silicon oxynitride, or the like, which may be formed by a deposition process such as CVD, ALD, or the like. One or more layers of dielectric material may be deposited in the openings. A removal process may be performed to remove the excess portions of the dielectric material, which excess portions are over the top surfaces of the gate electrode 144, thereby forming the isolation regions 146. The isolation regions 146 (or may not) may be formed of the same dielectric material as the dielectric walls 122.

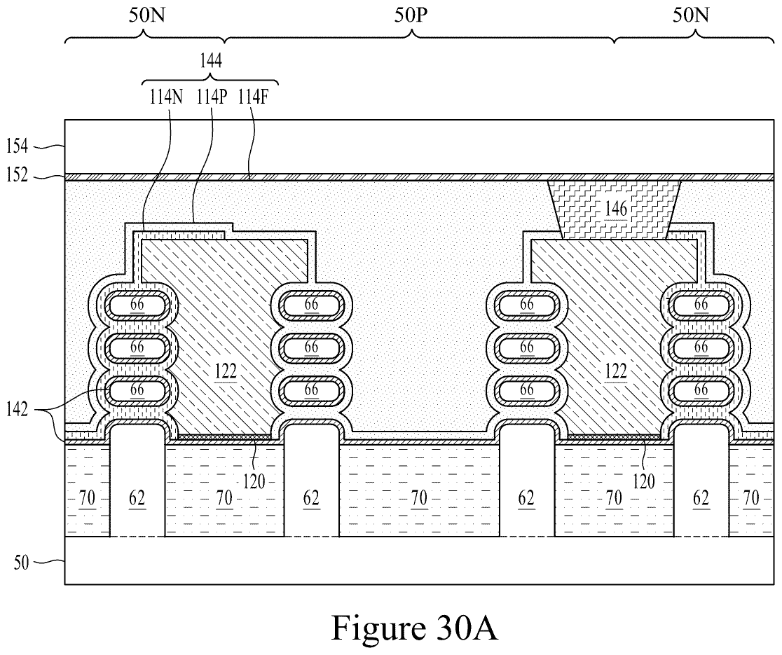

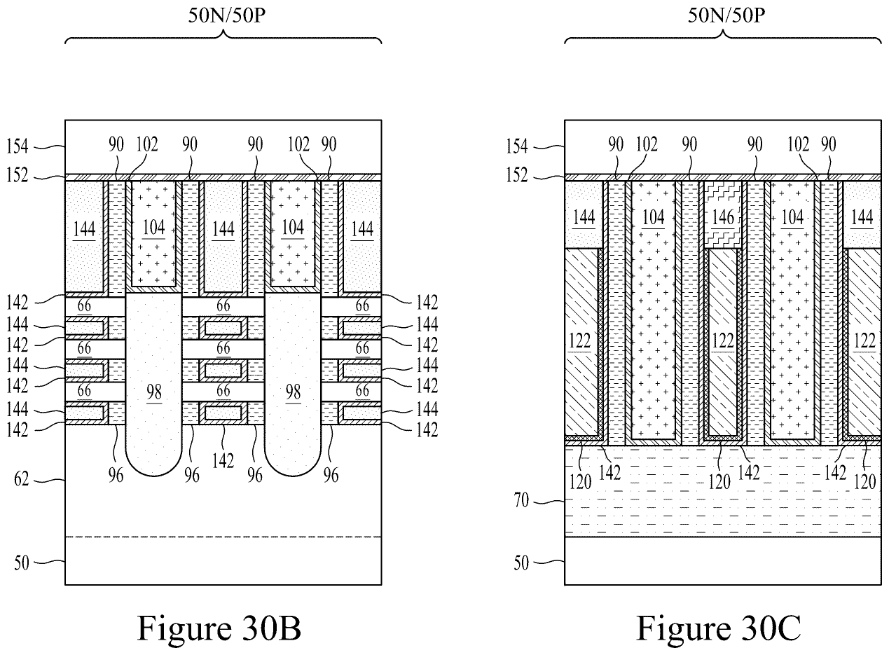

In FIGS. 30A-30C, a second ILD 154 is deposited over the gate spacers 90, the CESL 102, the first ILD 104, the gate dielectrics 142, the gate electrodes 144, and the isolation regions 146. In some embodiments, the second ILD 154 is a flowable film formed by a flowable CVD method. In some embodiments, the second ILD 154 is formed of a dielectric material such as PSG, BSG, BPSG, USG, or the like, which may be formed by any suitable deposition process, such as CVD, PECVD, or the like.

In some embodiments, an etch stop layer (ESL) 152 is formed between the second ILD 154 and the gate spacers 90, the CESL 102, the first ILD 104, the gate dielectrics 142, the gate electrodes 144, and the isolation regions 146. The ESL 152 may be formed of a dielectric material having a high etching selectivity from the etching of the second ILD 154, such as silicon nitride, silicon oxide, silicon oxynitride, or the like, which may be formed by any suitable deposition process, such as CVD, ALD, or the like.

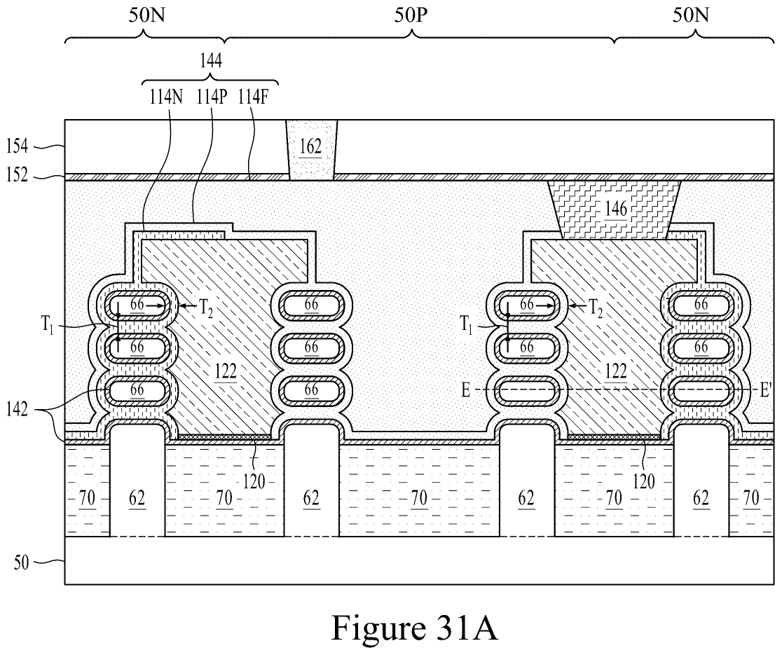

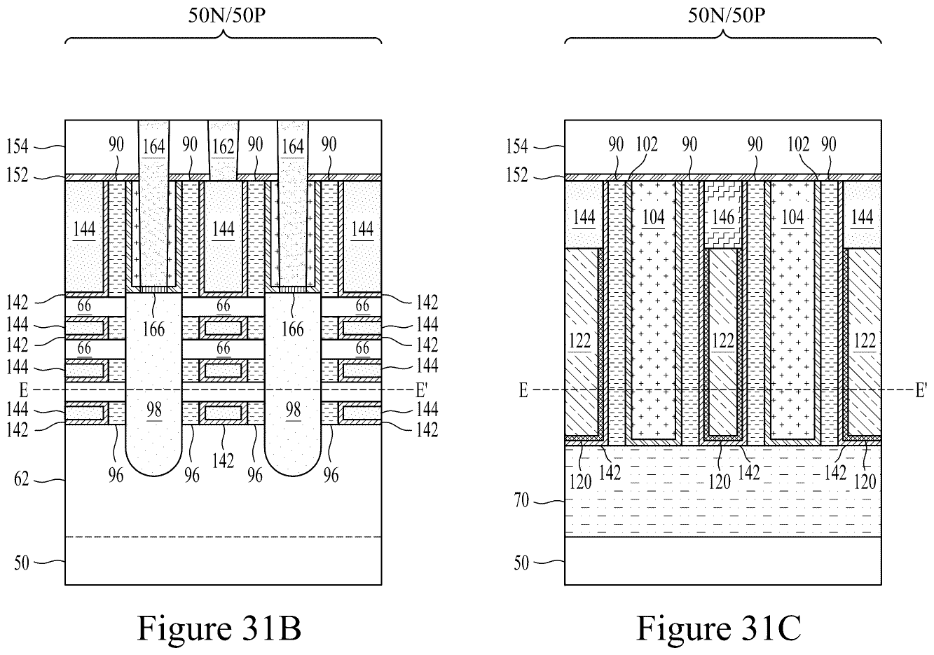

In FIGS. 31A-31C, gate contacts 162 and source/drain contacts 164 are formed to contact, respectively, the gate electrodes 144 and the epitaxial source/drain regions 98. The gate contacts 162 are physically and electrically coupled to the gate electrodes 144. The source/drain contacts 164 are physically and electrically coupled to the epitaxial source/drain regions 98.

As an example to form the gate contacts 162 and the source/drain contacts 164, openings for the gate contacts 162 are formed through the second ILD 154 and the ESL 152, and openings for the source/drain contacts 164 are formed through the second ILD 154, the ESL 152, the first ILD 104, and the CESL 102. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 154. The remaining liner and conductive material form the gate contacts 162 and the source/drain contacts 164 in the openings. The gate contacts 162 and the source/drain contacts 164 may be formed in distinct processes, or may be formed in the same process. Although shown as being formed in the same cross-sections, it should be appreciated that each of the gate contacts 162 and the source/drain contacts 164 may be formed in different cross-sections, which may avoid shorting of the contacts.

Optionally, metal-semiconductor alloy regions 166 are formed at the interfaces between the epitaxial source/drain regions 98 and the source/drain contacts 164. The metal-semiconductor alloy regions 166 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 166 can be formed before the material(s) of the source/drain contacts 164 by depositing a metal in the openings for the source/drain contacts 164 and then performing a thermal annealing process. The metal can be any metal capable of reacting with the semiconductor materials (e.g., silicon, silicon carbide, silicon germanium, germanium, etc.) of the epitaxial source/drain regions 98 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 164, such as from surfaces of the metal-semiconductor alloy regions 166. The material(s) of the source/drain contacts 164 can then be formed on the metal-semiconductor alloy regions 166.

As previously noted, the width of the openings 130 may be less than the width of the openings 108 (see FIGS. 21A-21C and 24A-24C). Because of this, the gate electrodes 144 (e.g., the work function tuning layers 114N/114P) have different thicknesses in different locations. Specifically, the portions of the gate electrodes 144 between vertical pairs of the nanostructures 66 have a greater thickness than the portions of the gate electrodes 144 between the nanostructure 66 and the dielectric walls 122. In some embodiments, the portions of the gate electrodes 144 (e.g., the work function tuning layers 114N/114P) between vertical pairs of the nanostructures 66 have a thickness T₁ in the range of 2 nm to 6 nm, and the portions of the gate electrodes 144 (e.g., the work function tuning layers 114N/114P) between a nanostructure 66 and a dielectric wall 122 have a thickness T₂ in the range of 2 nm to 6 nm, where the thickness T₁ is greater than the thickness T₂.

As previously described, the dielectric walls 122 are formed on the liner layer 120. Because of this, etching of the inner spacers 96 may be avoided when patterning the dielectric walls 122. Gate-drain capacitance (C_{gd}) and leakage between the epitaxial source/drain regions 98 and the gate electrodes 144 may thus be reduced, improving performance of the nanostructure-FETs, particularly in AC applications. Additionally, the gate structures extend around all sides of the nanostructures 66 in the cross-section of FIG. 31A, which may improve gate control as compared to other devices that include dielectric walls, such as forksheet structures. The gate structures (including the gate dielectrics 142 and the gate electrodes 144) completely fill the respective areas between the nanostructures 66 and the dielectric walls 122, such that a gate dielectric 142 and a gate electrode 144 each partially fill a respective area.

Specifically, a gate dielectric 142 partially fills an area between a nanostructure 66 and a dielectric wall 122, and a gate electrode 144 completely fills a remainder of the area that is unfilled by the gate dielectric 142. In this embodiment, the dielectric walls 122 are formed after the nanostructures 64 are removed (see FIGS. 13A-13C), after the gate dielectric layer 112 is formed (see FIGS. 14A-14C), and before the gate electrode layer 114 (see FIGS. 26A-26C) are formed.

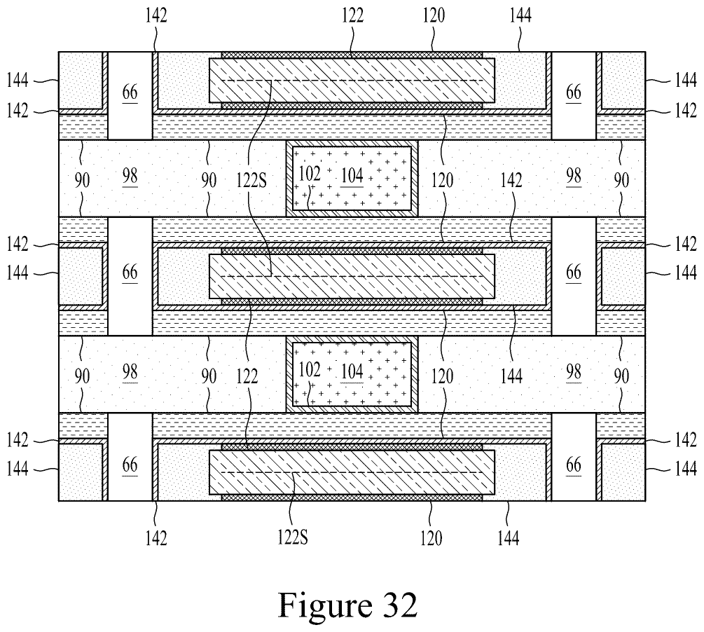

FIG. 32 is a top-down view of the nanostructure-FETs of FIGS. 31A-31C, shown along reference cross-section E-E′ in FIGS. 31A-31C. The dielectric walls 122 are disposed between adjacent groups of the nanostructures 66 along a first direction (e.g., in the cross-section of FIG. 31A) in the top-down view. Additionally, the dielectric walls 122 are disposed between adjacent pairs of the gate spacers 90 along a second direction (e.g., in the cross-sections of FIG. 31B or 31C) in the top-down view. The first direction is perpendicular to the second direction in the top-down view, such that both the first and second directions are perpendicular to the major surface of the substrate 50. The gate spacers 90 separate the dielectric walls 122 from the first ILD 104.

When the dielectric walls 122 are trimmed to expand the openings 130 (described for FIGS. 21A-21C and 24A-24C), repeated etching of the liner layer 120 may occur. As a result, the liner layer 120 may be recessed from sidewalls of the dielectric walls 122 in the top-down view. Portions of the gate electrodes 144 may therefore be formed in the space previously occupied by the recessed liner layer 120, e.g., between the dielectric walls 122 and the gate dielectrics 142 along the second direction (e.g., in the cross-sections of FIG. 31B or 31C).

‘The material of the dielectric walls 122 may seam together during formation. As a result, the dielectric walls 122 have seams 122S. In some embodiment, the seams 122S are parallel to the longitudinal axes of the gate structures and are perpendicular to the longitudinal axes of the nanostructures 66 in a top-down view.

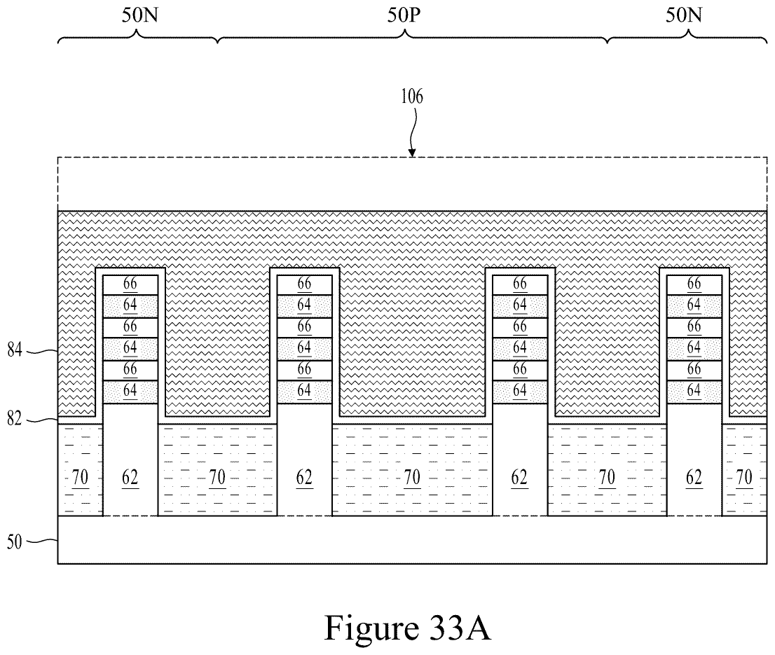

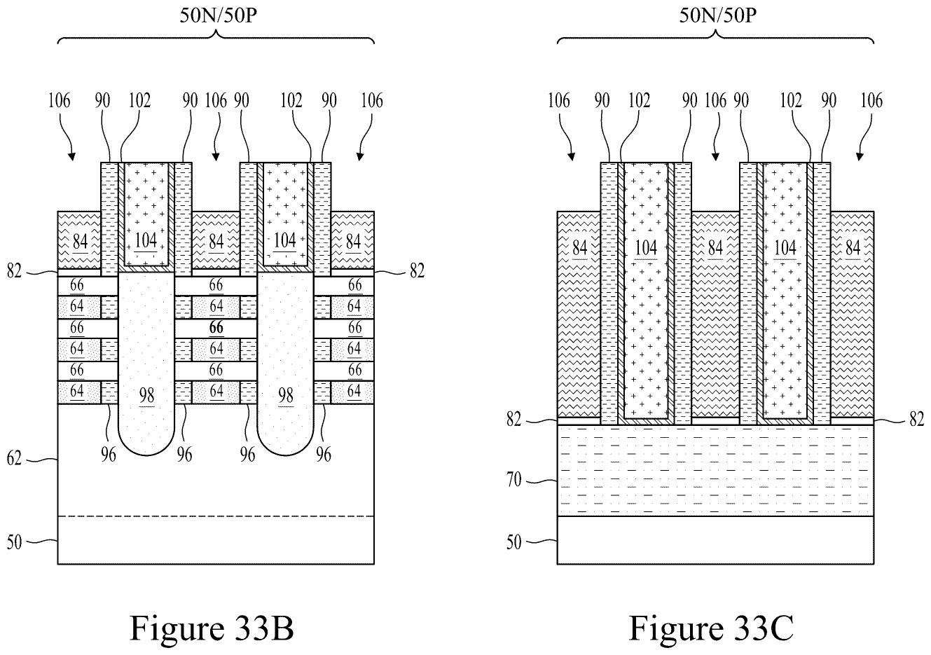

FIGS. 33A-52C are views of intermediate stages in the manufacturing of nanostructure-FETs, in accordance with some embodiments. FIGS. 33A, 34A, 35A, 36A, 37A, 38A, 39A, 40A, 41A, 42A, 43A, 44A, 45A, 46A, 47A, 48A, 49A, 50A, 51A, and 52A are cross-sectional views illustrated along a similar cross-section as reference cross-section A-A’ in FIG. 1. FIGS. 33B, 34B, 35B, 36B, 37B, 38B, 39B, 40B, 41B, 42B, 43B, 44B, 45B, 46B, 47B, 48B, 49B, 50B, 51B, and 52B are cross-sectional views illustrated along a similar cross-section as reference cross-section B-B′ in FIG. 1. FIGS. 33C, 34C, 35C, 36C, 37C, 38C, 39C, 40C, 41C, 42C, 43C, 44C, 45C, 46C, 47C, 48C, 49C, 50C, 51C, and 52C are cross-sectional views illustrated along a similar cross-section as reference cross-section C-C′ in FIG. 1.

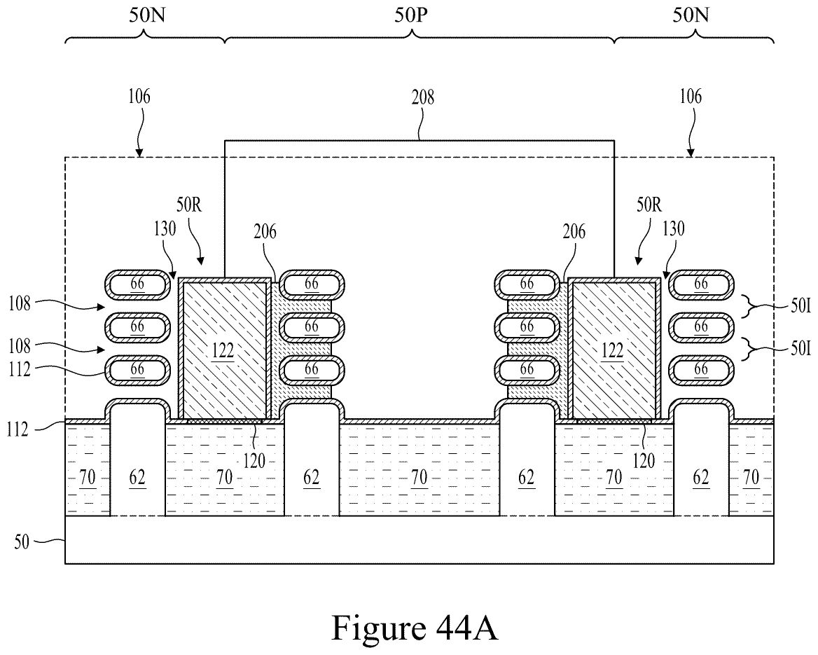

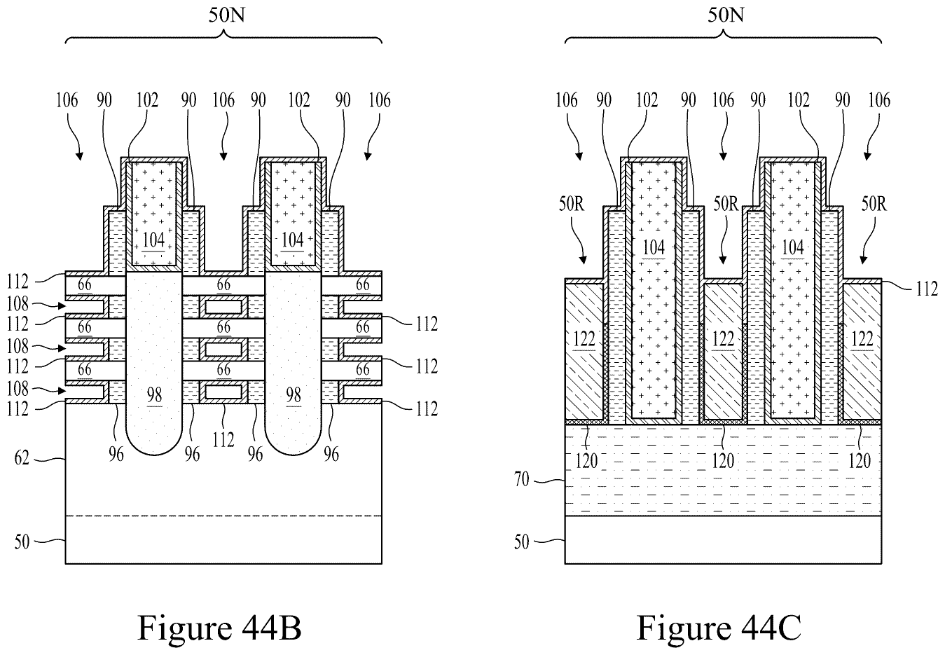

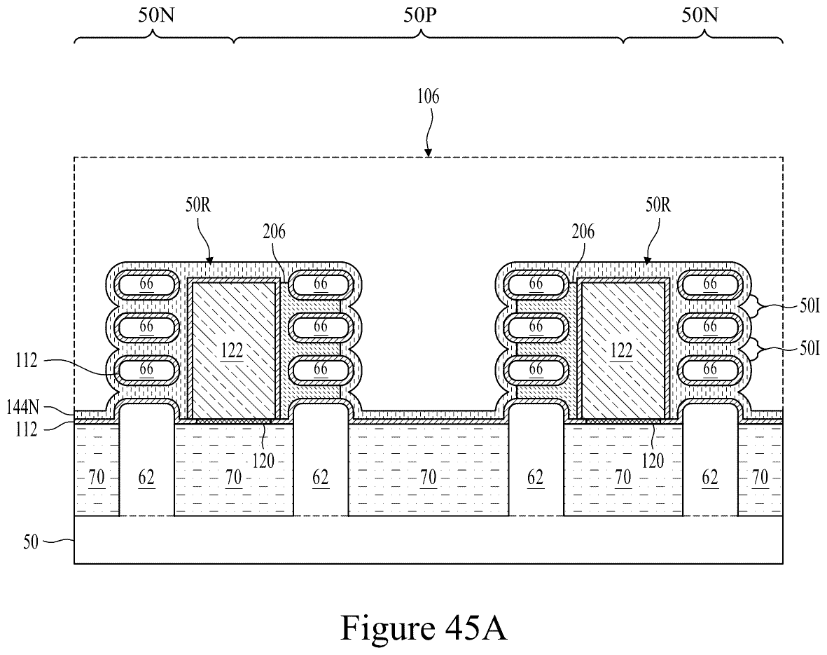

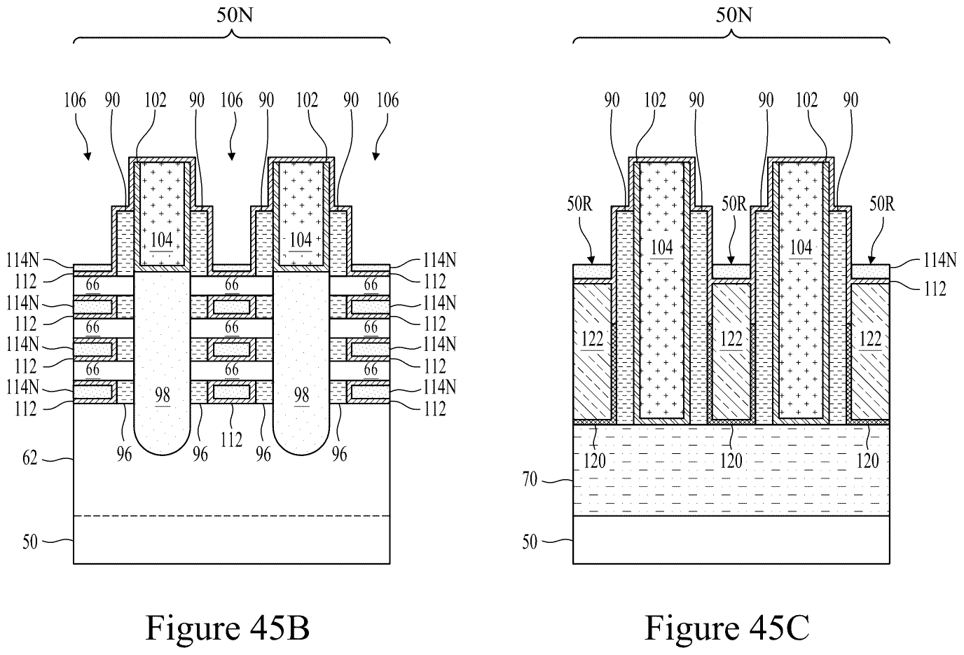

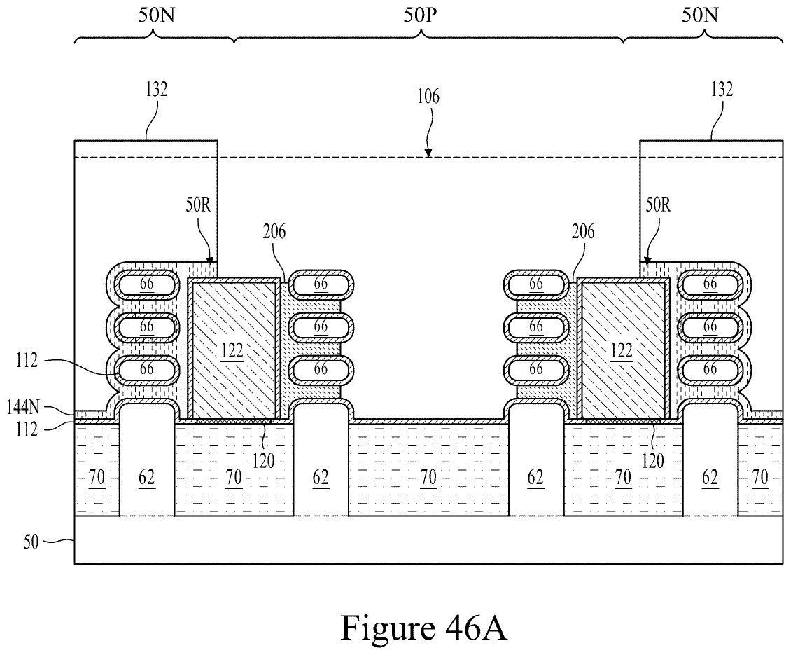

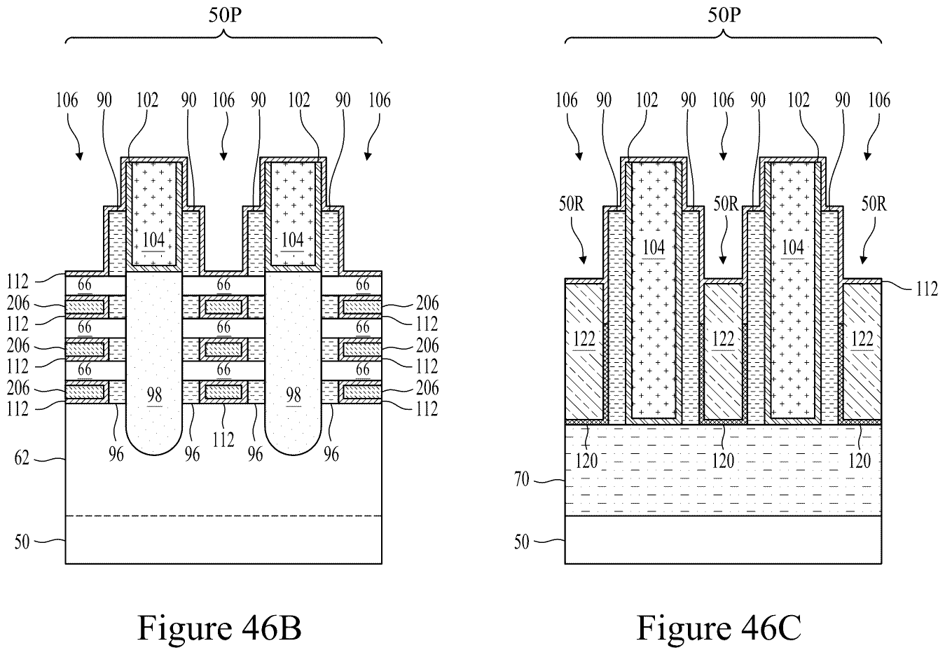

FIGS. 33B, 33C, 34B, 34C, 35B, 35C, 36B, 36C, 37B, 37C, 38B, 38C, 39B, 39C, 40B, 40C, 41B, 41C, 42B, 42C, 43B, 43C, 49B, 49C, 50B, 50C, 51B, 51C, 52B, and 52C illustrate features in either of the n-type regions 50N and the p-type regions 50P. For example, the structures illustrated may be applicable to both the n-type regions 50N and the p-type regions 50P. Differences (if any) in the structures of the n-type regions 50N and the p-type regions 50P are explained in the description of each figure. FIGS. 44B, 44C, 45B, and 45C illustrate features in the n-type regions 50N. FIGS. 46B, 46C, 47B, 47C, 48B, and 48C illustrate features in the p-type regions 50P.

In FIGS. 33A-33C, the structure of FIGS. 12A-12C is obtained. Then the masks 86 (if present) are removed, so that recesses 106 are formed. The dummy gates 84 are then recessed to expand the recesses 106. In some embodiments, the masks 86 are removed and the dummy gates 84 are recessed by an anisotropic dry etch process. For example, the etching process may include a dry etch process using reaction gas(es) that selectively etch the material of the dummy gates 84 at a faster rate than the materials of the first ILD 104 and the gate spacers 90.

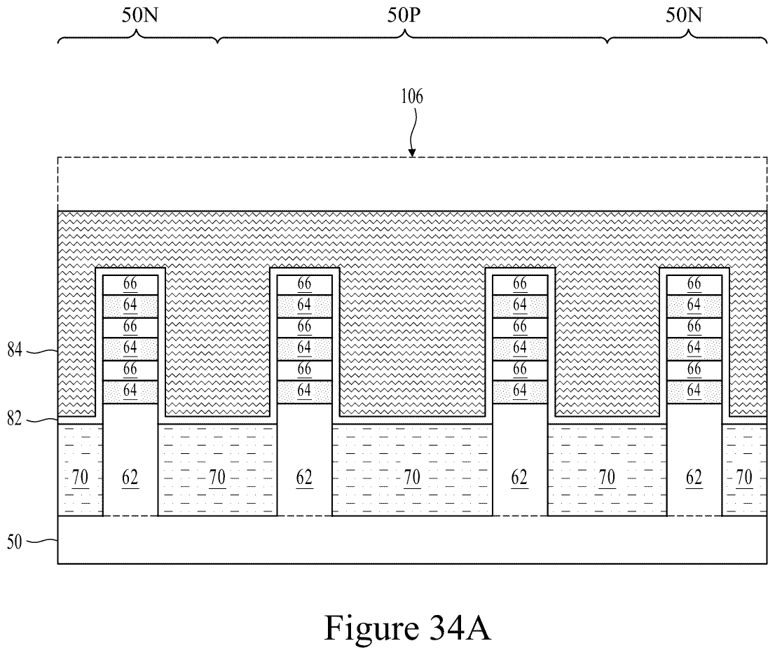

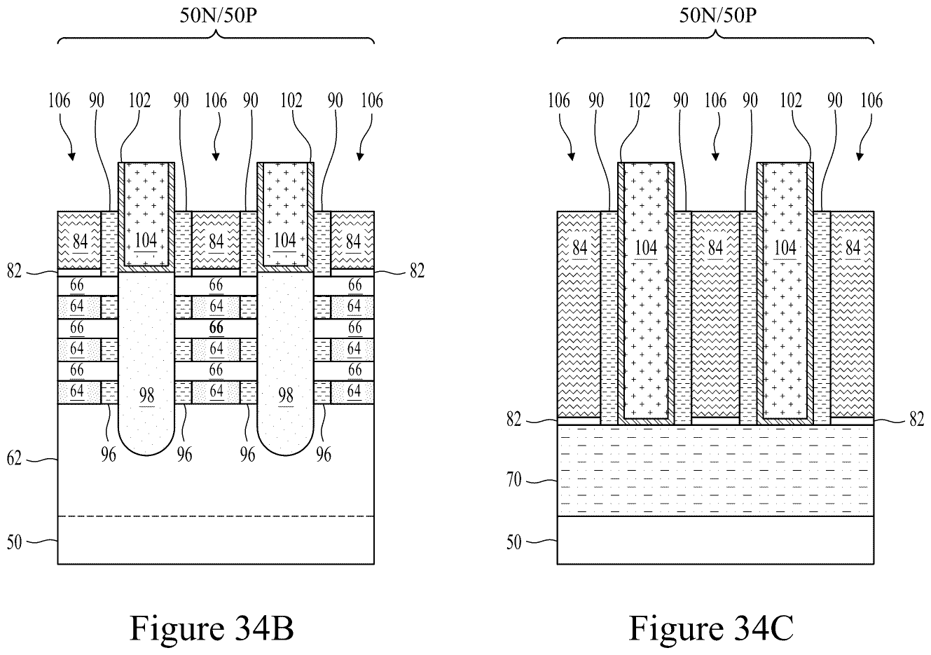

In FIGS. 34A-34C, the gate spacers 90 are recessed. In some embodiments, the gate spacers 90 are recessed by an anisotropic dry etch process. For example, the etching process may include a dry etch process using reaction gas(es) that selectively etch the material of the gate spacers 90 at a faster rate than the materials of the first ILD 104 and the dummy gates 84. The dummy gates 84 may be used as an etching mask when etching the gate spacers 90.

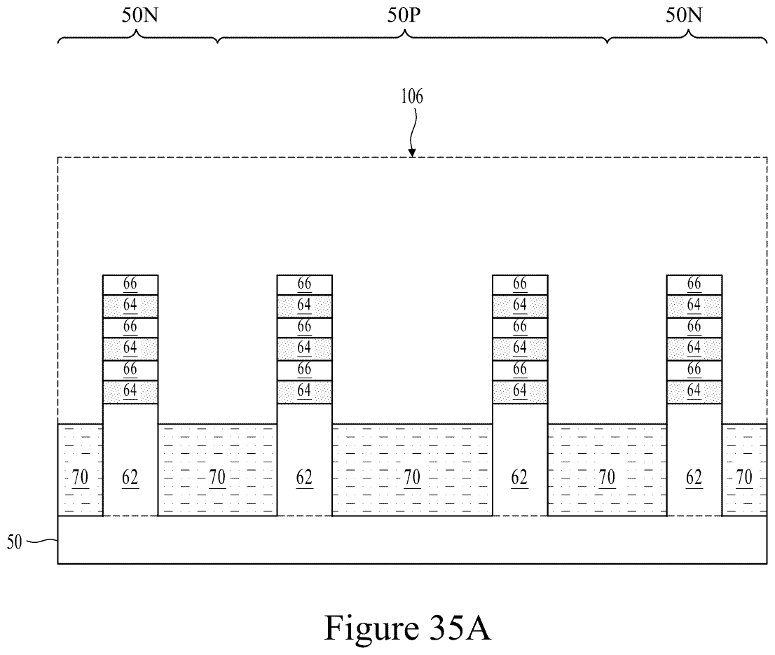

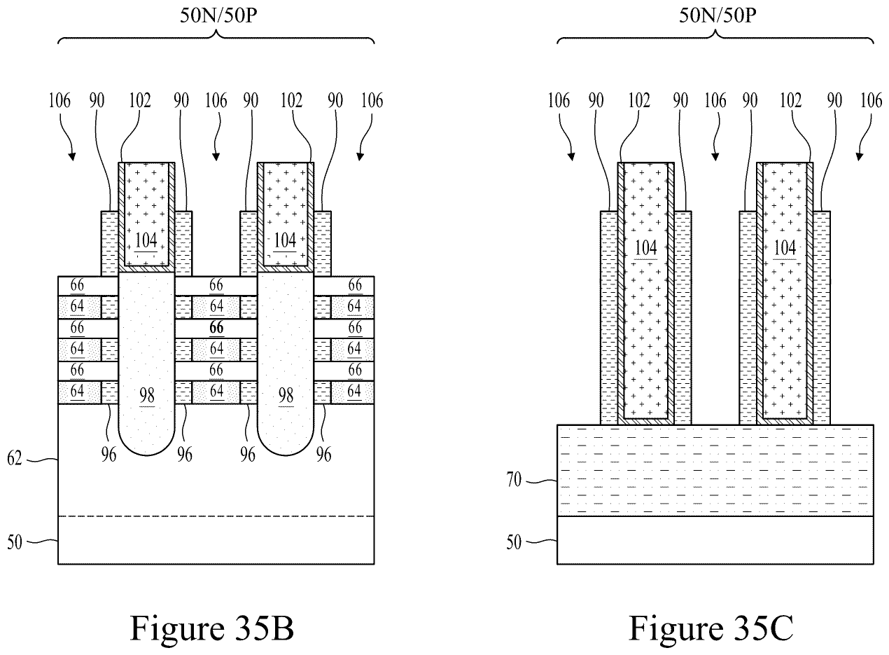

In FIGS. 35A-35C, the remaining portions of the dummy gates 84 are removed.

Portions of the dummy dielectrics 82 in the recesses 106 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 104 and the gate spacers 90. During the removal, the dummy dielectrics 82 may be used as etch stop layers when the dummy gates 84 are etched. The dummy dielectrics 82 may then be removed after the removal of the dummy gates 84.

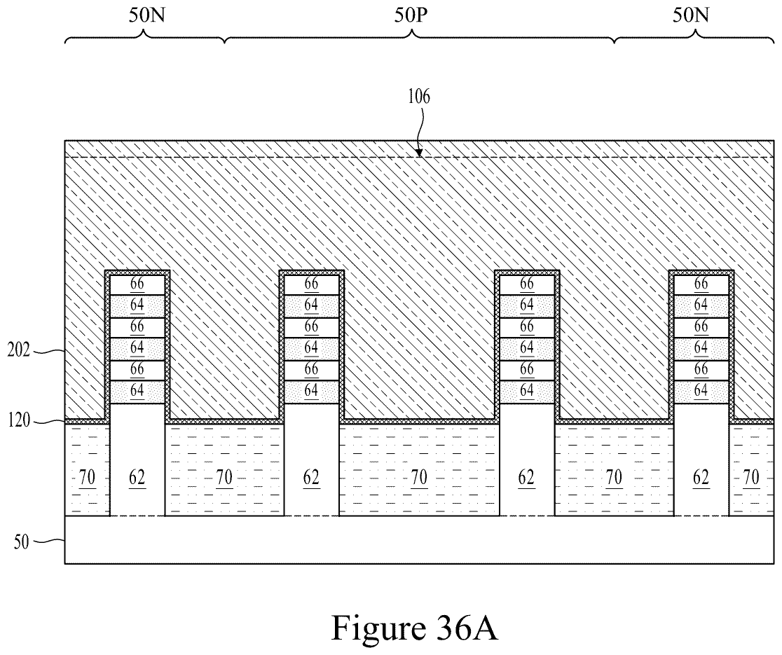

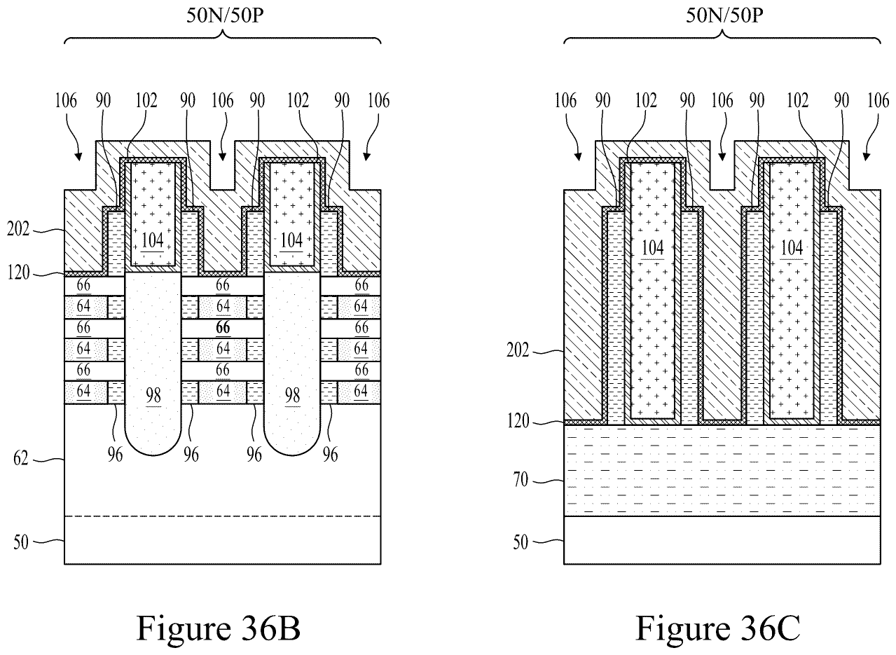

In FIGS. 36A-36C, a liner layer 120 is conformally formed in the recesses 106. The liner layer 120 may be formed similarly as described for FIGS. 15A-15C. The liner layer 120 extends along the sidewalls of the CESL 102 exposed by the recessing of the gate spacers 90. The liner layer 120 may extend over the first ILD 104 and the gate spacers 90. In some embodiments, the liner layer 120 has a thickness in the range of 1 nm to 5 nm, such as in the range of 1.5 nm to 5 nm.

An insulation material 202 for the dielectric walls is formed on the liner layer 120. The insulation material 202 is formed of a dielectric material having a high etching selectivity from the etching of the liner layer 120. Acceptable dielectric materials may include oxides such as silicon oxide or aluminum oxide, silicon nitride, silicon carbonitride, silicon oxycarbonitride, or the like, which may be formed by a deposition process such as chemical vapor deposition (CVD), atomic layer deposition (ALD), or the like.

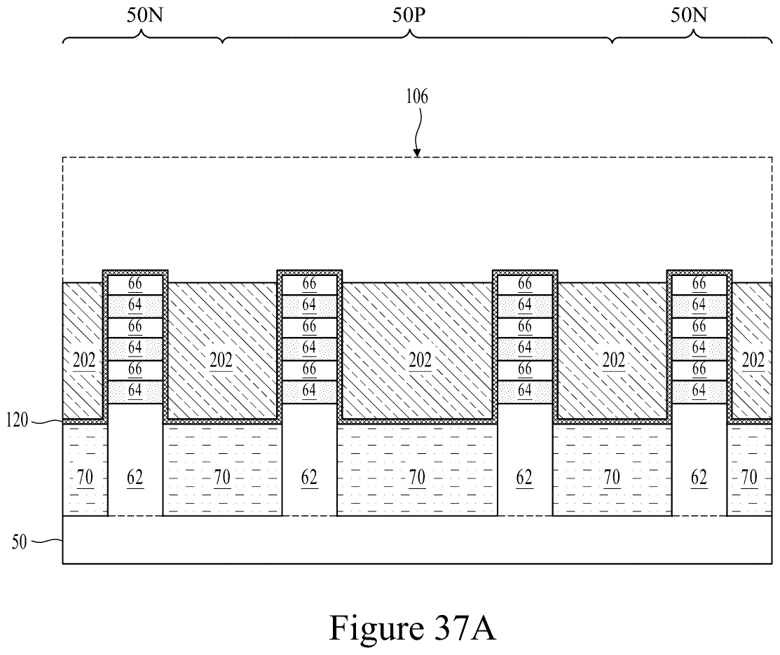

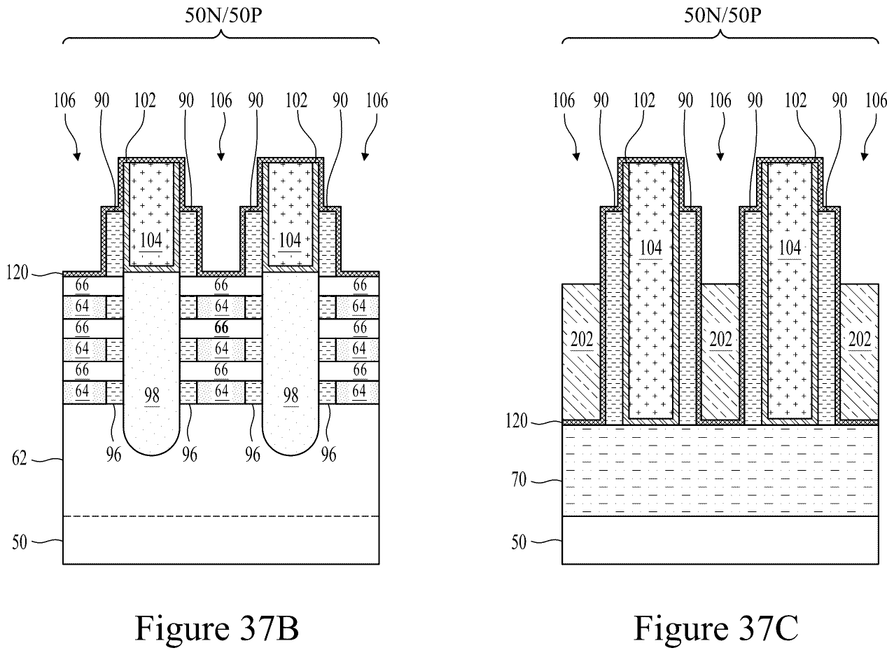

In FIGS. 37A-37C, the insulation material 202 is pulled back to remove the insulation material 202 outside of the recesses 106 and to reduce the height of the insulation material 202 in the recesses 106. The insulation material 202 may be pulled back with any acceptable etch process that is selective to the insulation material 202 (e.g., selectively etches the material of the insulation material 202 at a faster rate than the material of the liner layer 120). The etch process may be isotropic. The insulation material 202 is recessed until the portions of the liner layer 120 above the nanostructures 64, 66 are exposed. Timed etch processes may be used to stop the etching of the insulation material 202 after the insulation material 202 reaches a desired height.

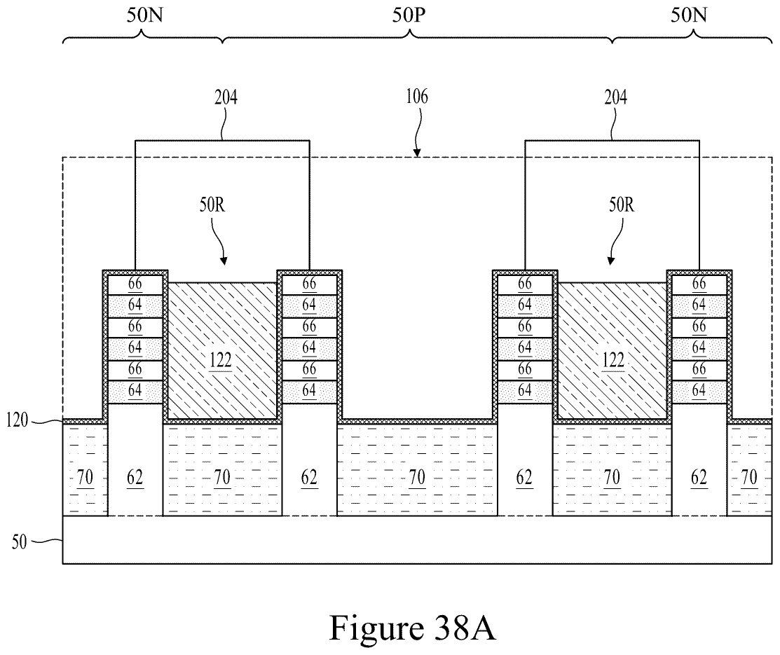

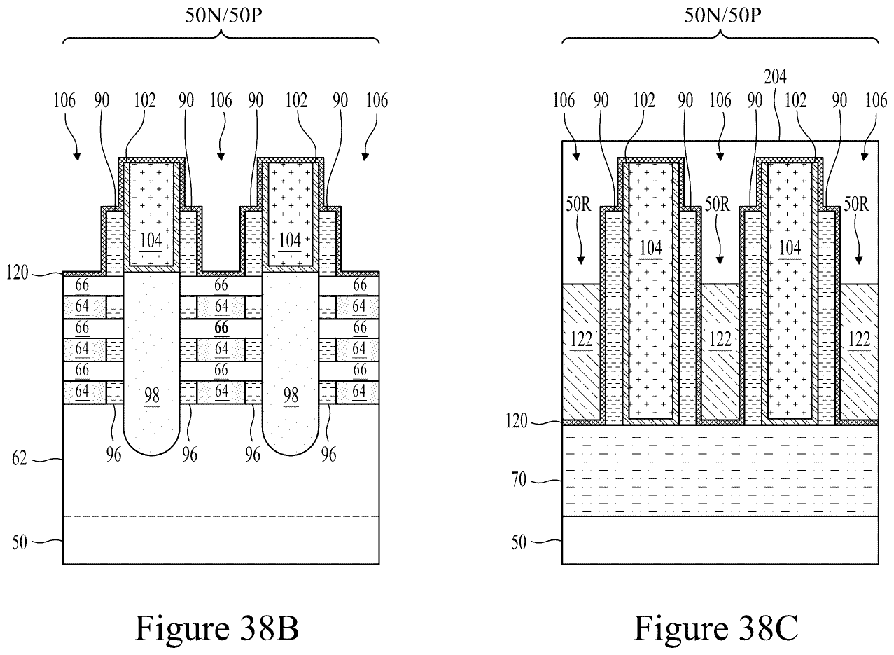

In FIGS. 38A-38C, the insulation material 202 is patterned to remove portions of the insulation material 202 in undesired locations, thereby forming the dielectric walls 122. The insulation material 202 may be patterned with any acceptable etch process that is selective to the insulation material 202 (e.g., selectively etches the material of the insulation material 202 at a faster rate than the material of the liner layer 120). The etch process may be isotropic. A mask 204, such as a photoresist, may be formed in the recesses 106 and used as an etching mask when etching the insulation material 202. The photoresist can be formed by using a spin-on technique and can be patterned using acceptable photolithography techniques. After the etching, the mask 204 may be removed, such as by an acceptable ashing process when the mask 204 is a photoresist. The dielectric walls 122 include the remaining portions of the insulation material 202. Each dielectric wall 122 is in a region 50R between the second nanostructures 66 in an n-type region 50N and the second nanostructures 66 in an adjacent p-type region 50P.

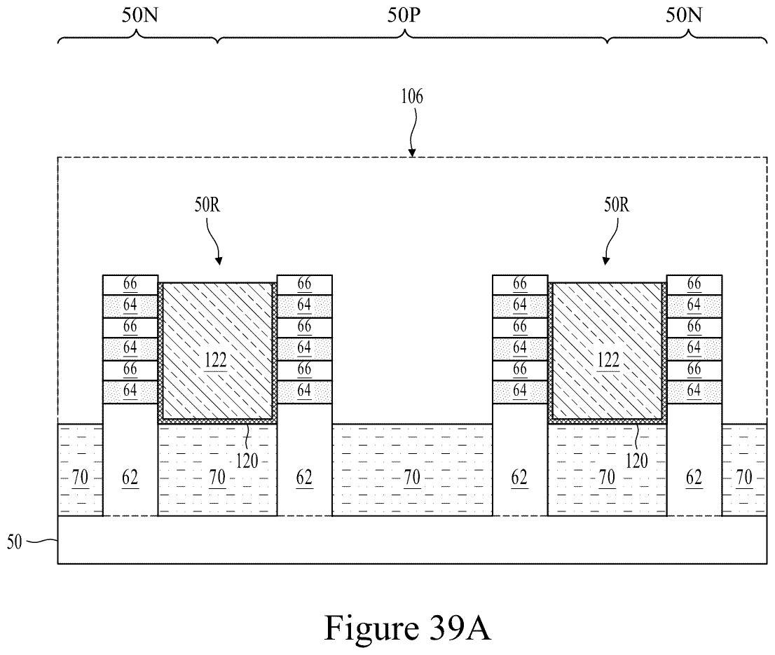

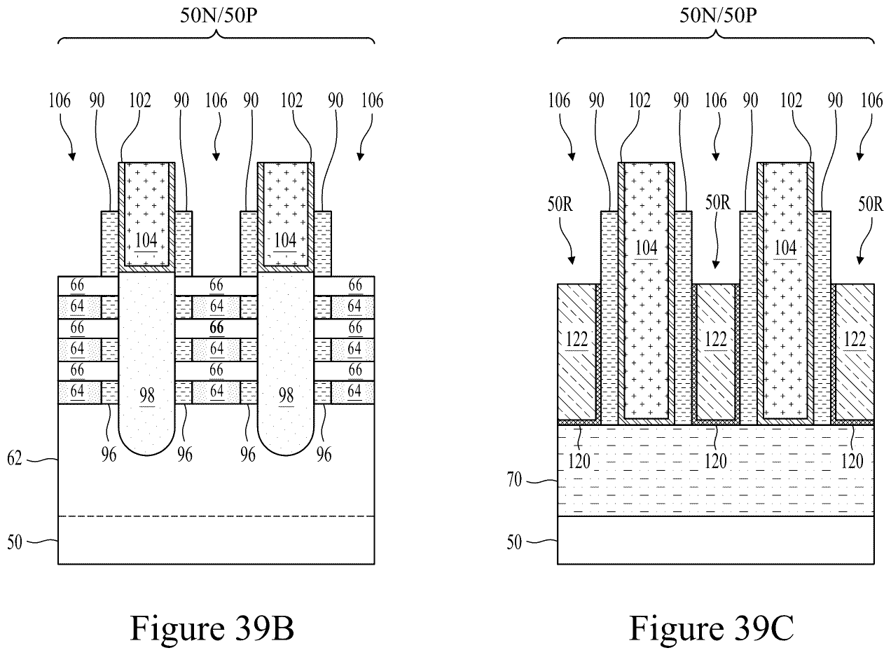

In FIGS. 39A-39C, the portions of the liner layer 120 exposed (e.g., not covered) by the dielectric walls 122 are removed. The liner layer 120 may be removed with any acceptable etch process that is selective to the liner layer 120 (e.g., selectively etches the material of the liner layer 120 at a faster rate than the material of the dielectric walls 122). The etch process may be isotropic. The dielectric walls 122 may be used as an etching mask when etching the liner layer 120.

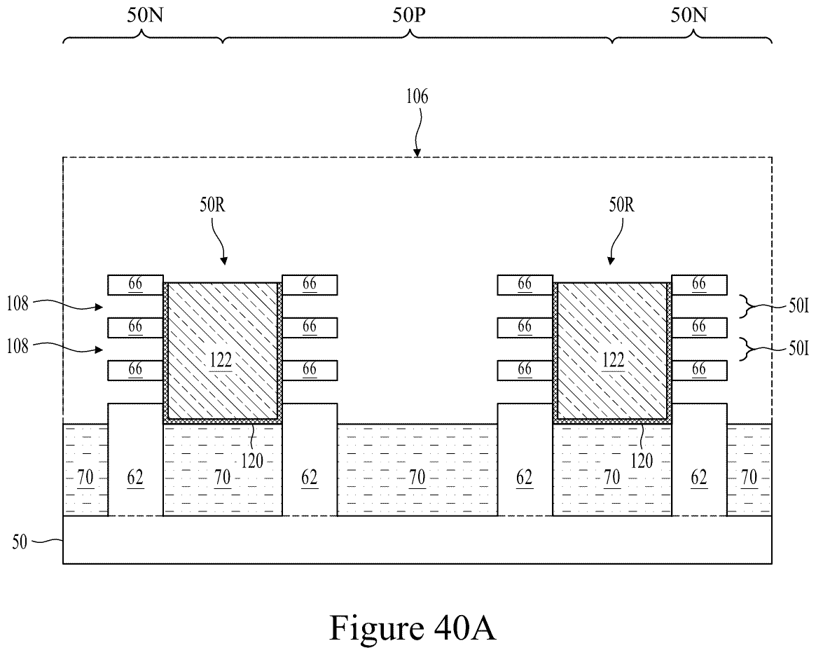

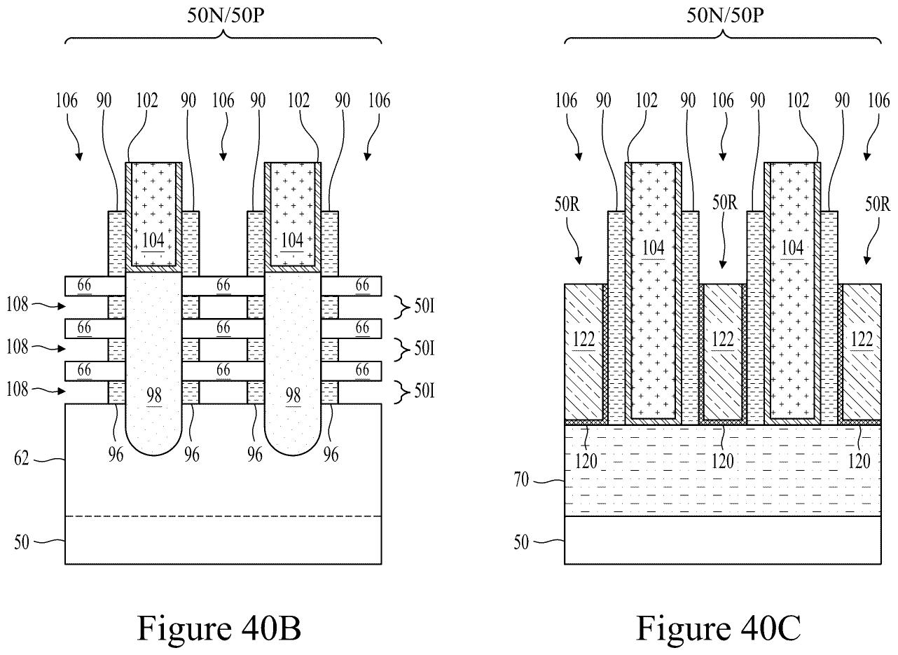

In FIGS. 40A-40C, the remaining portions of the first nanostructures 64 are removed to form openings 108 in regions 50I between the second nanostructures 66. The remaining portions of the first nanostructures 64 can be removed similarly as described for FIGS. 13A-13C.

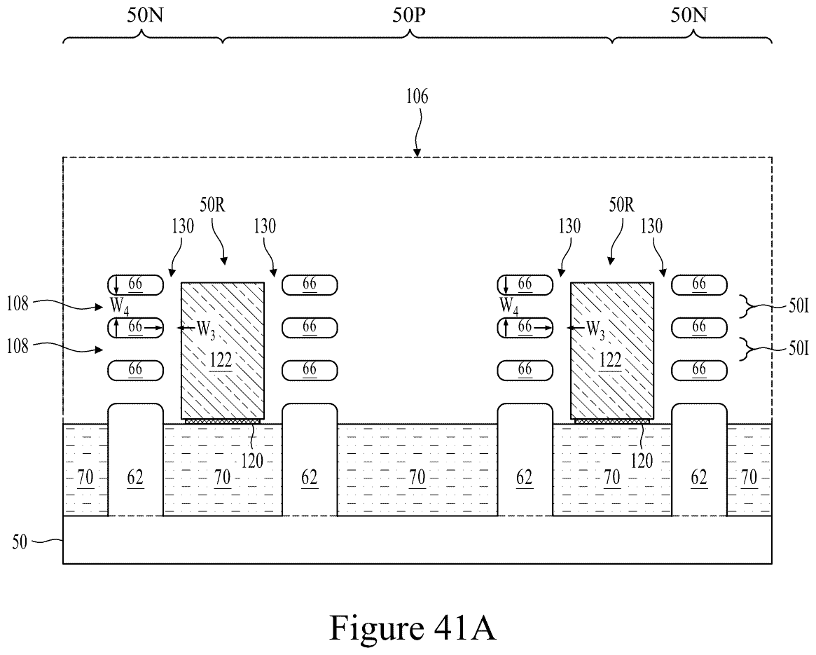

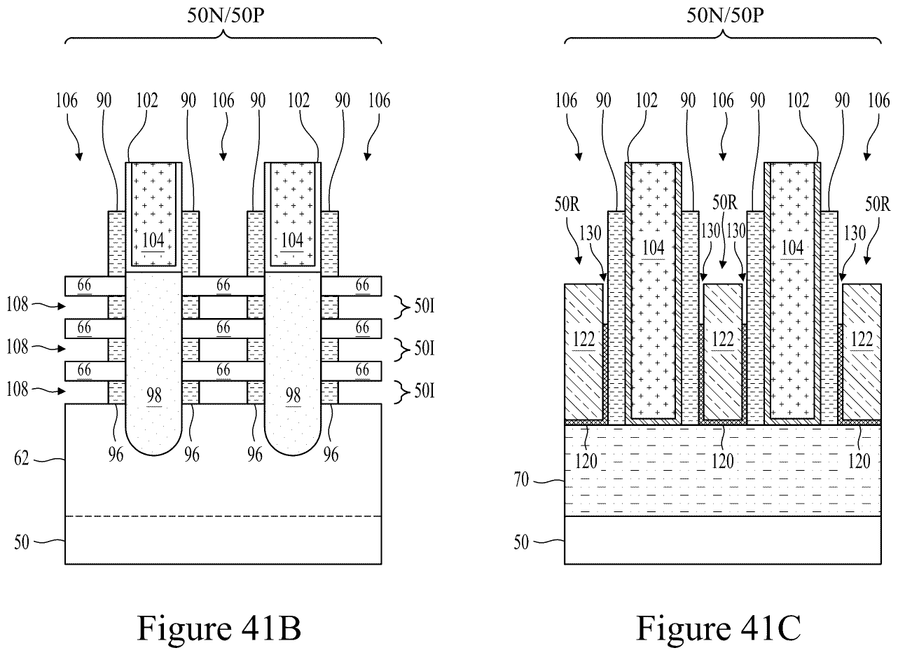

In FIGS. 41A-41C, the liner layer 120 is pulled back to remove the portions of the liner layer 120 along the sidewalls of the dielectric walls 122. The liner layer 120 may be pulled back with any acceptable etch process that is selective to the liner layer 120 (e.g., selectively etches the material of the liner layer 120 at a faster rate than the materials of the dielectric walls 122 and the nanostructures 66). At least some portions of the liner layer 120 between the dielectric walls 122 and the STI regions 70 may also be removed. As a result, the liner layer 120 may be recessed from sidewalls of the dielectric walls 122 in the cross-sectional view. The exposed portions of the second nanostructures 66 may be rounded after the removal process. Additionally, removing the portions of the liner layer 120 forms openings 130 between the dielectric walls 122 and the nanostructures 66 and the gate spacers 90. The dielectric walls 122 may optionally be trimmed to expand the openings 130. The dielectric walls 122 may be trimmed similarly as described for FIGS. 21A-21C and 24A-24C. The width W3 of the openings 130 may be less than or equal to the width W4 of the openings 108.

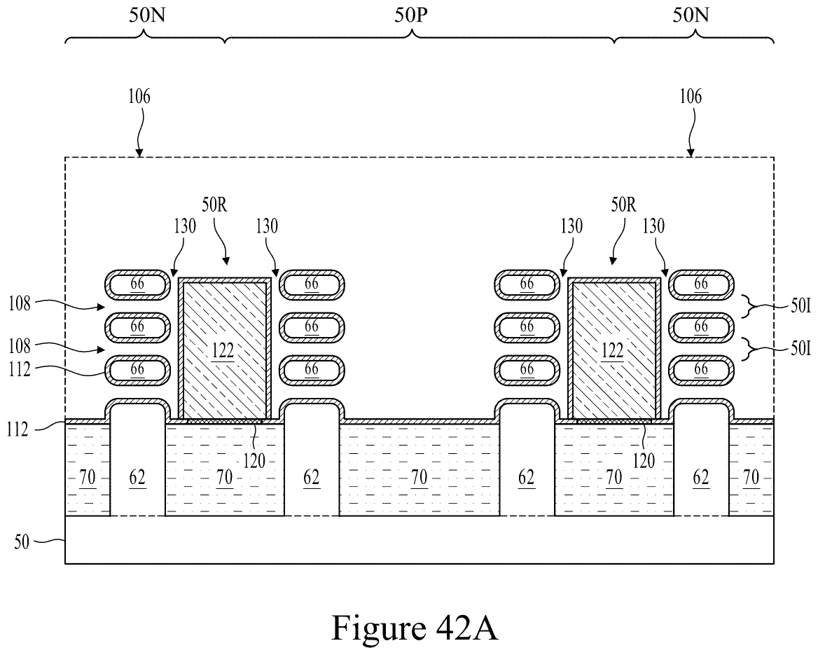

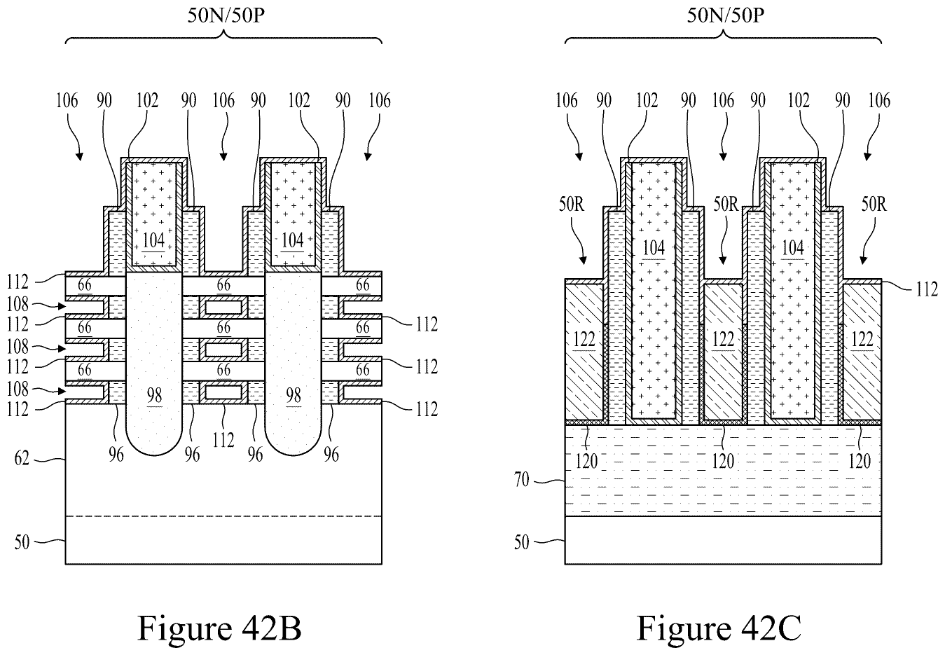

In FIGS. 42A-42C, a gate dielectric layer 112 is conformally formed on the dielectric walls 122 and the channel regions of the second nanostructures 66, such that it conformally lines the recesses 106, the openings 108, and the openings 130. Portions of the gate dielectric layer 112 may be between the dielectric walls 122 and the STI regions 70. The gate dielectric layer 112 may be formed similarly as described for FIGS. 14A-14C. In this embodiment, the gate dielectric layer 112 does not completely fill the openings 130.

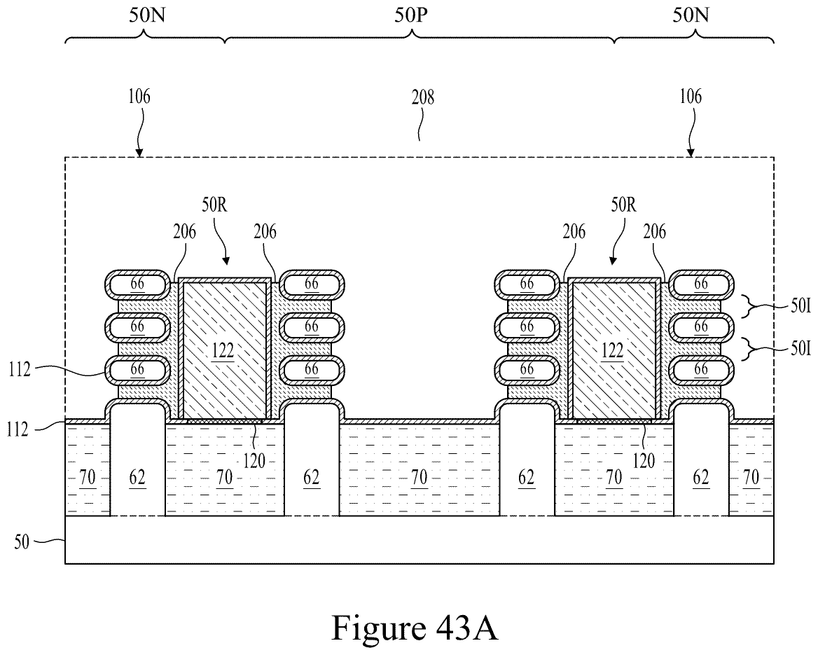

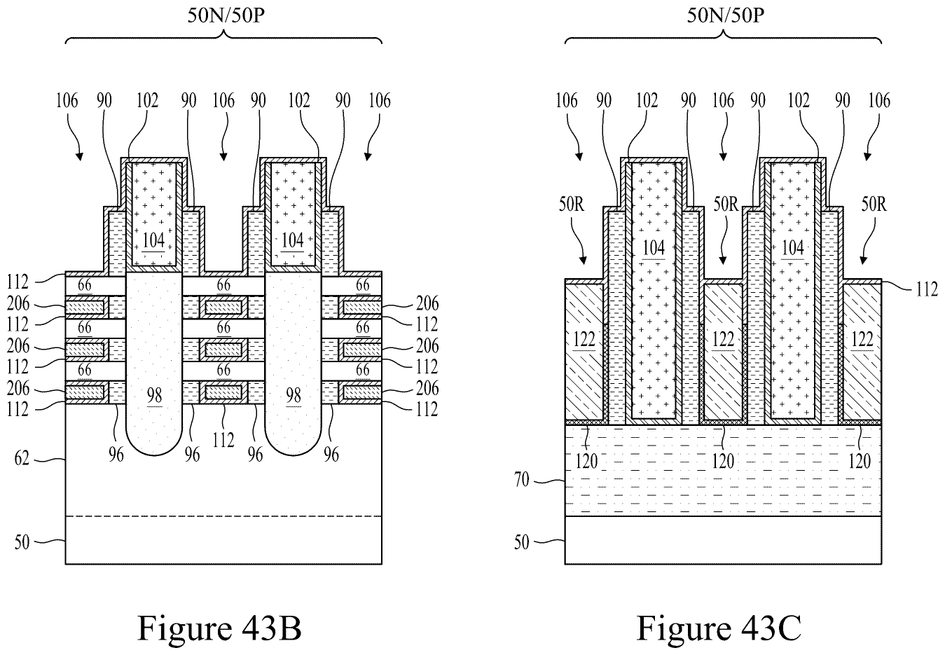

In FIGS. 43A-43C, sacrificial structures 206 are formed between the nanostructures 66 and the dielectric walls 122, and between vertical pairs of the nanostructures 66. The sacrificial structures 206 may be formed by conformally depositing a dielectric material in the recesses 106, the openings 108, and the openings 130, and then etching the dielectric material to remove portions of the dielectric material outside of the openings 108 and the openings 130. Acceptable dielectric materials may include aluminum oxide, aluminum nitride, silicon oxide, silicon nitride, silicon carbonitride, silicon oxycarbonitride, or the like, which may be formed by a deposition process such as chemical vapor deposition (CVD), atomic layer deposition (ALD), or the like. Any acceptable etch process, such as a dry etch, a wet etch, the like, or a combination thereof, may be performed to pattern the dielectric material. The sacrificial structures 206 may be formed of the same dielectric material as the liner layer 120.

In FIGS. 44A-44C, the sacrificial structures 206 in the n-type regions 50N are removed. Removing the sacrificial structures 206 in the n-type regions 50N re-forms the openings 108 and the openings 130 in the n-type regions 50N. The sacrificial structures 206 in the p-type regions 50P are not removed at this step. The sacrificial structures 206 may be removed with any acceptable etch process that is selective to the sacrificial structures 206 (e.g., selectively etches the material of the sacrificial structures 206 at a faster rate than the materials of the dielectric walls 122 and the gate dielectric layer 112). The etch process may be isotropic. For example, when the sacrificial structures 206 are formed of aluminum oxide, the etch process may be a wet etch using ammonium hydroxide (NH₄OH), dilute hydrofluoric (dHF) acid, or the like. A mask 208, such as a photoresist, may be formed in the p-type regions 50P and used as an etching mask when etching the sacrificial structures 206. The photoresist can be formed by using a spin-on technique and can be patterned using acceptable photolithography techniques. After the removal of the sacrificial structures 206 in the n-type regions 50N, the mask 208 may be removed, such as by an acceptable ashing process when the mask 208 is a photoresist.

In FIGS. 45A-45C, an n-type work function tuning layer 114N is conformally formed on the gate dielectric layer 112, such that it conformally lines the recesses 106, the openings 108, and the openings 130 in the n-type regions 50N. The n-type work function tuning layer 114N may be formed similarly as described for FIGS. 22A-22C. Because the sacrificial structures 206 were removed from the n-type regions 50N but not the p-type regions 50P, the n-type work function tuning layer 114N is formed around the second nanostructures 66 in the n-type regions 50N but not the p-type regions 50P. The n-type work function tuning layer 114N fills the remaining portions of the regions 50I between the second nanostructures 66 in the n-type regions 50N.

In FIGS. 46A-46C, the n-type work function tuning layer 114N is patterned to remove portions of the n-type work function tuning layer 114N in the p-type regions 50P. The n-type work function tuning layer 114N may be patterned similarly as described for FIGS. 23A-23C. A mask 132, such as a photoresist, may be formed in the p-type regions 50P and used as an etching mask when etching the n-type work function tuning layer 114N. Removing the portions of the n-type work function tuning layer 114N in the p-type regions 50P re-exposes the sacrificial structures 206 in the p-type regions 50P.

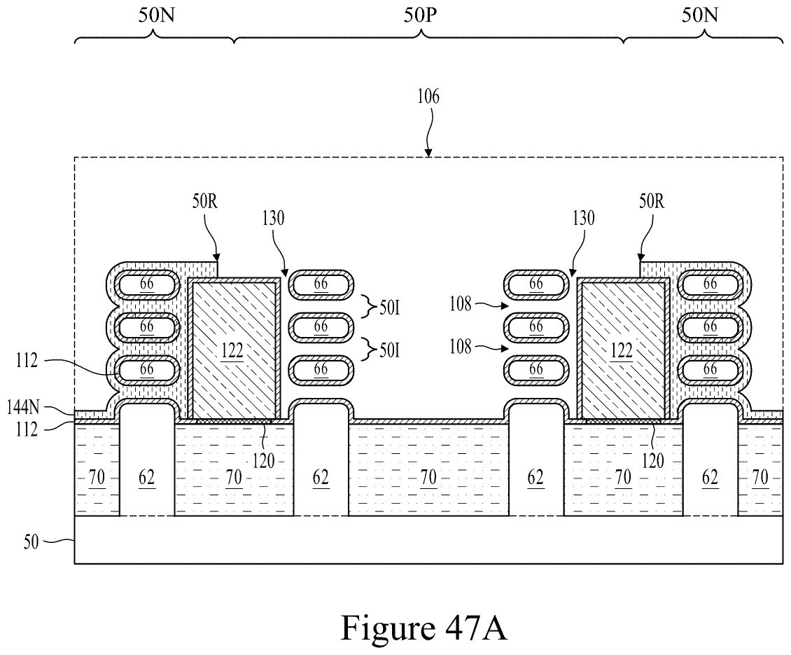

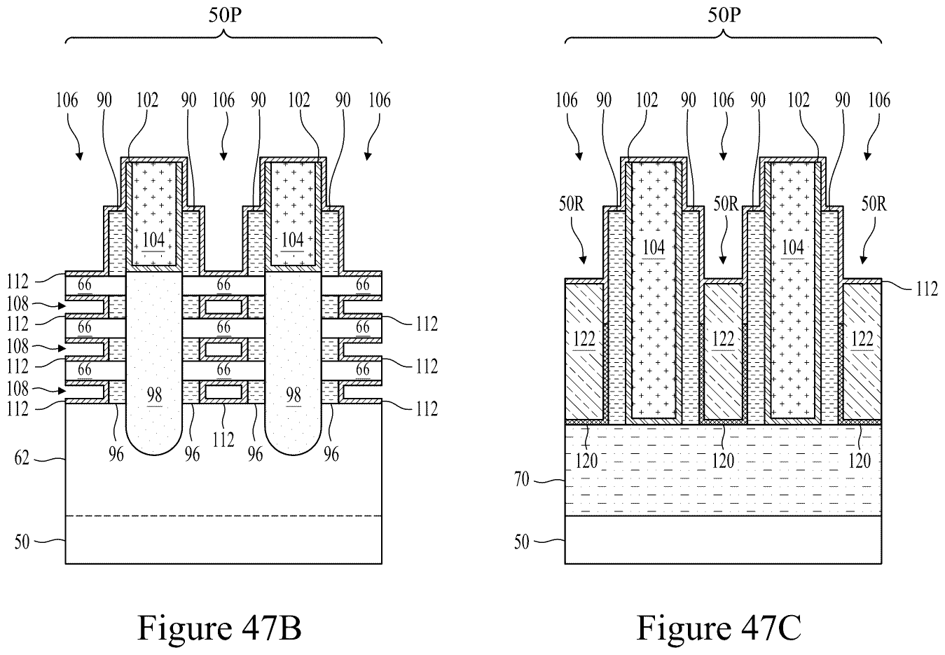

In FIGS. 47A-47C, the sacrificial structures 206 in the p-type regions 50P are removed. Removing the sacrificial structures 206 in the p-type regions 50P re-forms the openings 108 and the openings 130 in the p-type regions 50P. The sacrificial structures 206 may be removed similarly as described for FIGS. 44A-44C, except the n-type work function tuning layer 114N may be used as an etching mask when etching the sacrificial structures 206.

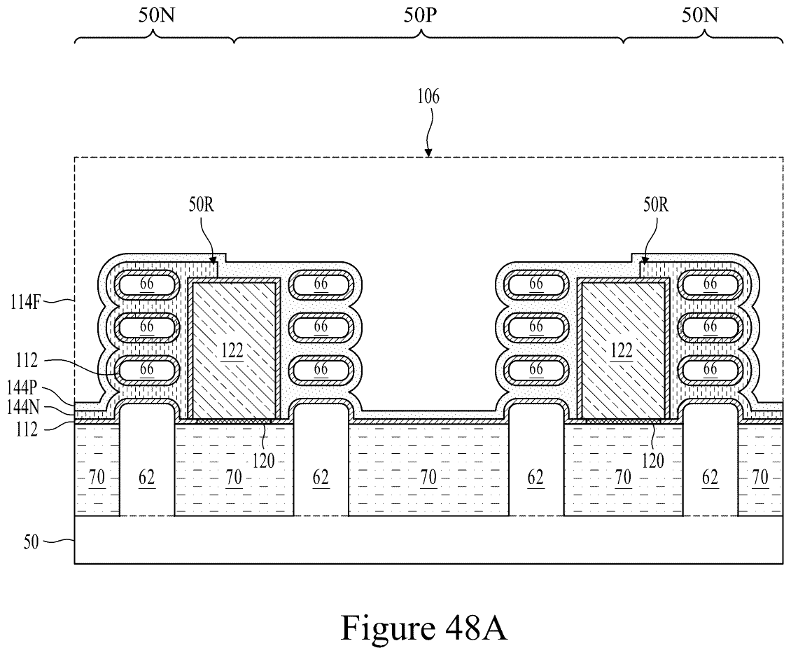

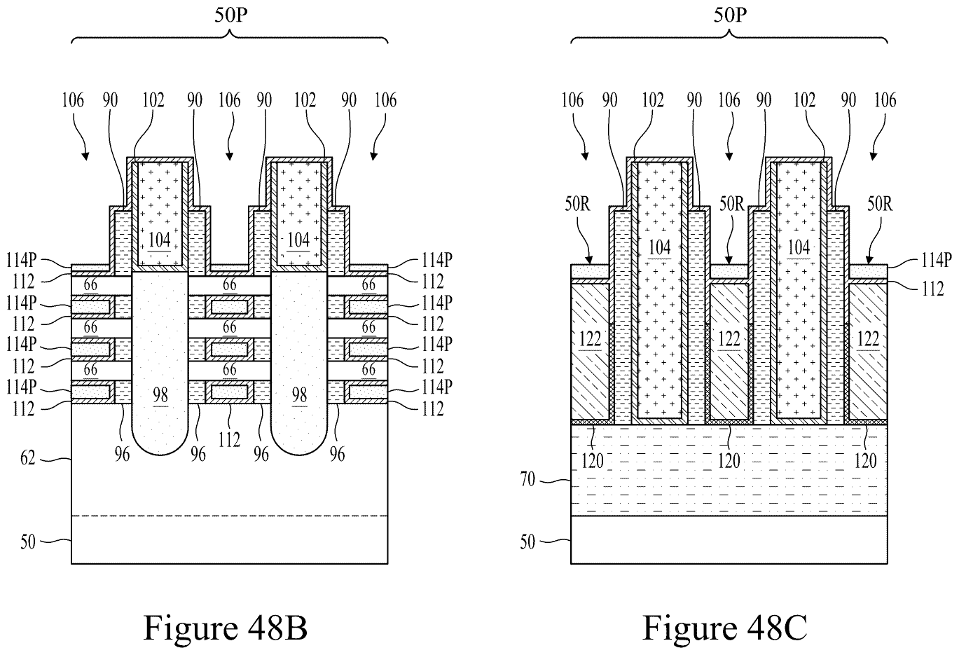

In FIGS. 48A-48C, a p-type work function tuning layer 114P is conformally formed on the gate dielectric layer 112, such that it conformally lines the recesses 106, the openings 108, and the openings 130 in the p-type regions 50P. The p-type work function tuning layer 114P may be formed similarly as described for FIGS. 25A-25C. Because the sacrificial structures 206 were removed from the p-type regions 50P, the p-type work function tuning layer 114P is formed around the second nanostructures 66 in the p-type regions 50P. The p-type work function tuning layer 114P fills the remaining portions of the regions 50I between the second nanostructures 66 in the p-type regions 50P.

In the illustrated embodiment, the p-type work function tuning layer 114P is formed in both the p-type regions 50P and the n-type regions 50N, and the n-type work function tuning layer 114N is formed in the n-type regions 50N but not the p-type regions 50P. The resulting gate structures in each region thus include different materials and a different number of layers. The gate structures in the n-type regions 50N may include more work function tuning layers than the gate structures in the p-type regions 50P. Other work function tuning layer structures may be utilized in the different regions. For example, the p-type work function tuning layer 114P may also be patterned to remove portions of the p-type work function tuning layer 114P in the n-type regions 50N, thereby exposing the n-type work function tuning layer 114N.

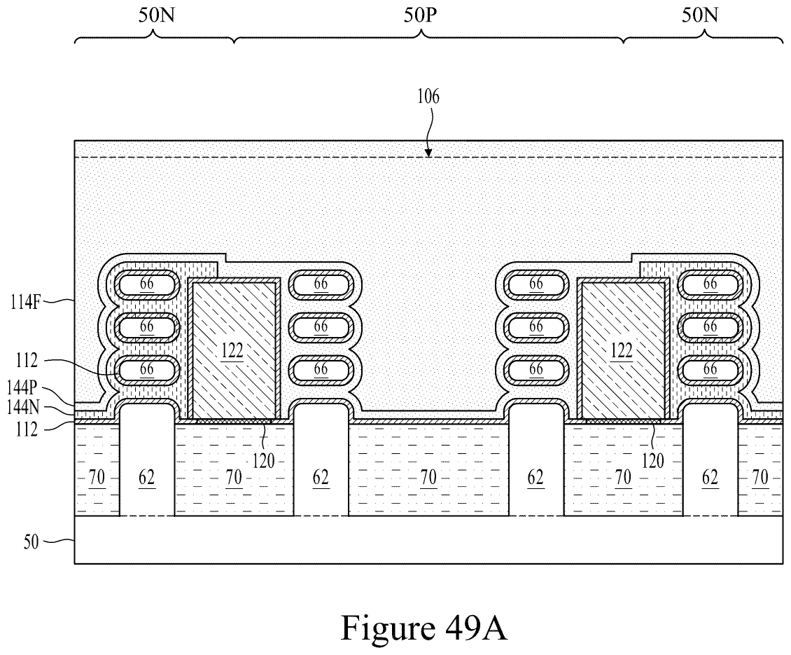

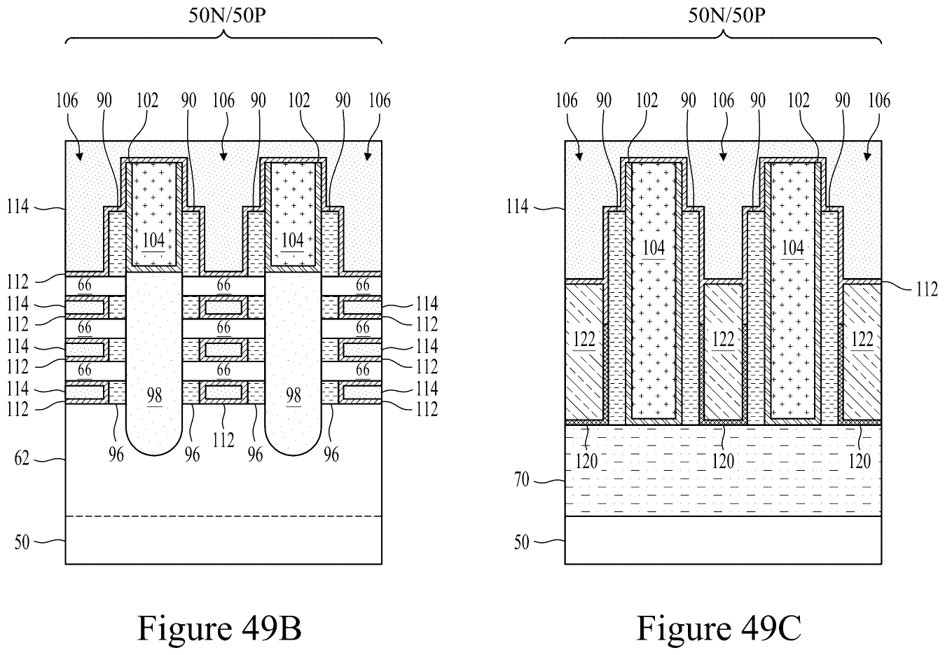

In FIGS. 49A-49C, the remaining portions of the gate electrode layer are formed in the recesses 106 in the p-type regions 50P and the n-type regions 50N. In the illustrated embodiment, a fill layer 114F (not shown in FIGS. 49B-49C, but see FIG. 49A) is deposited on the p-type work function tuning layer 114P and the n-type work function tuning layer 114N (when exposed).

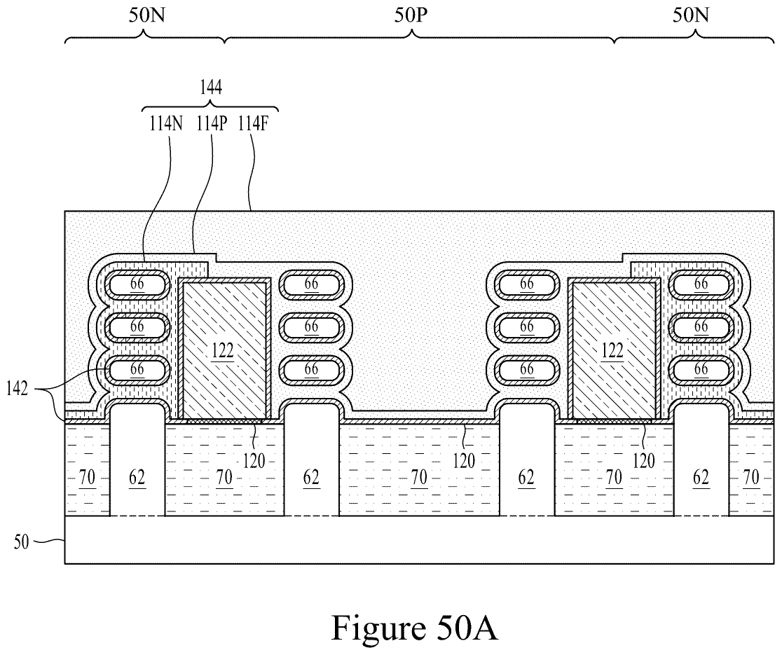

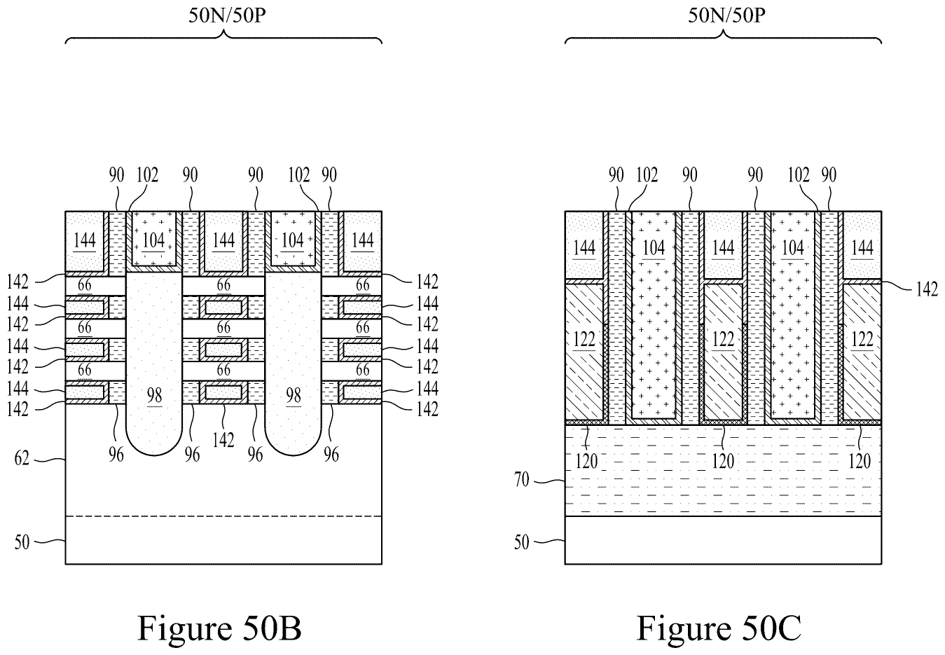

In FIGS. 50A-50C, a removal process is performed to remove the excess portions of the gate dielectric layer 112 and the gate electrode layer 114, which excess portions are over the top surfaces of the first ILD 104 and the gate spacers 90, thereby forming gate dielectrics 142 and gate electrodes 144. The excess portions of the gate dielectric layer 112 and the gate electrode layer 114 can be removed similarly as described for FIGS. 27A-27C. Additionally, in this embodiment, portions of the first ILD 104 extending above the top surfaces of the gate spacers 90 are removed. As demonstrated by FIG. 50A, the resulting gate structures (including the gate dielectrics 142 and the gate electrodes 144) are T-shaped gate structures, extending along top surfaces and sidewalls of the dielectric walls 122. The gate dielectrics 142 are disposed on the dielectric walls 122. The gate structures are formed x-shaped in a self-aligned manner, as a result of the previously described process, thereby obviating one or more trim step(s).

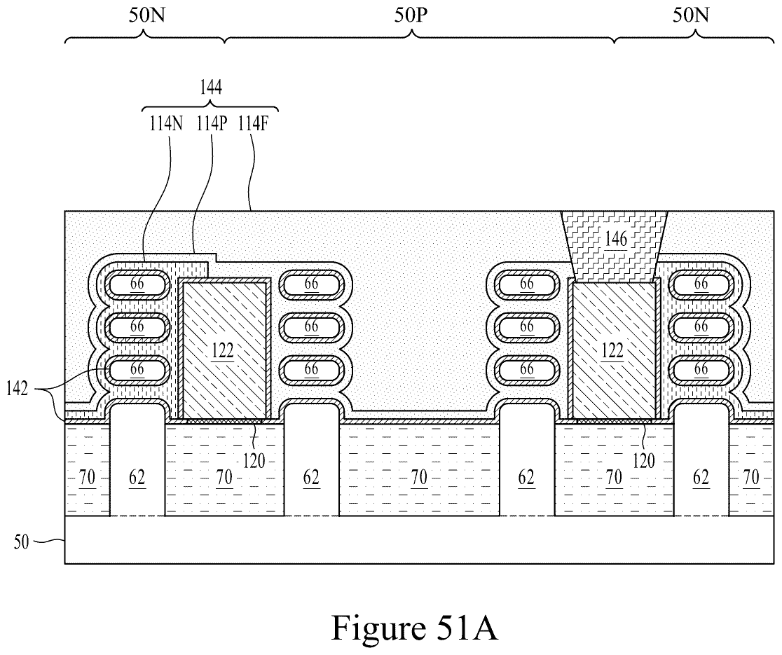

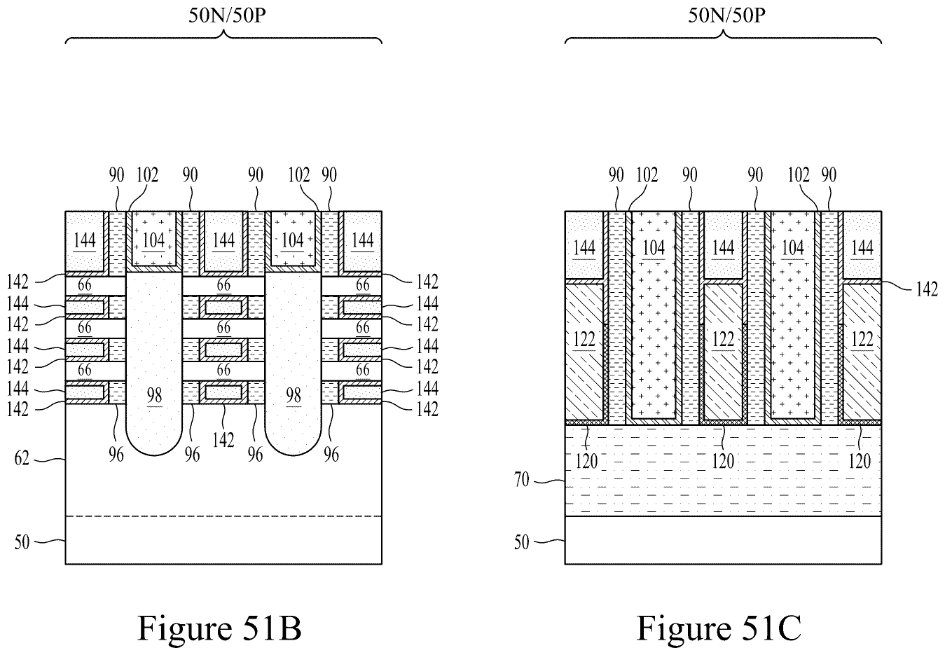

In FIGS. 51A-51C, an isolation region 146 may be formed to divide a gate structure (including a gate dielectric 142 and a gate electrode 144) into multiple gate structure segments. The isolation region 146 may be formed similarly as described for FIGS. 28A-29C, except the isolation region 146 may be wider than the underlying dielectric wall 122.

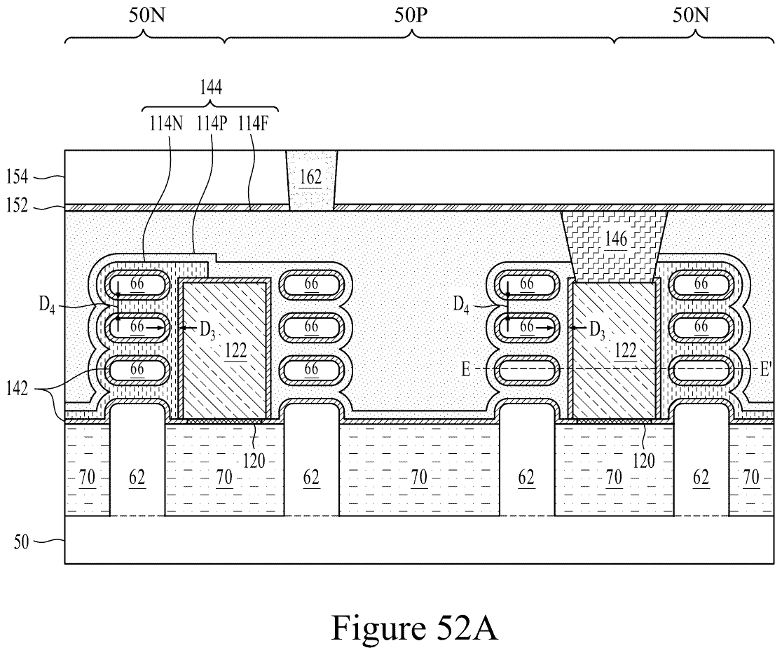

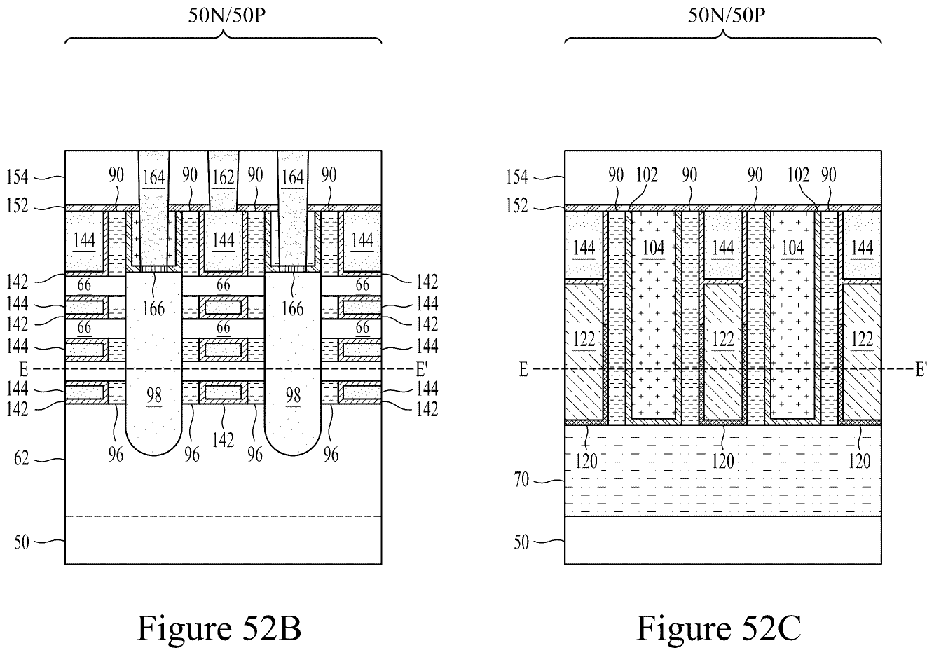

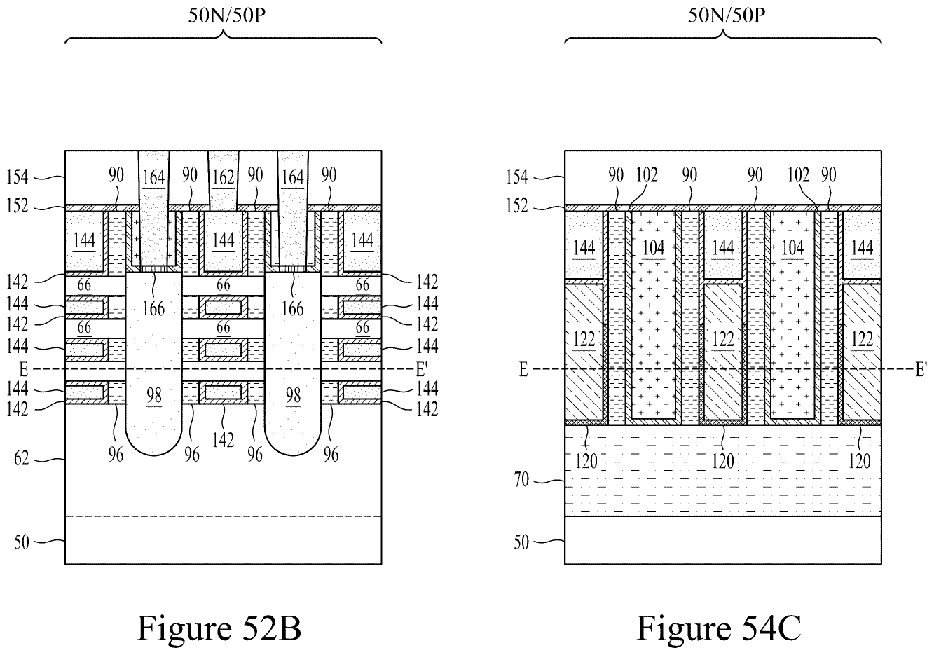

In FIGS. 52A-52C, a second ILD 154 is deposited over the gate spacers 90, the CESL 102, the first ILD 104, the gate dielectrics 142, the gate electrodes 144, and the isolation regions 146. The second ILD 154 may be formed similarly as described for FIGS. 30A-30C. In some embodiments, an etch stop layer (ESL) 152 is formed between the second ILD 154 and the gate spacers 90, the CESL 102, the first ILD 104, the gate dielectrics 142, the gate electrodes 144, and the isolation regions 146. The ESL 152 may be formed similarly as described for FIGS. 30A-30C.

Additionally, gate contacts 162 and source/drain contacts 164 are formed to contact, respectively, the gate electrodes 144 and the epitaxial source/drain regions 98. The gate contacts 162 and the source/drain contacts 164 may be formed similarly as described for FIGS. 31A-31C. Optionally, metal-semiconductor alloy regions 166 are formed at the interfaces between the epitaxial source/drain regions 98 and the source/drain contacts 164. The metal-semiconductor alloy regions 166 may be formed similarly as described for FIGS. 31A-31C.

As previously noted, the width of the openings 130 may be less than or equal to the width of the openings 108 (see FIGS. 41A-41C). As such, the distance D₃ between the nanostructures 66 and the dielectric walls 122 may be may be less than or equal to the distance D₄ between vertical pairs of nanostructures 66. In some embodiments, the distance D is in the range of 1 nm to 7 nm, and the distance D₄ is in the range of 5 nm to 12 nm. In some embodiments, the distance D₃ is less than the distance D₄, which may reduce the resistance of the gate structures and increase device performance. In this embodiment, the openings 130 (see FIGS. 41A-41C) are partially filled by the gate dielectrics 142 and partially filled by the gate electrodes 144 (e.g., the work function tuning layers 114N/114P).

As previously described, the dielectric walls 122 are formed on the liner layer 120. Because of this, etching of the inner spacers 96 may be avoided when patterning the dielectric walls 122. Gate-drain capacitance (C_{gd}) and leakage between the epitaxial source/drain regions 98 and the gate electrodes 144 may thus be reduced, improving performance of the nanostructure-FETs, particularly in AC applications. Additionally, the gate structures extend around all sides of the nanostructures 66 in the cross-section of FIG. 52A, which may improve gate control as compared to other devices that include dielectric walls, such as forksheet structures. The gate structures (including the gate dielectrics 142 and the gate electrodes 144) completely fill the respective areas between the nanostructures 66 and the dielectric walls 122, such that a gate dielectric 142 and a gate electrode 144 each partially fill a respective area. In this embodiment, the dielectric walls 122 are formed before the nanostructures 64 are removed (see FIGS. 40A-40C).

FIG. 53 is a top-down view of the nanostructure-FETs of FIGS. 52A-52C, and is along reference cross-section E-E′ in FIGS. 52A-52C. In this embodiment, the gate dielectrics 142 also extend along the sidewalls of the dielectric walls 122. Additionally, the gate dielectrics 142 are not between the dielectric walls 122 and the gate spacers 90.

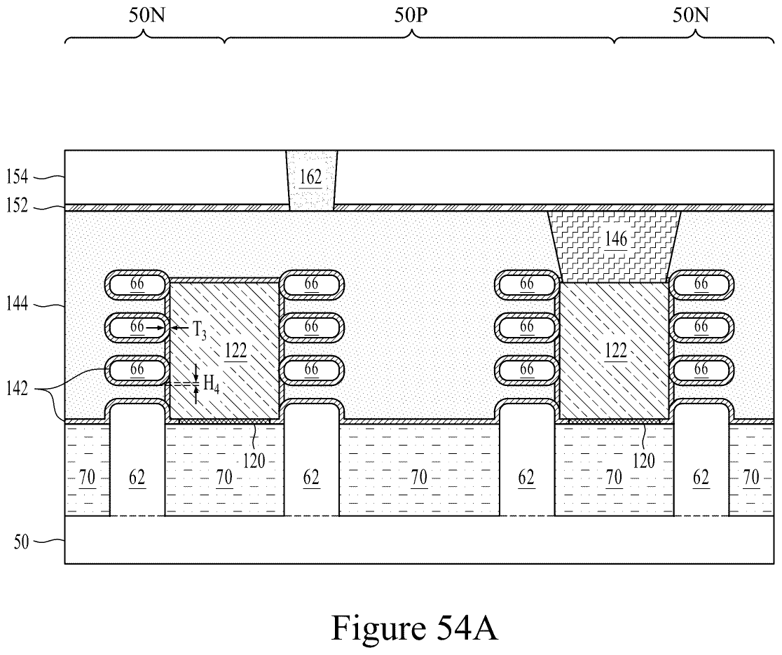

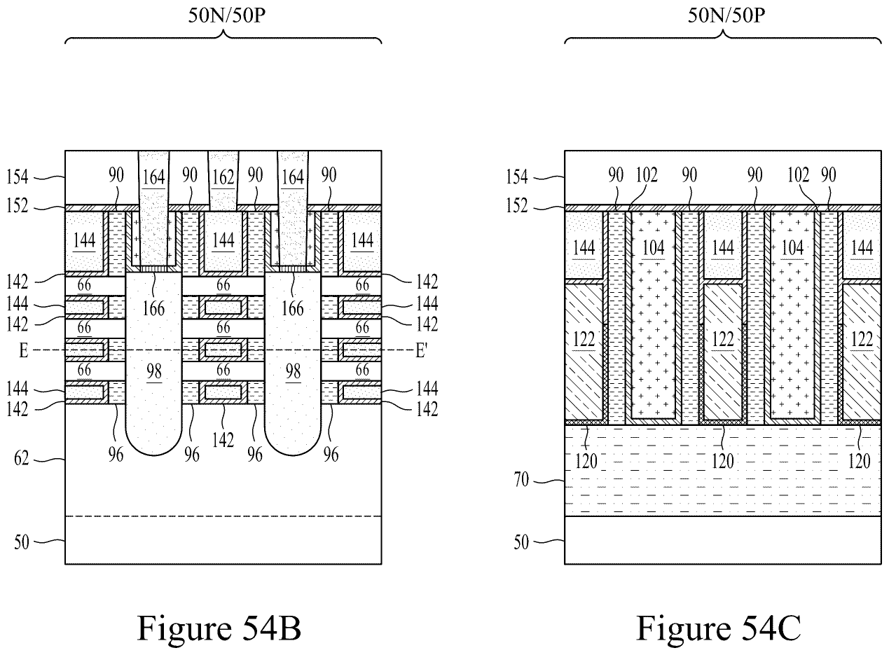

FIGS. 54A-54C are views of nanostructure-FETs, in accordance with some embodiments. This embodiment is similar to the embodiment of FIGS. 52A-52C, except the openings 130 (see FIGS. 41A-41C) are completely filled by the gate dielectrics 142. The gate dielectrics 142 may completely fill the openings 130 when trimming of the dielectric walls 122 (previously described for FIGS. 41A-41C) is omitted such that the openings 130 are small. Therefore, the gate dielectrics 142 completely fill the respective areas between the nanostructures 66 and the dielectric walls 122. Although not separately illustrated in FIGS. 54A-54C, the gate electrodes 144 may have the previously described structure (e.g., including the work function tuning layers 114N/114P and the fill layer 114F).

In some embodiments, the portions of the gate dielectrics 142 between a nanostructure 66 and a dielectric wall 122 have a thickness T₃ in the range of 2 nm to 5 nm. Additionally, the gate electrodes 144 can have vertical extensions that are between the gate dielectrics 142 and the dielectric walls 122. In some embodiments, the vertical extensions of the gate electrodes 144 have a height H4 in the range of 0 nm to 3 nm.

Embodiments may achieve advantages. Forming the dielectric walls 122 between adjacent groups of nanostructures 66 allows the adjacent groups of nanostructures 66 to be formed closer together. Device density may thus be improved. Additionally, the gate structures around the nanostructures 66 and over the dielectric walls 122 are x-shaped, thereby allowing a same gate structure to control the channel regions of adjacent devices. The amount of gate contacts used in a CMOS process may thus be reduced.

In an embodiment, a device includes: an isolation region on a substrate; first nanostructures above the isolation region; second nanostructures above the isolation region; a first gate spacer on the first nanostructures; a second gate spacer on the second nanostructures; a dielectric wall between the first gate spacer and the second gate spacer along a first direction in a top-down view, the dielectric wall disposed between the first nanostructures and the second nanostructures along a second direction in the top-down view, the first direction perpendicular to the second direction; and a gate structure around the first nanostructures and around the second nanostructures, a first portion of the gate structure filling a first area between the dielectric wall and the first nanostructures, a second portion of the gate structure filling a second area between the dielectric wall and the second nanostructures. In some embodiments of the device, the gate structure includes a gate dielectric, the gate dielectric completely filling the first area and the second area. In some embodiments of the device, the gate structure includes a gate dielectric and a gate electrode, the gate dielectric partially filling the first area and the second area, the gate electrode completely filling a remainder of the first area and the second area that is unfilled by the gate dielectric. In some embodiments of the device, the gate structure includes a gate dielectric, the dielectric wall disposed on the gate dielectric. In some embodiments of the device, the gate structure includes a gate dielectric disposed on the dielectric wall. In some embodiments, the device further includes: a liner layer between the dielectric wall and the isolation region. In some embodiments of the device, sidewalls of the liner layer are recessed from sidewalls of the dielectric wall. In some embodiments, the device further includes: a p-type source/drain region adjacent the first nanostructures; and an n-type source/drain region adjacent the second nanostructures.

In an embodiment, a device includes: a trench isolation region on a substrate; first nanostructures above the trench isolation region; second nanostructures above the trench isolation region; a dielectric wall having a lower portion and an upper portion, the lower portion disposed between the first nanostructures and the second nanostructures, the upper portion overlapping the first nanostructures and the second nanostructures, the upper portion wider than the lower portion; a gate structure around the first nanostructures and around the second nanostructures; and a gate isolation region extending through the gate structure, the gate isolation region disposed on the dielectric wall. In some embodiments of the device, the gate structure includes: a p-type work function tuning layer wrapped around the first nanostructures; and an n-type work function tuning layer wrapped around the second nanostructures. In some embodiments of the device, a first portion of the p-type work function tuning layer completely fills a first area between a pair of the first nanostructures, and a second portion of the p-type work function tuning layer completely fills a second area between the first nanostructures and the dielectric wall. In some embodiments of the device, the first portion of the p-type work function tuning layer has a first thickness, the second portion of the p-type work function tuning layer has a second thickness, and the first thickness is greater than the second thickness. In some embodiments of the device, the upper portion of the dielectric wall is wider than the gate isolation region.

In an embodiment, a method includes: forming first nanostructures and second nanostructures above a trench isolation region; removing a dummy gate from the first nanostructures and the second nanostructures; after removing the dummy gate, forming a dielectric wall between the first nanostructures and the second nanostructures, the dielectric wall separated from the first nanostructures by a first opening, the dielectric wall separated from the second nanostructures by a second opening; depositing a gate dielectric layer on the first nanostructures and the second nanostructures, the gate dielectric layer at least partially filling the first opening and the second opening; and forming a gate electrode layer on the gate dielectric layer, the gate electrode layer disposed above the dielectric wall. In some embodiments of the method, forming the dielectric wall includes: depositing a liner layer on the gate dielectric layer; depositing a dielectric material on the liner layer; patterning the dielectric material, the dielectric wall including a remaining portion of the dielectric material between the first nanostructures and the second nanostructures; and removing portions of the liner layer around the first nanostructures and the second nanostructures to form the first opening and the second opening. In some embodiments of the method, the gate electrode layer is formed on the dielectric wall. In some embodiments of the method, a portion of the liner layer remains between the gate dielectric layer and the dielectric wall. In some embodiments of the method, forming the dielectric wall includes: depositing a liner layer on the first nanostructures, the second nanostructures, and the trench isolation region; depositing a dielectric material on the liner layer; patterning the dielectric material, the dielectric wall including a remaining portion of the dielectric material between the first nanostructures and the second nanostructures; and removing portions of the liner layer between the dielectric material and the first nanostructures and between the dielectric material and the second nanostructures to form the first opening and the second opening. In some embodiments of the method, the gate dielectric layer is deposited on the dielectric wall. In some embodiments of the method, a portion of the liner layer remains between the trench isolation region and the dielectric wall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
an isolation region on a substrate;
first nanostructures above the isolation region;
second nanostructures above the isolation region;
a first gate spacer on the first nanostructures;
a second gate spacer on the second nanostructures;
a dielectric wall between the first gate spacer and the second gate spacer along a first direction in a top-down view, the dielectric wall disposed between the first nanostructures and the second nanostructures along a second direction in the top-down view, the first direction perpendicular to the second direction; and
a gate structure around the first nanostructures and around the second nanostructures, a first portion of the gate structure filling a first area between the dielectric wall and the first nanostructures, a second portion of the gate structure filling a second area between the dielectric wall and the second nanostructures.

2. The device of claim 1, wherein the gate structure comprises a gate dielectric, the gate dielectric completely filling the first area and the second area.

3. The device of claim 1, wherein the gate structure comprises a gate dielectric and a gate electrode, the gate dielectric partially filling the first area and the second area, the gate electrode completely filling a remainder of the first area and the second area that is unfilled by the gate dielectric.

4. The device of claim 1, wherein the gate structure comprises a gate dielectric, the dielectric wall disposed on the gate dielectric.

5. The device of claim 1, wherein the gate structure comprises a gate dielectric disposed on the dielectric wall.

6. The device of claim 1 further comprising:
a liner layer between the dielectric wall and the isolation region.

7. The device of claim 6, wherein sidewalls of the liner layer are recessed from sidewalls of the dielectric wall.

8. The device of claim 1 further comprising:
a p-type source/drain region adjacent the first nanostructures; and
an n-type source/drain region adjacent the second nanostructures.

9. A device comprising:
a trench isolation region on a substrate;
first nanostructures above the trench isolation region;
second nanostructures above the trench isolation region;
a dielectric wall having a lower portion and an upper portion, the lower portion disposed between the first nanostructures and the second nanostructures, the upper portion overlapping the first nanostructures and the second nanostructures, the upper portion wider than the lower portion;
a gate structure around the first nanostructures and around the second nanostructures; and
a gate isolation region extending through the gate structure, the gate isolation region disposed on the dielectric wall.

10. The device of claim 9, wherein the gate structure comprises:
a p-type work function tuning layer wrapped around the first nanostructures; and
an n-type work function tuning layer wrapped around the second nanostructures.

11. The device of claim 10, wherein a first portion of the p-type work function tuning layer completely fills a first area between a pair of the first nanostructures, and a second portion of the p-type work function tuning layer completely fills a second area between the first nanostructures and the dielectric wall.

12. The device of claim 11, wherein the first portion of the p-type work function tuning layer has a first thickness, the second portion of the p-type work function tuning layer has a second thickness, and the first thickness is greater than the second thickness.

13. The device of claim 9, wherein the upper portion of the dielectric wall is wider than the gate isolation region.

14. A device comprising:
first nanostructures;
second nanostructures;
a dielectric wall between the first nanostructures and the second nanostructures;
a gate dielectric around the first nanostructures and around the second nanostructures; and
a gate electrode over the gate dielectric, the gate electrode comprising:
a first work function tuning layer, the first work function tuning layer filling first areas between the first nanostructures, the first work function tuning layer extending along a top surface and a first sidewall of the dielectric wall;
a second work function tuning layer over the first work function tuning layer, the second work function tuning layer filling second areas between the second nanostructures, the second work function tuning layer extending along the top surface and a second sidewall of the dielectric wall, the second sidewall being opposite the first sidewall; and
a fill layer over the second work function tuning layer.

15. The device of claim 14, wherein the dielectric wall has an upper portion and a lower portion, the upper portion being wider than the lower portion, the upper portion overlapping the first nanostructures and the second nanostructures.

16. The device of claim 14, wherein the dielectric wall has an upper portion and a lower portion, the upper portion and the lower portion having the same width.

17. The device of claim 14, wherein the dielectric wall is between the gate dielectric and the gate electrode.

18. The device of claim 14, wherein the gate dielectric is between the dielectric wall and the gate electrode.

19. The device of claim 14, wherein the first work function tuning layer is n-type, the second work function tuning layer is p-type, and the device further comprises:
a first source/drain region adjacent to the first nanostructures, the first source/drain region exerting a tensile strain on the first nanostructures; and
a second source/drain region adjacent to the second nanostructures, the second source/drain region exerting a compressive strain on the second nanostructures.

20. The device of claim 19, further comprising:
first spacers disposed between the first nanostructures, the first spacers separating the first source/drain region from the gate electrode; and
second spacers disposed between the second nanostructures, the second spacers separating the second source/drain region from the gate electrode.
